(19) United States
(12) Patent Application Publication
(10) Pub. No.: US 2026/0150654 A1
(43) Pub. Date: May 28, 2026

(54) MANAGING CONDUCTIVE CHANNELS IN SEMICONDUCTOR DEVICES

(71) Applicant: Yangtze Memory Technologies Co., Ltd., Wuhan (CN)

(72) Inventors: Zongliang HUO, Wuhan (CN); Wenbin ZHOU, Wuhan (CN); Wei XU, Wuhan (CN); Qiangwei ZHANG, Wuhan (CN); Zongke XU, Wuhan (CN)

(21) Appl. No.: 19/030,730

(22) Filed: Jan. 17, 2025

Related U.S. Application Data
(63) Continuation of application No. PCT/CN2024/136654, filed on Dec. 4, 2024.

(30) Foreign Application Priority Data
Nov. 27, 2024 (WO) PCT/CN2024/134870

(51) Int. Cl. H01L 23/528; H01L 21/768; H01L 23/00; H01L 23/48; H01L 23/498; H01L 23/522; H01L 23/538; H01L 25/16; H10B 80/00; H10D 80/30

(52) U.S. Cl. CPC H10W 20/435; H10B 80/00; H10W 20/081; H10W 20/496; H10W 70/65; H10W 70/69; H10D 80/30; H10W 20/20; H10W 80/312; H10W 80/327; H10W 90/00; H10W 90/297; H10W 90/724; H10W 90/792

(57) ABSTRACT

Systems, devices, and methods for managing conductive channels in a semiconductor device are provided. In one aspect, a semiconductor device includes a plurality of array structures. An array structure of the plurality of array structures includes a plurality of memory cells. A memory cell of the plurality of memory cells includes a transistor and a capacitor that are stacked together along a first direction. A separation structure is provided which is surrounding the capacitors of the array structure. A connection structure is provided, which includes a layered structure and a conductive channel extending into the layered structure along the first direction. The separation structure separates the capacitors of the array structure from the connection structure. A first contact structure is coupled to a first end of the conductive channel. A second contact structure is coupled to a second end of the conductive channel.

### CROSS-REFERENCE TO RELATED APPLICATIONS

This application is a continuation of International Application No. PCT/CN2024/136654, filed on Dec. 4, 2024, which claims priority to International Patent Application No. PCT/CN2024/134870, filed on Nov. 27, 2024. The disclosures of the aforementioned applications are hereby incorporated by reference in their entireties.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing conductive channels in three-dimensional (3D) semiconductor devices.

One aspect of the present disclosure features a semiconductor device, including a plurality of array structures. An array structure of the plurality of array structures includes a plurality of memory cells. A memory cell of the plurality of memory cells includes a transistor and a capacitor that are stacked together along a first direction. A separation structure is provided surrounding the capacitors of the array structure, the separation structure extending along the first direction. A connection structure is provided adjacent to the separation structure. The connection structure includes a layered structure and a conductive channel extending into the layered structure along the first direction, where the separation structure separates the capacitors of the array structure from the connection structure.

In some implementations, the layered structure includes a first dielectric layer and a second dielectric layer stacked together along the first direction.

In some implementations, the layered structure includes a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG). And the first supporting layer and second supporting layer include at least one of silicon carbon nitride (SiCN) or silicon boron nitride (SiBN).

In some implementations, the separation structure includes at least one of silicon carbon nitride (SiCN) or silicon boron nitride (SiBN).

In some implementations, a material of the separation structure is different from a material of the first dielectric layer of the layered structure.

In some implementations, an edge of the separation structure is wave shaped.

In some implementations, the conductive channel includes at least one of tungsten (W), polysilicon, or titanium intrude (TiN).

In some implementations, the capacitor includes a first end and a second end opposite to the first end along the first direction, and the second end of the capacitor is coupled to the transistor. A first end of the conductive channel is coplanar with the first end of the capacitor.

In some implementations, the first end of the conductive channel is coupled to a first contact structure. And a second end of the conductive channel is opposite to the first end of the conductive channel along the first direction and coupled to a second contact structure.

In some implementations, a height of the conductive channel is greater than a height of the capacitor along the first direction.

In some implementations, the semiconductor device includes a plurality of contact structures including the first contact structure, the second contact structure and a third contact structure. And the connection structure includes a plurality of conductive channels including the conductive channel. The first contact structure and the second contact structure are coupled to first and second ends of one or more same conductive channels including the conductive channel. The third contact structure is coupled to at least one of the plurality of conductive channels. And adjacent conductive channels coupled to the first contact structure and the third contact structure are spaced from each other by at least one dummy channel between the adjacent conductive channels.

In some implementations, the transistor includes a transistor body, a first terminal, and a second terminal. The first terminal and the second terminal are on opposite ends of the transistor body along the first direction. The first terminal is coupled to the capacitor. The semiconductor device includes: a bit line extending along a second direction and coupled to the second terminal of the transistor, and a word line extending along a third direction, the third direction being perpendicular to the first direction and different from the second direction.

In some implementations, the conductive channel is coupled to the word line.

In some implementations, a height of the conductive channel is greater than a height of the capacitor along the first direction.

In some implementations, the conductive channel is between adjacent array structures along the third direction.

In some implementations, the conductive channel is coupled to the bit line.

In some implementations, the conductive channel is coupled to a first end of a semiconductor body. A second end of the semiconductor body is coupled to the bit line. And the semiconductor body includes at least one of N type dopants or P type dopants.

In some implementations, a width of the semiconductor body is greater than a width of the transistor body along the second direction.

In some implementations, a height of the conductive channel is equal to a height of the capacitor along the first direction.

In some implementations, the conductive channel is between adjacent array structures along the second direction.

In some implementations, the conductive channel is a first conductive channel. The connection structure includes a plurality of conductive channels includes the first conductive channel, a second conductive channel and a third conductive channel. The first conductive channel is coupled to the word line, the second conductive channel is coupled to the bit line, and the third conductive channel is coupled to a contact structure.

In some implementations, the first conductive channel, the second conductive channel and the third conductive channel have a uniform size.

In some implementations. a size of the conductive channel is smaller than a width of the separation structure along a second direction perpendicular to the first direction or a third direction perpendicular to the first direction and different from the second direction. The separation structure is surrounding the capacitors of the array structure along the second direction and the third direction.

In some implementations, the capacitor extends along the first direction and includes a first electrode, a second electrode, and a capacitor dielectric between the first electrode and the second electrode. The first electrode is coupled to the transistor. An outer size of the first electrode is equal to a size of the conductive channel.

In some implementations, the array structure of the plurality of array structures includes a plurality of capacitors includes the capacitor. The connection structure includes a plurality of conductive channels includes the conductive channel. The plurality of capacitors and the plurality of conductive channels have uniform pitch along a second direction perpendicular to the first direction or a third direction perpendicular to the first direction and different from the second direction. The separation structure is surrounding the capacitors of the array structure along the second direction and the third direction.

In some implementations, the connection structure includes a dummy channel extending into the layered structure along the first direction. A first end of the dummy channel is coplanar with a first end of the capacitor. A second end of the capacitor is coupled to the transistor. The second end of the capacitor is opposite to the first end of the capacitor along the first direction.

In some implementations, a size of the dummy channel is equal to a size of the conductive channel.

In some implementations, the dummy channel includes a material different from a material of the conductive channel.

In some implementations, the dummy channel includes a dielectric material.

In some implementations, the dummy channel is between the conductive channel and the separation structure.

In some implementations, the semiconductor device includes: a memory structure, which includes the plurality of array structures, the separation structure, and the connection structure; and a control structure coupled to the memory structure and including control circuits.

In some implementations, the semiconductor device includes a first bonding layer in a first side of the memory structure, and a second bonding layer in a first side of the control structure. The first bonding layer is in contact with the second bonding layer.

In some implementations, the first bonding layer includes one or more first conductive contacts isolated by a first dielectric material. The second bonding layer includes one or more second conductive contacts isolated by a second dielectric material. The conductive channel of the memory structure is coupled to at least one of the one or more first conductive contacts. At least one of the one or more first conductive contacts is in contact with a corresponding one of the one or more second conductive contacts.

In some implementations, a first end of the conductive channel is coupled to a conductive layer. A second end of the conductive channel is coupled to at least one of the one or more first conductive contacts. A height of the conductive channel is greater than a height of the capacitor along the first direction.

In some implementations, each end of the conductive channel is coplanar with a respective end of the capacitor.

In some implementations, a first end of the conductive channel is coplanar with a first end of capacitor. A second end of the conductive channel is coupled to a bit line or a word line. The first end of the conductive channel is coupled to the control structure through at least one of the first conductive contacts or the second conductive contacts.

In some implementations, the control structure includes a conductive via. A first end of the conductive via is coupled to the conductive channel of the memory structure through at least one of the first conductive contacts or the second conductive contacts. A second end of the conductive via is coupled to a padding out structure.

In some implementations, a third bonding layer is in a second side of the memory structure. A fourth bonding layer is in a second side of the control structure. The third bonding layer includes one or more third conductive contacts isolated by a third dielectric material. The fourth bonding layer includes one or more fourth conductive contacts isolated by a fourth dielectric material. The conductive channel of the memory structure is coupled to at least one of the one or more first conductive contacts or the one or more third conductive contacts.

In some implementations, the memory structure is a first memory structure. The semiconductor device includes a plurality of memory structures includes the first memory structure and a second memory structure. A fifth bonding layer is in a first side of the second memory structure. A sixth bonding layer is in a second side of the second memory structure. The fifth bonding layer includes one or more fifth conductive contacts isolated by a fifth dielectric material. The sixth bonding layer includes one or more sixth conductive contacts isolated by a sixth dielectric material. The conductive channel of the second memory structure is coupled to at least one of the one or more fifth conductive contacts or the one or more sixth conductive contacts. The control structure is a first control structure. The semiconductor device includes a plurality of control structures includes the first control structure and a second control structure. A seventh bonding layer is in a first side of the second control structure. The seventh bonding layer includes one or more seventh conductive contacts isolated by a seventh dielectric material. The first memory structure, the first control structure, the second memory structure, and the second control structure are stacked together along the first direction.

In some implementations, at least one of the one or more third conductive contacts of the first memory structure is in contact with a corresponding one of the one or more fifth conductive contacts of the second memory structure. The conductive channel of the first memory structure is coupled to the conductive channel of the second memory structure through at least one of the third conductive contacts or the fifth conductive contacts. At least one of the one or more sixth conductive contacts of the second memory structure is in contact with a corresponding one of the one or more seventh conductive contacts of the second control structure.

In some implementations, an eighth bonding layer is in a second side of the second control structure. The eighth bonding layer includes one or more eighth conductive contacts isolated by an eighth dielectric material. At least one of the one or more third conductive contacts of the first memory structure is in contact with a corresponding one of the one or more seventh conductive contacts of the second control structure. The conductive channel of the first memory structure is coupled to the second control structure through at least one of the third conductive contacts or the seventh conductive contacts. At least one of the one or more fifth conductive contacts of the second memory structure is in contact with a corresponding one of the one or more eighth conductive contacts of the second control structure.

In some implementations, the second control structure includes a conductive via. A first end of the conductive via is coupled to the conductive channel of the first memory structure through at least one of the third conductive contacts or the seventh conductive contacts. A second end of the conductive via is coupled to the conductive channel of the second memory structure through at least one of the fifth conductive contacts or the eighth conductive contacts.

Another aspect of the present disclosure features a semiconductor device including: a plurality of memory structures including a first memory structure and a second memory structure. At least one of the first memory structure or the second memory structure includes: a plurality of array structures. An array structure of the plurality of array structures includes a plurality of memory cells. A memory cell of the plurality of memory cells includes a transistor and a capacitor that are stacked together along a first direction. A separation structure is included surrounding the capacitors of the array structure. The separation structure extends along the first direction. A connection structure is provided that includes a layered structure and a conductive channel extending into the layered structure along the first direction. The separation structure separates the capacitors of the array structure from the connection structure. One or more conductive contacts are included in at least one side coupled to the conductive channel. The semiconductor device includes a control structure including a connecting structure coupled to at least one of the one or more conductive contacts of the first memory structure. The conductive channel of the first memory structure is coupled to the conductive channel of the second memory structure through at least one of the one or more of the conductive contacts.

In some implementations, the control structure includes a conductive via extending through the control structure along the first direction. The conductive via of the control structure is coupled to the conductive channel of the first memory structure through the connecting structure.

In some implementations, the semiconductor device includes a plurality of control structures including the control structure. The plurality of control structures and the plurality of memory structures are coupled to one another through hybrid bonding.

In some implementations, at least one of the first memory structure or the second memory structure includes a semiconductor device according to at least one of implementations.

Another aspect of the present disclosure features a method including: forming a plurality of memory structures includes a first memory structure and a second memory structure. Forming at least one of the first memory structure or the second memory structure includes: forming a plurality of array structures. An array structure of the plurality of array structures includes a plurality of memory cells. A memory cell of the plurality of memory cells includes a transistor and a capacitor that are stacked together along a first direction. Forming at least one of the first memory structure or the second memory structure further includes: forming a separation structure surrounding the capacitors of the array structure, the separation structure extending along the first direction; forming a connection structure including a layered structure and a conductive channel extending into the layered structure along the first direction, where the separation structure separates the capacitors of the array structure from the connection structure; forming one or more conductive contacts in at least one side coupled to the conductive channel; and forming a control structure including a connecting structure, the connecting structure being coupled to at least one of the one or more conductive contacts of the first memory structure. The conductive channel of the first memory structure is coupled to the conductive channel of the second memory structure through at least one of the one or more conductive contacts.

In some implementations, forming at least one of the first memory structure or the second memory structure includes: forming the layered structure; forming openings extending into the layered structure along the first direction; forming the separation structure extending into the layered structure and defining an array region surrounded by the separation structure; forming the capacitors in the array region; and forming the conductive channel outside of the separation structure and extending into the layered structure.

In some implementations, forming conductive channels outside of the separation structure includes: depositing a conductive material into at least one of the openings outside of the separation structure.

In some implementations, the method includes depositing a sacrificial material into one or more openings outside of the separation structure; removing the sacrificial material of at least one of the one or more openings outside of the separation structure to form holes; and depositing the conductive material into the holes.

In some implementations, the method includes forming an etch stop layer between the layered structure and the transistors; and at least partially removing the etch stop layer outside of the separation structure.

In some implementations, the method includes forming a first contact structure coupled to a first end of one or more conductive channels.

In some implementations, the method includes forming a second contact structure coupled to a second end of the one or more conductive channels.

In some implementations, the method includes forming capacitors in the array region surrounded by the separation structure includes: depositing a first electrode into the openings in the array region.

In some implementations, forming the one or more conductive contacts in at least one side includes: forming a first bonding layer in a first side of the first memory structure and a third bonding layer in a second side of the first memory structure; forming a fourth bonding layer in a first side of the second memory structure; forming one or more first conductive contacts extending through the first bonding layer and isolated by a first dielectric material; forming one or more third conductive contacts extending through the third bonding layer and isolated by a third dielectric material; and forming one or more fourth conductive contacts extending through the fourth bonding layer and isolated by a fourth dielectric material.

In some implementations, the method includes stacking the first memory structure and the second memory structure, where the third bonding layer is in contact with the fourth bonding layer. At least one of the one or more third conductive contacts of the first memory structure is in contact with a corresponding one of the one or more fourth conductive contacts of the second memory structure.

In some implementations, the control structure includes one or more connecting structures including the connecting structure. Forming the control structure includes: forming a second bonding layer in a first side of the control structure; and forming the one or more connecting structures extending through the second bonding layer and isolated by a second dielectric material.

In some implementations, the method includes stacking the first memory structure and the control structure, where the first bonding layer is in contact with the second bonding layer. At least one of the one or more first conductive contacts of the first memory structure is in contact with a corresponding one of the one or more connecting structures of the control structure.

Another aspect of the present disclosure features a semiconductor device including: a memory die including a memory structure and a control structure coupled to the memory structure. The memory structure includes a plurality of array structures. An array structure of the plurality of array structures includes a plurality of memory cells. A memory cell of the plurality of memory cells includes a transistor and a capacitor that are stacked together along a first direction. The memory structure includes a separation structure surrounding the capacitors of the array structure, the separation structure extending along the first direction, and a connection structure adjacent to the separation structure. The connection structure includes a layered structure and a conductive channel extending into the layered structure along the first direction. The separation structure separates the capacitors of the array structure from the connection structure. A semiconductor device includes a base die coupled to the memory die. The base die and the memory die are stacked along the first direction.

In some implementations, the semiconductor device includes a computing die coupled to the memory die; and an interposer coupled to the base die and the computing die. The interposer includes interconnection lines and conductive terminals.

In some implementations, the memory die, the base die, the computing die and the interposer are stacked along the first direction.

In some implementations, the memory die and the base die are stacked along the first direction. The base die and the computing die are integrated on different positions of the interposer along a second direction perpendicular to the first direction. The base die and the computing die are coupled through the interconnection lines.

In some implementations, the base die is coupled to first conductive terminals of the conductive terminals on a surface of the interposer. The computing die is coupled to second conductive terminals of the conductive terminals on the surface of the interposer. The first conductive terminals and the second conductive terminals are coupled through the interconnection lines in the interposer.

In some implementations, the computing die is coupled to the memory die through the base die.

In some implementations, the semiconductor device includes a plurality of memory dies including the memory die. At least one of the plurality of memory dies includes one or more conductive contacts in at least one side. The plurality of memory dies is stacked along the first direction and coupled to each other through the conductive channel of the memory structure and the one or more conductive contacts.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction. The semiconductor device includes a separation structure surrounding capacitors of the array structure, the separation structure extending along the first direction; a connection structure adjacent to the separation structure. The connection structure includes a layered structure and a conductive channel extending into the layered structure along the first direction. The separation structure separates the capacitors of the array structure from the connection structure, and the conductive channel includes a first end and a second end that are opposite to each other along the first direction. The semiconductor device includes a first contact structure and a second contact structure. The first contact structure is coupled to the first end of the conductive channel and the second contact structure is coupled to the second end of the conductive channel.

In some implementations, the layered structure includes a first dielectric layer and a second dielectric layer stacked together along the first direction.

In some implementations, the layered structure includes: a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the separation structure includes at least one of silicon carbon nitride (SiCN) or silicon boron nitride (SiBN).

In some implementations, at least one material of the separation structure is different from a material of the layered structure.

In some implementations, an edge of the separation structure is wave shaped.

In some implementations, the conductive channel includes at least one of tungsten (W), polysilicon, or titanium intrude (TiN).

In some implementations, the capacitor includes a first end and a second end opposite to the first end along the first direction. The second end of the capacitor is coupled to the transistor. A first end of the conductive channel is coplanar with the first end of the capacitor.

In some implementations, a height of the conductive channel is greater than a height of the capacitor along the first direction.

In some implementations, a height of the conductive channel is equal to a height of the capacitor along the first direction.

In some implementations, the connection structure includes a plurality of conductive channels including the conductive channel. The first contact structure and the second contact structure are coupled to first and second ends of one or more same conductive channels including the conductive channel.

In some implementations, the semiconductor device includes a third contact structure coupled to at least one of the plurality of conductive channels. Adjacent conductive channels that are coupled to the first contact structure and the third contact structure are spaced from each other by at least one dummy channel between the adjacent conductive channels.

In some implementations, a size of the conductive channel is smaller than a width of the separation structure along a second direction perpendicular to the first direction or a third direction perpendicular to the first direction and different from the second direction. The separation structure is surrounding capacitors of the array structure along the second direction and the third direction.

In some implementations, the capacitor extends along the first direction and includes a first electrode, a second electrode, and a capacitor dielectric between the first electrode and the second electrode. The first electrode is coupled to the transistor, and an outer size of the first electrode is equal to a size of the conductive channel.

In some implementations, the array structure of the plurality of array structures includes a plurality of capacitors including the capacitor, and the connection structure includes a plurality of conductive channels including the conductive channel. The plurality of capacitors and the plurality of conductive channels have uniform pitch along a second direction perpendicular to the first direction or a third direction perpendicular to the first direction and different from the second direction. The separation structure is surrounding the capacitors of the array structure along the second direction and the third direction.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction. The semiconductor device includes a connection structure adjacent to the array structures. The connection structure includes a layered structure and a conductive channel extending into the layered structure along the first direction. The layered structure includes a first dielectric layer and a second dielectric layer stacked together along the first direction, and the conductive channel includes a first end and a second end that are opposite to each other along the first direction. The semiconductor device includes a first contact structure and a second contact structure. The first contact structure is coupled to the first end of the conductive channel and the second contact structure is coupled to the second end of the conductive channel.

In some implementations, the layered structure includes a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the semiconductor device includes a separation structure surrounding capacitors of the array structure. The separation structure extends along the first direction. The separation structure separates capacitors of the array structure from the connection structure.

In some implementations, the capacitor includes a first end and a second end opposite to the first end along the first direction. The second end of the capacitor is coupled to the transistor, and a first end of the conductive channel is coplanar with the first end of the capacitor.

Another aspect of the present disclosure features a method including: forming a plurality of array structures, where an array structure of the plurality of array structures includes a plurality of memory cells, and a memory cell of the plurality of memory cells includes a transistor and a capacitor that are stacked together along a first direction; forming a separation structure surrounding capacitors of the array structure, where the separation structure extends along the first direction; forming a connection structure adjacent to the separation structure. The connection structure includes a layered structure and a conductive channel extending into the layered structure along the first direction. The separation structure separates the capacitors of the array structure from the connection structure. The conductive channel includes a first end and a second end that are opposite to each other along the first direction. The method includes forming a plurality of contact structures including a first contact structure and a second contact structure. The first contact structure is coupled to the first end of the conductive channel and the second contact structure is coupled to the second end of the conductive channel.

In some implementations, the method includes forming an etch stop layer; forming the layered structure on the etch stop layer; forming openings extending into the layered structure along the first direction; forming the separation structure extending into the layered structure and defining an array region surrounded by the separation structure; forming the capacitors in the array region; and forming the conductive channel outside of the array region and extending into the layered structure.

In some implementations, the method includes at least partially removing the etch stop layer outside of the array region.

In some implementations, forming the conductive channels outside of the array region includes: depositing a sacrificial material into one or more openings outside of the array region; removing the sacrificial material of at least one of the one or more openings outside of the array region to form holes; and depositing a conductive material into the holes.

In some implementations, forming the conductive channel outside of the array region includes: depositing a conductive material into at least one of the openings outside of the array region.

In some implementations, forming capacitors in the array region surrounded by the separation structure includes: depositing at least one conductive material into the openings in the array region to form an electrode of the capacitors.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction; a bit line extending along a second direction perpendicular to the first direction and coupled to the transistor; a separation structure surrounding capacitors of the array structure, where the separation structure extends along the first direction; and a connection structure adjacent to the separation structure. The connection structure includes a layered structure and a conductive channel extending into the layered structure along the first direction. The separation structure separates the capacitors of the array structure from the connection structure. The conductive channel is coupled to the bit line.

In some implementations, the layered structure includes a first dielectric layer and a second dielectric layer stacked together along the first direction.

In some implementations, the layered structure includes: a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the separation structure includes at least one of silicon carbon nitride (SiCN) or silicon boron nitride (SiBN).

In some implementations, the conductive channel includes at least one of tungsten (W), polysilicon, or titanium intrude (TiN).

In some implementations, the capacitor includes a first end and a second end opposite to the first end along the first direction. The second end of the capacitor is coupled to the transistor. A first end of the conductive channel is coplanar with the first end of the capacitor.

In some implementations, a height of the conductive channel is equal to a height of the capacitor along the first direction.

In some implementations, the transistor is a first transistor. The semiconductor device further includes a second transistor including a semiconductor body, and the conductive channel is coupled to the bit line through the semiconductor body of the second transistor.

In some implementations, each of a first end and a second end of the semiconductor body includes dopants with a first type, and a middle portion of the semiconductor body between the first end and the second end of the semiconductor body includes the dopants with a second type.

In some implementations, the first type is different from the second type.

In some implementations, the semiconductor body of the second transistor is coupled to a word line extending along a third direction perpendicular to the first direction and the second direction. The second transistor is configured to be supplied with a voltage applied on the word line while the conductive channel is coupled to the bit line through the semiconductor body of the second transistor.

In some implementations, the connection structure includes a plurality of conductive channels including the conductive channel. The semiconductor device further includes a contact structure coupled to at least two of the plurality of conductive channels.

In some implementations, the semiconductor body of the second transistor is coupled to at least two of the plurality of conductive channels.

In some implementations, the contact structure is between adjacent array structures along the second direction.

In some implementations, the connection structure includes a dummy channel extending into the layered structure along the first direction. The capacitor includes a first end and a second end opposite to the first end along the first direction. The second end of the capacitor is coupled to the transistor. A first end of the dummy channel is coplanar with the first end of the capacitor.

In some implementations, a size of the conductive channel is smaller than a width of the separation structure along a second direction perpendicular to the first direction or a third direction perpendicular to the first direction and different from the second direction. The separation structure is surrounding capacitors of the array structure along the second direction and the third direction.

In some implementations, the capacitor extends along the first direction and includes a first electrode, a second electrode, and a capacitor dielectric between the first electrode and the second electrode. The first electrode is coupled to the transistor, and an outer size of the first electrode is equal to a size of the conductive channel.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction; a bit line extending along a second direction perpendicular to the first direction and coupled to the transistor; and a connection structure adjacent to the array structures. The connection structure includes a layered structure and a conductive channel extending into the layered structure along the first direction. The layered structure includes a first dielectric layer and a second dielectric layer stacked together along the first direction, and the conductive channel is coupled to the bit line.

In some implementations, the layered structure includes: a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the semiconductor device includes a separation structure surrounding capacitors of the array structure. The separation structure extends along the first direction. The separation structure separates the capacitors of the array structure from the connection structure.

In some implementations, the transistor is a first transistor. The semiconductor device further includes a second transistor includes a semiconductor body, and the conductive channel is coupled to the bit line through the semiconductor body of the second transistor.

In some implementations, each of a first end and a second end of the semiconductor body includes dopants with a first type, and a middle portion of the semiconductor body between the first end and the second end of the semiconductor body includes the dopants with a second type.

In some implementations, the first type is different from the second type.

In some implementations, the semiconductor body of the second transistor is coupled to a word line extending along a third direction perpendicular to the first direction and the second direction. The second transistor is configured to be supplied with a voltage applied on the word line while the conductive channel is coupled to the bit line through the semiconductor body of the second transistor.

In some implementations, the capacitor includes a first end and a second end opposite to the first end along the first direction. The second end of the capacitor is coupled to the transistor. A first end of the conductive channel is coplanar with the first end of the capacitor.

Another aspect of the present disclosure features a method including: forming a plurality of array structures, where an array structure of the plurality of array structures includes a plurality of memory cells, and a memory cell of the plurality of memory cells includes a transistor and a capacitor that are stacked together along a first direction; forming a separation structure surrounding capacitors of the array structure, where the separation structure extends along the first direction; forming a connection structure adjacent to the separation structure, where the connection structure includes a layered structure and a conductive channel extending into the layered structure along the first direction, and the separation structure separates the capacitors of the array structure from the connection structure; and forming a bit line extending along a second direction perpendicular to the first direction and coupled to the transistor, where the conductive channel is coupled to the bit line.

In some implementations, the method includes forming the layered structure; forming openings extending into the layered structure along the first direction; forming the separation structure extending into the layered structure and defining an array region surrounded by the separation structure; forming the capacitors in the array region; and forming the conductive channel outside of the array region and extending into the layered structure.

In some implementations, the method includes forming a second transistor outside of the array region, where the conductive channel is coupled to the bit line through a semiconductor body of the second transistor.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction; a word line extending along a second direction perpendicular to the first direction; a separation structure surrounding capacitors of the array structure, where the separation structure extends along the first direction; and a connection structure adjacent to the separation structure, where the connection structure includes a layered structure and a conductive channel extending into the layered structure along the first direction. The separation structure separates the capacitors of the array structure from the connection structure, and the conductive channel is coupled to the word line.

In some implementations, the layered structure includes a first dielectric layer and a second dielectric layer stacked together along the first direction.

In some implementations, the layered structure includes: a first supporting layer between the first dielectric layer and the second dielectric layer, and a second supporting layer stacked over the first dielectric layer.

In some implementations, at least one material of the separation structure is different from a material of the layered structure.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the separation structure includes at least one of silicon carbon nitride (SiCN) or silicon boron nitride (SiBN).

In some implementations, an edge of the separation structure is wave shaped.

In some implementations, the conductive channel includes at least one of tungsten (W), polysilicon, or titanium intrude (TiN).

In some implementations, the capacitor includes a first end and a second end opposite to the first end along the first direction, the second end of the capacitor is coupled to the transistor, and a first end of the conductive channel is coplanar with the first end of the capacitor.

In some implementations, the conductive channel is between adjacent array structures along the second direction.

In some implementations, a height of the conductive channel is equal to a height of the capacitor along the first direction.

In some implementations, the array structure is in an array region, and the conductive channel is in a word line (WL) pick-up region. The semiconductor device includes an etch-stop layer between the capacitor and the transistor. The etch-stop layer extends in the array region and the WL pick-up region along the second direction. A height of the word line in the array region is smaller than a height of the word line in the WL pick-up region along the first direction.

In some implementations, a height of the conductive channel is greater than a height of the capacitor along the first direction.

In some implementations, the array structure is in an array region, and the conductive channel is in a word line (WL) pick-up region. The array region includes an etch-stop layer between the capacitor and the transistor. The etch-stop layer extends within the array region and without extending into the WL pick-up region. A height of the word line in the array region is equal to a height of the word line in the WL pick-up region along the first direction.

In some implementations, the transistor includes a transistor body. The transistor body includes a first terminal and a second terminal. The first terminal and the second terminal are on opposite ends of the transistor body along the first direction. The first terminal is coupled to the capacitor.

In some implementations, the semiconductor device includes a contact structure. The connection structure includes a plurality of conductive channels including the conductive channel, and the contact structure is coupled to at least one of the plurality of conductive channels including the conductive channel.

In some implementations, a size of the conductive channel is smaller than a width of the separation structure along a second direction perpendicular to the first direction or a third direction perpendicular to the first direction and different from the second direction. The separation structure is surrounding capacitors of the array structure along the second direction and the third direction.

In some implementations, the capacitor extends along the first direction and includes a first electrode, a second electrode, and a capacitor dielectric between the first electrode and the second electrode. The first electrode is coupled to the transistor, and an outer size of the first electrode is equal to a size of the conductive channel.

In some implementations, the array structure of the plurality of array structures includes a plurality of capacitors including the capacitor, and the connection structure includes a plurality of conductive channels including the conductive channel. The plurality of capacitors and the plurality of conductive channels have uniform pitch along a second direction perpendicular to the first direction. The separation structure is surrounding capacitors of the array structure along the second direction and the third direction.

Another aspect of the present disclosure features a semiconductor device including: a plurality of array structures, where an array structure of the plurality of array structures includes a plurality of memory cells, and a memory cell of the plurality of memory cells includes a transistor and a capacitor that are stacked together along a first direction; a word line extending along a second direction perpendicular to the first direction; and a connection structure adjacent to the array structures. The connection structure includes a layered structure and a conductive channel extending into the layered structure along the first direction. The layered structure includes a first dielectric layer and a second dielectric layer stacked together along the first direction. The conductive channel is coupled to the word line.

In some implementations, the layered structure includes: a first supporting layer between the first dielectric layer and the second dielectric layer, and a second supporting layer stacked over the first dielectric layer.

In some implementations, the first dielectric layer includes tetraethyl orthosilicate (TEOS), the second dielectric layer includes borophosphosilicate glass (BPSG), and the first supporting layer and second supporting layer include at least one of silicon carbon nitride (SiCN) or silicon boron nitride (SiBN).

In some implementations, the semiconductor device includes a separation structure surrounding capacitors of the array structure. The separation structure extends along the first direction. The separation structure separates the capacitors of the array structure from the connection structure.

In some implementations, the capacitor includes a first end and a second end opposite to the first end along the first direction. The second end of the capacitor is coupled to the transistor. A first end of the conductive channel is coplanar with the first end of the capacitor.

Another aspect of the present disclosure features a method including: forming a plurality of array structures, where an array structure of the plurality of array structures includes a plurality of memory cells, and a memory cell of the plurality of memory cells includes a transistor and a capacitor that are stacked together along a first direction; forming a word line extending along a second direction perpendicular to the first direction; forming a separation structure surrounding capacitors of the array structure, where the separation structure extends along the first direction; and forming a connection structure adjacent to the separation structure, where the connection structure includes a layered structure and a conductive channel extending into the layered structure along the first direction. The separation structure separates the capacitors of the array structure from the connection structure, and the conductive channel is coupled to the word line.

In some implementations, the method includes forming an etch-stop layer; forming the layered structure; forming openings extending into the layered structure along the first direction; forming the separation structure extending into the layered structure and defining an array region surrounded by the separation structure; forming the capacitors in the array region; and forming the conductive channel outside of the separation structure and extending into the layered structure.

In some implementations, forming the conductive channel outside of the array region includes: depositing a conductive material into at least one of the openings outside of the array region.

In some implementations, the method includes at least partially removing the etch-stop layer outside of the array region.

In some implementations, the method includes recessing a portion of the word line in the array region.

In some implementations, the method includes forming a contact structure, and forming a plurality of conductive channels including the conductive channel. The contact structure is coupled to at least one of the plurality of conductive channels includes the conductive channel.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices.

FIG. 2A illustrates an example semiconductor device with multiple memory dies.

FIG. 2B illustrates a simplified cross-sectional view of an example of a semiconductor device with two structures.

FIG. 2C illustrates a simplified cross-sectional view of an example of a semiconductor device with three structures.

FIGS. 2D and 2E illustrate simplified cross-sectional views of example semiconductor devices with four structures.

FIG. 2F illustrates a simplified cross-sectional view of an example semiconductor device with two semiconductor devices of FIG. 2D stacked together.

FIG. 2G illustrates a simplified cross-sectional view of another example semiconductor device with two semiconductor devices of FIG. 2E stacked together.

FIG. 3 illustrates a side view of a high bandwidth memory (HBM).

FIG. 4A illustrates a three-dimensional view of an example memory structure.

FIG. 4B illustrates a plan view of a part of a separation structure.

FIG. 4C illustrates a cross-sectional view of an example semiconductor device with through-silicon-contact (TSC) conductive channels.

FIG. 4D illustrates a cross-sectional view of an example semiconductor device with bit line (BL) conductive channels.

FIG. 4E illustrates a cross-sectional view of an example semiconductor device with word line (WL) conductive channels.

FIG. 5 illustrates an example of a semiconductor device with a memory structure and a control structure.

FIG. 6 illustrates an example of a semiconductor device with two memory structures and two control structures.

FIG. 7A illustrates an example of a semiconductor device with a first implementation of TSC conductive channels.

FIG. 7B illustrates an example of a semiconductor device with a second implementation of TSC conductive channels.

FIG. 8 illustrates an example of a semiconductor device with BL conductive channels and WL conductive channels.

FIG. 9 is a flow chart of an example process for forming a semiconductor device with at least one memory structure and at least one control structure.

FIG. 10 illustrates a plan view of a memory structure with TSC conductive channels.

FIGS. 11A and 11B illustrate cross-sectional views of the memory structure of FIG. 10 with two implementations of TSC conductive channels.

FIG. 12 illustrated a cross-sectional view of a semiconductor device with the first implementations of TSC conductive channels.

FIGS. 13A through 13C illustrate cross-sectional views of a memory structure of FIG. 12 at various stages of a fabrication process.

FIG. 14 illustrated a cross-sectional view of a semiconductor device with the second implementations of TSC conductive channels.

FIGS. 15A through 15D illustrate cross-sectional views of a memory structure of FIG. 14 at various stages of a fabrication process.

FIG. 16 is a flow chart of an example process for forming a semiconductor device with TSC conductive channels.

FIG. 17 illustrates a plan view of a semiconductor device with BL conductive channels.

FIGS. 18A through 18C are cross-sectional views of different implementations of a semiconductor device in a view similar to the A-A′ axis of the semiconductor device of FIG. 17.

FIG. 19 is a flow chart of an example process for forming a semiconductor device with BL conductive channels.

FIG. 20 illustrates a plan view of a semiconductor device with WL conductive channels.

FIGS. 21A and 21B are cross-sectional views of different implementations of a semiconductor device in a view similar to the A-A′ axis of the semiconductor device of FIG. 20.

FIGS. 22A through 22C illustrated cross-sectional views of the semiconductor device of FIG. 21A at various stages of a fabrication process.

FIGS. 23A through 23C illustrated cross-sectional views of the semiconductor device of FIG. 21B at various stages of a fabrication process.

FIG. 24 is a flow chart of an example process for forming a semiconductor device with WL conductive channels.

It is to be understood that the various exemplary implementations shown in the figures are merely illustrative representations and are not necessarily drawn to scale.

### DETAILED DESCRIPTION

In a DRAM memory device, a memory array can include a plurality of memory cells. A memory cell can include a capacitor and a transistor. A memory device can include word lines and bit lines coupled to corresponding transistors. A memory device can further include conductive structures, which can be vertical electrical connections that at least partially extend through a wafer. The conductive structures can couple word lines and bit lines to a memory control circuitry for controlling the operations, e.g., reading and writing, of memory arrays. Conductive structures can also be used to enable communication with another wafer. In some situations, due to manufacturing cost concern, the conductive structures may have a large critical dimension, which in turn reduces storage density of the memory device. Increasing memory storage density without significantly increasing the manufacturing cost can be challenging.

Implementations of the present disclosure provide semiconductor devices and methods to form such semiconductor devices. In some implementations, a semiconductor device includes a plurality of array structures. An array structure of the plurality of array structures includes a plurality of memory cells. A memory cell of the plurality of memory cells includes a transistor and a capacitor that are stacked together along a first direction. A separation structure is provided which is surrounding the capacitors of the array structure, and the separation structure extends along the first direction. A connection structure is provided adjacent to the separation structure. The connection structure includes a layered structure and a conductive channel extending into the layered structure along the first direction. The separation structure separates the capacitors of the array structure from the connection structure.

In some implementations, a semiconductor device includes a plurality of array structures. An array structure of the plurality of array structures includes a plurality of memory cells. A memory cell of the plurality of memory cells includes a transistor and a capacitor that are stacked together along a first direction. A separation structure is provided which is surrounding the capacitors of the array structure. A connection structure is provided, which includes a layered structure and a conductive channel extending into the layered structure along the first direction. The separation structure separates the capacitors of the array structure from the connection structure. A first contact structure is coupled to a first end of the conductive channel. A second contact structure is coupled to a second end of the conductive channel.

In some implementations, a semiconductor device includes a plurality of array structures. An array structure of the plurality of array structures includes a plurality of memory cells. A memory cell of the plurality of memory cells includes a transistor and a capacitor that are stacked together along a first direction. A separation structure is provided which is surrounding the capacitors of the array structure. A connection structure is provided, which includes a layered structure and a conductive channel extending into the layered structure along the first direction. The separation structure separates the capacitors of the array structure from the connection structure. A bit line is provided extending along a second direction perpendicular to the first direction and coupled to the transistor. The conductive channel is coupled to the bit line.

In some implementations, a semiconductor device includes a plurality of array structures and a word line. An array structure of the plurality of array structures includes a plurality of memory cells. A memory cell of the plurality of memory cells includes a transistor and a capacitor that are stacked together along a first direction. A separation structure is provided which is surrounding the capacitors of the array structure. A connection structure is provided, which includes a layered structure and a conductive channel extending into the layered structure along the first direction. The separation structure separates the capacitors of the array structure from the connection structure. The conductive channel is coupled to the word line.

Implementations of the present disclosure can provide one or more of the following technical advantages and/or benefits. For example, the technologies described in the present disclosure can reduce manufacturing cost by reducing the process steps needed to form conductive channels, which can be used for padding out word line (WL) and bit line (WL) and/or for coupling to other structures (e.g., memory structures and/or control structures). Instead of having separate process steps to form these conductive channels, they can be formed at least partially together with capacitors in memory cells. For example, a full print photolithography mask can be deployed to define patterns for both capacitors and conductive channels in both memory array regions and space between adjacent memory arrays. Therefore, a manufacture cost can be reduced, and the manufacture process can be streamlined. Further, the technologies described in the present disclosure can simplify bonding process between a control structure (e.g., a Complementary Metal Oxide Semiconductors (CMOS) wafer) and a memory structure by reducing the requirement of a carrier wafer. Employment of a carrier wafer may later require a de-bonding process. Without a de-bonding process, mechanical stress and surface damages can be mitigated, thereby enhancing the reliability of the semiconductor device. In some implementations, bit lines and/or word lines are coupled out from a front side of a semiconductor device through the conductive channels, which can reduce the complexity of manufacture process. In addition, the conductive channels can have pitch and critical dimensions (CD) identical or substantially similar to those of the capacitors in the memory arrays, thereby providing smaller area, better uniformity and higher storage capacity. It can also provide flexibility in selecting a desired number of conductive channels for parallel connections. Connecting multiple conductive channels in parallel can reduce resistance, and thus reduce energy consumption. Adjacent conductive channels can be separated by one or more dummy channels, which can lower parasitic capacitance. Additionally, the technologies described in the present disclosure can enable stacking of multiple memory dies in a high bandwidth memory (HBM) by connecting memory dies to a base die and/or a computing die through conductive channels. The conductive channels can be through-silicon-contacts (TSC).

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

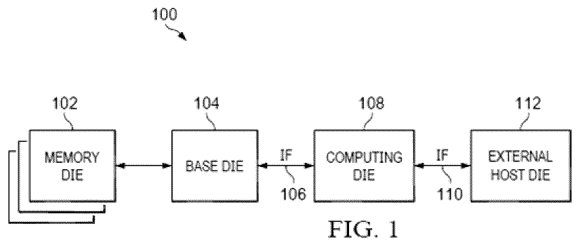

FIG. 1 illustrates a block diagram of an example system 100 having one or more semiconductor devices (e.g., memory devices), according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include one or more memory dies 102, a base die 104, a computing die 108, and an external host die 112. In some implementations, each of dies 102, 104, 108, and 112 can be a die or multiple dies stacked together. Each of dies 102, 104, 108, and 112 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some implementations, each die is encapsulated in a protective package, providing physical support, protection from environmental factor, and connections (e.g., through pins or solder balls) to external devices or system.

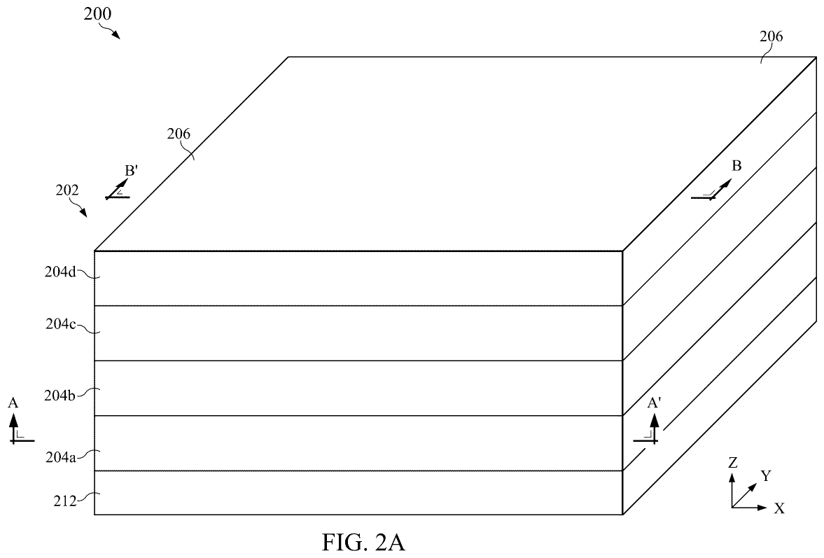

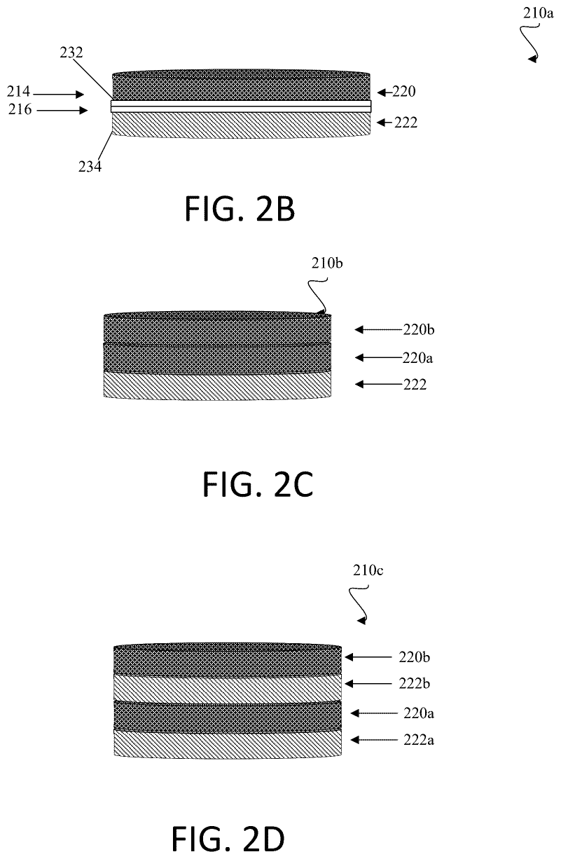

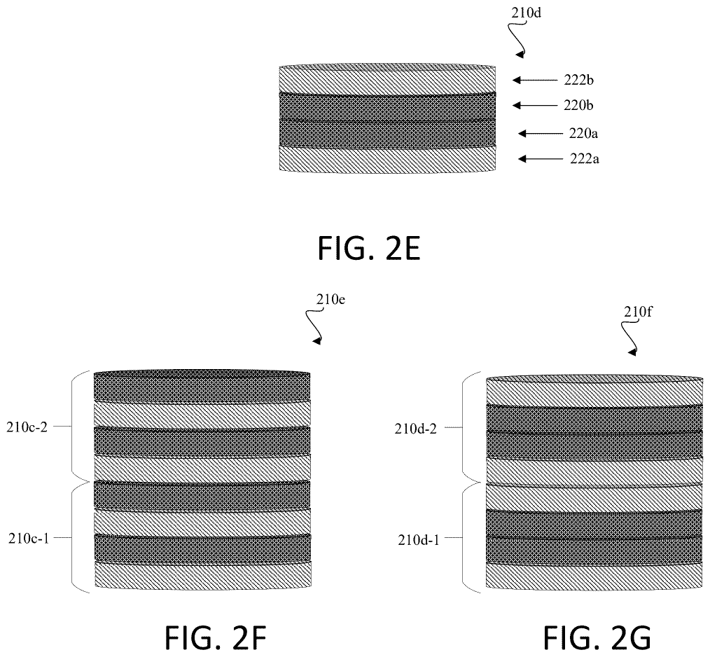

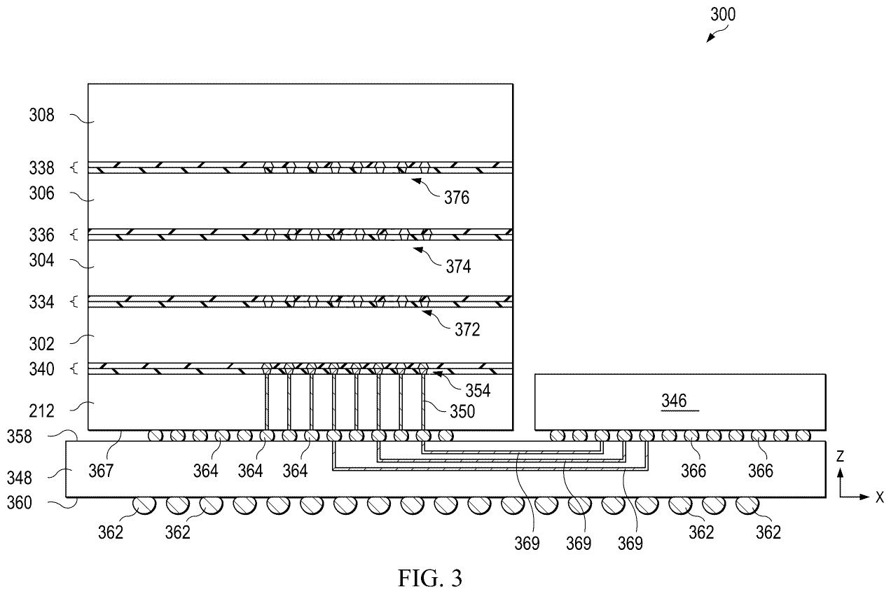

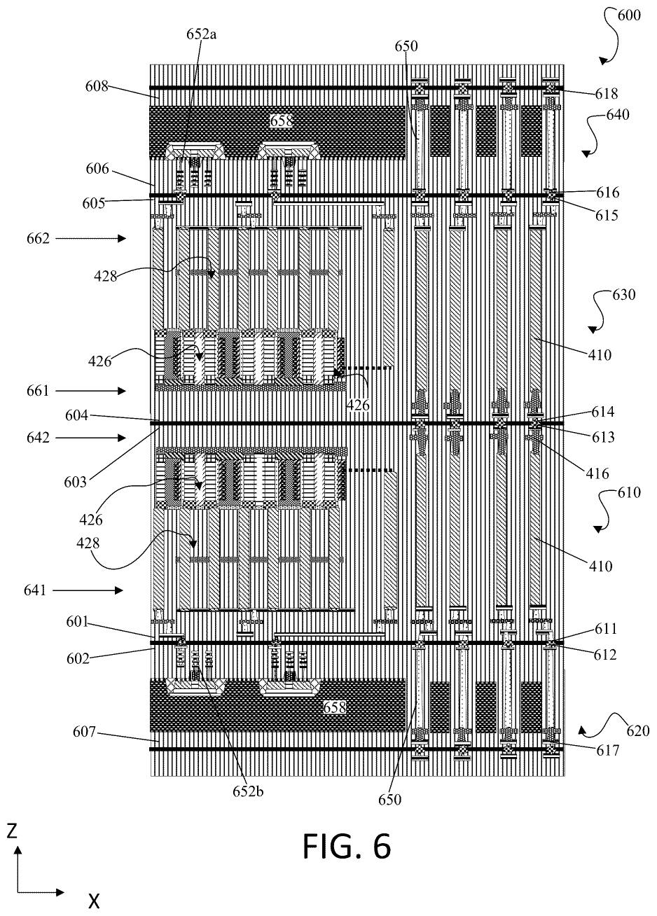

Memory dies 102 can include any memory device disclosed herein, such as a memory device (e.g., a 3D memory device) based on any one of semiconductor structures as described with respect to FIGS. 2A-2E, 3A-3D, 4A-4J, 6A-6D, and 7A-7M. In some implementations, memory dies 102 include one or more dynamic random access memory (DRAM) devices. In some implementations, memory dies 102 include one or more NAND Flash memories. In some implementations, memory dies 102 can include a high bandwidth memory (HBM). In some implementations, memory dies 102 can be stacked together, e.g., as described in further detail with respect to FIGS. 2A-2E, 3A-3D, and 6A-6D. In some implementations, memory dies 102 can include a combination of one or more HBM devices as described with respect to FIGS. 2C and 3A-3D and one or more HBM devices as described with respect to FIGS. 2D and 6A-6D.

Base die 104 (also referred to as a logic die or a buffer die) can include buffer circuitry and test logic for memory dies 102. Base die 104 can be configured to provide physical layer communication protocols (e.g., IEEE-1500) between memory dies 102 and computing die 108. Base die 104 can be configured to transmit data between memory dies 102 and computing die 108 based on control commands and addresses from computing die 108.

Computing die 108 can be a logic device and can include at least one processor of an electronic device, such as a central processing unit (CPU), a graphics processing unit (GPU), an application-specific integrated circuit (ASIC), or a system-on-chip (SoC), such as an application processor (AP). Computing die 108 can be configured to send or receive data to or from memory dies 102. Computing die 108 is coupled to base die 104 through an interface 106. Interface 106 can include connections provided by connecting structures (e.g., as described with respect to FIGS. 3A and 6A) or an interposer (e.g., as described with respect to FIGS. 3D and 6D). In some implementations, interface 106 includes connections provided by any suitable combination of the aforementioned techniques.

System 100 can further include the external host die 112 coupled to computing die 108 through an interface 110. For example, external host die 112 can be a computer, and computing die 108 can be a CPU of the computer. In this example, interface 110 includes connections provided by a mainboard of the computer that are coupled to the CPU. As another example, external host die 112 is a graphics card, computing die 108 is a GPU of the graphics card, and interface 110 includes connections provided by a printed circuit board (PCB) of the graphics card that are coupled to the GPU.

System 100 may further include a memory controller (a.k.a., a controller circuit, which is not shown in FIG. 1) coupled to memory dies 102. In some implementations, the memory controller is located in the computing die 108. Consistent with implementations of the present disclosure, the memory controller can include conductive interconnections through a cover layer that are in contact with conductive pads in a conductive pad layer, and the memory controller can be coupled to memory dies 102 through at least one of the conductive interconnections. The memory controller is configured to control memory dies 102. For example, the memory controller may be configured to operate channel structures via word lines. The memory controller can manage data stored in memory dies 102 and communicate with computing die 108.

In some implementations, the memory controller is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller is designed/configured for operating in a high duty cycle environment SSDs or embedded multi-media-cards (eMMCs) used as data storage for mobile devices, such as smartphones, tablets, laptop computers, etc., and enterprise storage arrays. The memory controller can be configured to control operations of memory dies 102, such as read, erase, and program (or write) operations. The memory controller can also be configured to manage various functions with respect to the data stored or to be stored in memory dies 102 including, but not limited to bad-block management, garbage collection, logical-to-physical address conversion, wear leveling, etc. In some implementations, the memory controller is further configured to process error correction codes (ECCs) with respect to the data read from or written to memory dies 102. In some other implementations, the base die 104 instead of the memory controller is configured to process ECCs. Any other suitable functions may be performed by the memory controller as well, for example, formatting memory dies 102.

The memory controller can communicate with an external device (e.g., computing die 108) according to a particular communication protocol. For example, the memory controller may communicate with the external device through at least one of various interface protocols, such as a USB protocol, an MMC protocol, a peripheral component interconnection (PCI) protocol, a PCI express (PCIe or PCI-e) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller and one or more memory dies 102 can be integrated into various types of storage devices, for example, be included in the same package, such as a universal Flash storage (UFS) package or an eMMC package. That is, system 100 can be implemented and packaged into different types of end electronic products. For example, the memory controller and a single memory die 102 may be integrated into a memory card. The memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

FIGS. 2A-2E illustrate example semiconductor devices 200, according to some aspects of the present disclosure. The semiconductor device 200 can be used to form a memory device, e.g., a high bandwidth memory (HBM).

It is noted that X, Y, and Z axes (also referred to as X, Y, and Z directions) are included in FIG. 2A to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure, however, the X-Y axis may be different for different figures.

As shown in FIG. 2A, the semiconductor device 200 includes a stack 202 of memory dies 204a-204d. Each of the memory dies 204a-204d can be a dynamic random access memory (DRAM) device. The memory dies 204a-204d are stacked (e.g., sequentially) along a vertical direction (e.g., the Z direction). Each of the memory dies 204a-204d can include one or more memory structure and one or more control structure, as described in further detail below with reference to FIGS. 2B-2D. Each memory structure includes at least one memory array and/or a peripheral circuity. The memory array can include an array of memory cells, and the peripheral circuity can be coupled to the memory array. The memory dies 204a-204d can be referred to generally as memory dies 204 and individually as memory die 204.

In some implementations, adjacent memory dies (e.g., memory dies 204a and 204b) among the memory dies 204a-204d are bonded through a corresponding bonding layer (not shown in FIG. 2A). The semiconductor device 200 can further include a base die 212. The stack 202 can be stacked on the base die 212 along the vertical direction. In some implementations, memory die 204a and the base die 212 are bonded through another bonding layer (not shown in FIG. 2A).

FIGS. 2B-2E illustrated simplified cross-sectional views of example semiconductor devices 210a, 210b, 210c, 210d, 210e, 210f. The semiconductor devices 210a, 210b, 210c, 210d, 210e, 210f can be referred to generally as semiconductor devices 210 and individually as semiconductor device 210. A semiconductor device 210 can be diced into one or more memory dies 204. As shown in FIGS. 2B-2E, each memory die 204 can have multiple structures (e.g., memory structure and/or control structure) vertically stacked together.

FIG. 2B illustrates a simplified cross-sectional view of an example of a semiconductor device 210a with two structures. In some implementations, as illustrated in FIG. 2B, the semiconductor device 210 includes a memory structure 220 and a control structure 222 that is coupled to the memory structure 220. The memory structure 220 can include one or more memory substructures. In some implementations, the memory structure 220 is the size of a wafer, while the memory substructure is the size of a die. Each memory substructure can include one or more memory arrays. The control structure can include one or more control substructure. Each control substructure can include control circuitries to control the operations of memory cells in the memory arrays. The control circuitry can include, without limitation to, sense amplifiers, word line drivers, input-output (I/O) circuitry, address decoders, row and column address buffers, read/write control logic, row and column decoders, or any other suitable circuitry. In some implementations, the semiconductor device 210 includes a memory die 204, and the memory die 204 includes one memory substructure and one control substructure.

As illustrated in FIG. 2B, the memory structure 220 can be integrated on top of the control structure 222. A conductive channel (e.g., as shown in FIG. 6) can be formed in the memory structure 220. The conductive channel can be used to establish the communication with the control circuits in the control structure 222 and/or external devices, e.g., a power source.

In some implementations, the integration of the memory structure 220 and the control structure 222 is conducted through a direct bonding technique. As shown in FIG. 2B, a first bonding layer 232 are in a first side 214 of the memory structure 220, and a second bonding layer 234 are in a first side 216 of a control structure 222. The first side 214 of the memory structure 220 and the first side 216 of the control structure 222 can be bonded with the first bonding layer 232 being in contact with the second bonding layer 234. In some implementations, the first and second bonding layers 232, 234 are not separate layers deposited onto the memory structure 220 and control structure 222. For example, the bonding layers 232, 234 can refer to a bonding interface with diffused atoms between two semiconductor structures 220, 222 after thermal treatment. In some implementations, the bonding layers 232, 234 are separate layers deposited onto the memory structure 220 and control structure 222 for bonding (e.g., gluing) and not part of the structures 220, 222.

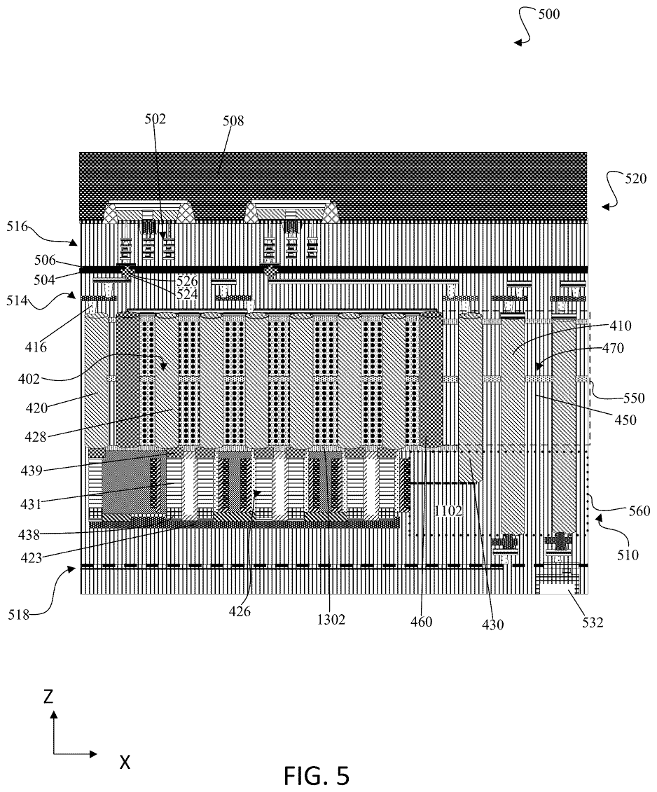

In some implementations, the integration of the memory structure 220 and the control structure 222 is conducted through a hybrid bonding technique with conductive contacts at the interface of two structures, as described in further detail below with reference to FIG. 5.

FIG. 2C illustrates a simplified cross-sectional view of an example of a semiconductor device 210b with three structures. The semiconductor device 210b can include two memory structures, e.g., a first memory structure 220a and a second memory structure 220b, and a control structure 222. All three structures can be vertically stacked together. As noted above, the memory structures 220a, 220b can include one or more memory substructure. Each memory substructure can include one or more memory arrays. In some implementations, the semiconductor device 210b includes a memory die 204, and the memory die 204 includes two memory substructures and one control substructure stacked together vertically.

Similar to the semiconductor device 210a, the two memory structures 220a, 220b and the control structure 222 can be integrated through direct bonding or hybrid bonding techniques, as described below in further details with reference to FIG. 6.

FIGS. 2D and 2E illustrate simplified cross-sectional views of example semiconductor devices 210c and 210d with four structures. In both examples, two memory structures 220a, 220b and two control structures 222a, 222b can be stacked together. The first memory structure 220a and the first control structure 222a can form a first structure pair (e.g., a memory die) using bonding techniques (e.g., hybrid bonding), and the second memory structure 220b and the second control structure 222b can form a second structure pair using the same bonding techniques. As illustrated in FIG. 2D, the first structure pair and the second structure pair can form the semiconductor device 210c by bonding the first memory structure 220a and the second control structure 222b (e.g., through hybrid bonding), which can be referred to as ACAC configuration in this disclosure. As illustrated in FIG. 2E, the first structure pair and the second structure pair can form the semiconductor device 210d by bonding the first memory structure 220a and the second memory structure 220b (e.g., through hybrid bonding), which can be referred to as CAAC configuration in this disclosure. The CAAC configuration is described in further details below with reference to FIG. 6.

As noted above, each of the semiconductor devices 210a, 210b, 210c and 210d can be implemented as a memory die 204. One or more memory dies 204 can be stacked together on a base die 212, as shown in FIG. 2A. FIG. 2F illustrates a simplified cross-sectional view of an example integrated semiconductor device 210e with two semiconductor devices 210c-1, 210c-2 stacked together, while FIG. 2G illustrates a simplified cross-sectional view of another example integrated semiconductor device 210f with two semiconductor devices 210d-1, 210d-2 stacked together. Neighboring semiconductor devices, e.g., the semiconductor devices 210c-1, 210c-2 or semiconductor devices 210d-1, 210d-2, can be also integrated together with direct bonding or hybrid bonding techniques. Although not shown, it is to be understood that three or more semiconductor devices 210 can be stacked together. This stacking approach can allow for a more compact design and increase the storage capacity. Such configuration may provide a scalable solution for meeting the growing demands for higher storage capacity in modern electronic devices.

FIG. 3 illustrates a side view of a semiconductor device 300, according to some aspects of the present disclosure. The semiconductor device 300 can include memory dies 302-308, a base die 212, a computing die 346, and an interposer 348. Memory dies 302-308 can be examples of memory dies 102 of FIG. 1, memory dies 204a-204d of FIG. 2A (e.g., DRAMs), or semiconductor devices 210a-210f of FIGS. 2B-2G. Memory dies 302-308 and base die 212 can be stacked (e.g., sequentially) along the Z direction. Base die 212 and computing die 346 can be integrated on different positions of the interposer 348 along the X direction. The semiconductor device 300 can be called as a high bandwidth memory (HBM) in some cases.

As shown in FIG. 3, the semiconductor device 300 includes bonding layers (e.g., bonding layers 334, 336, and 338) between adjacent memory dies of memory dies 302-308 and a bonding layer 340 between memory die 302 and base die 212. Each of these bonding layers can include a dielectric material such as silicon oxide.

In some implementations, bonding layers 340, 334, 336, and 338 can be referred to as direct bonding layers. Each of bonding layers 340, 334, 336, and 338 can include at least one dielectric material and exclude a conductive connecting structure. In some implementations, bonding layers 340, 334, 336, and 338 can be referred to as hybrid bonding layers. As show in FIG. 3, bonding layers 340, 334, 336, and 338 can include conductive contacts 354, 372, 374, 376, and at least one dielectric material isolating the connecting structures. Conductive contacts between adjacent memory dies (e.g., conductive contacts 372, 374, 376) can be configured to connect the memory dies 302, 304, 306, 308, as described in further detail below with reference to FIG. 6. Conductive contacts 354 can be configured to connect memory die 302 and base die 212. Conductive contacts can be also referred to as connecting structures in the present disclosure.

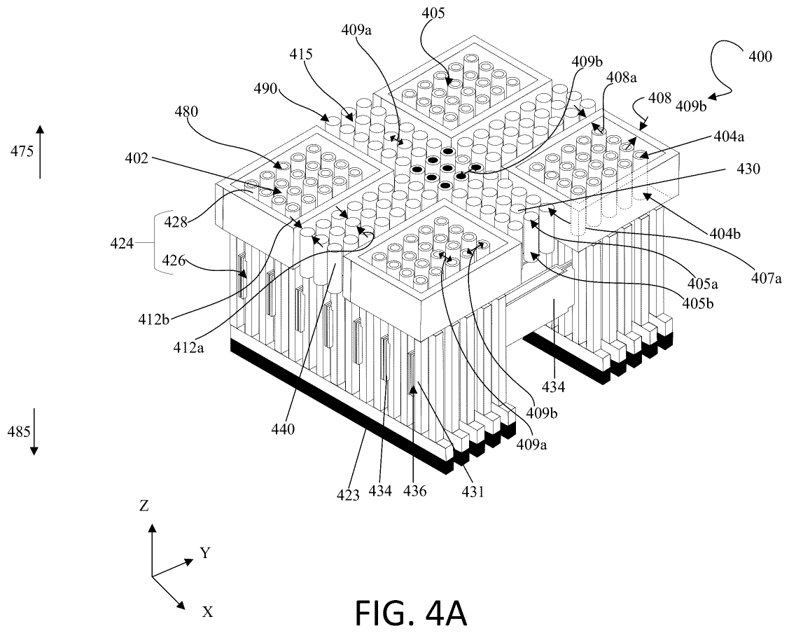

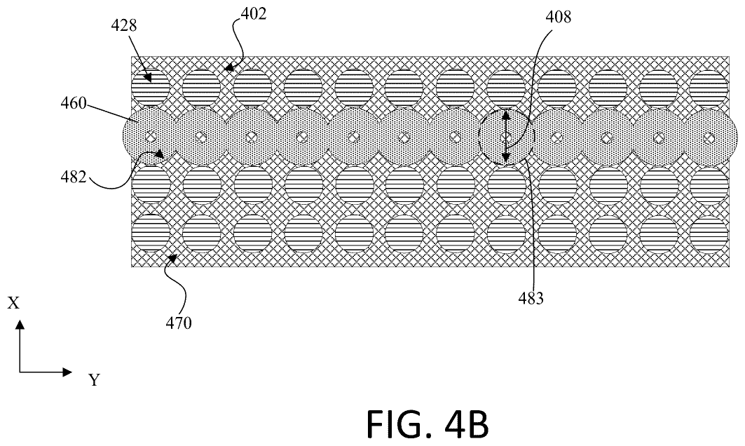

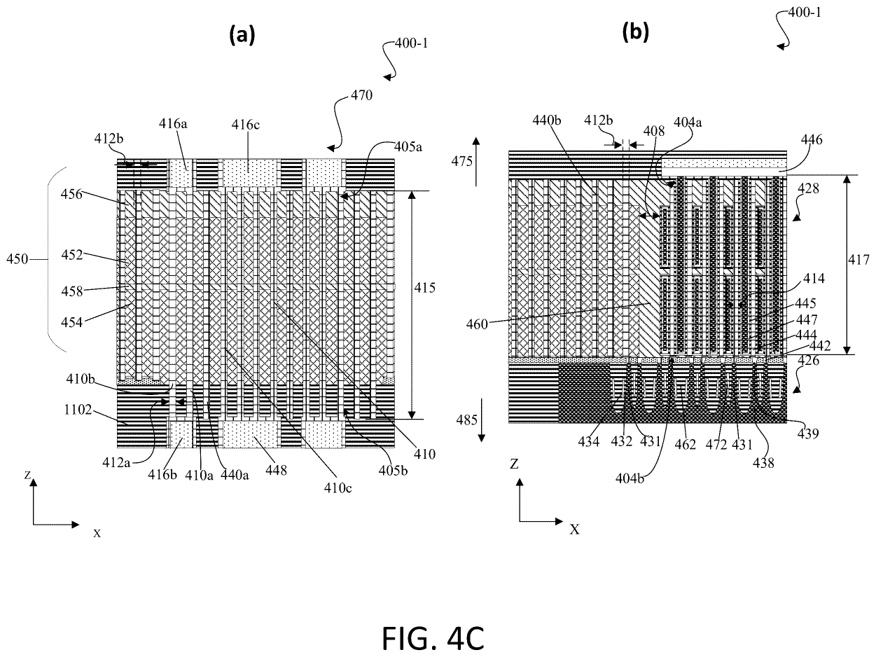

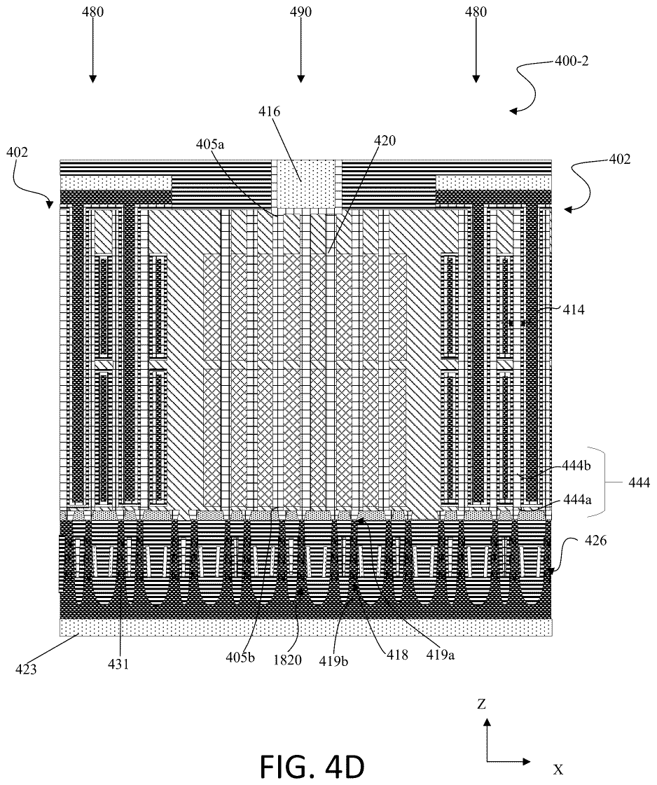

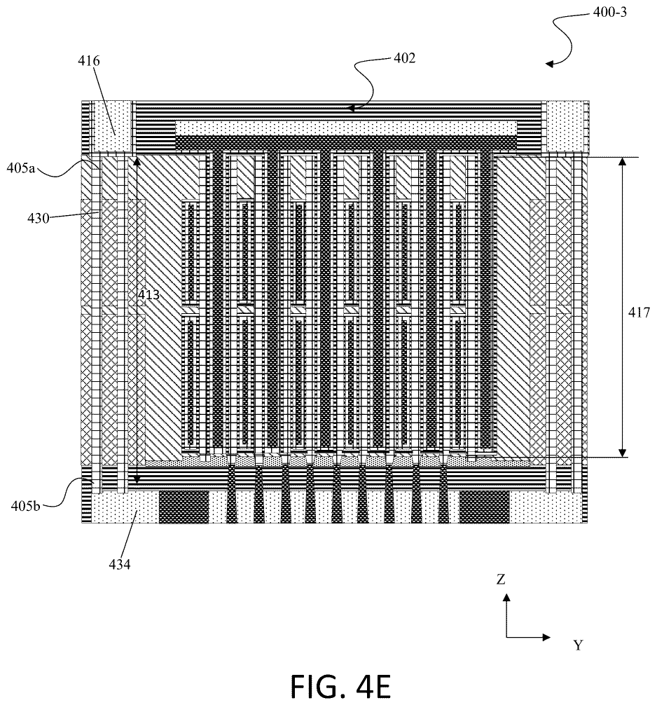

In some implementations, each memory die 302, 304, 306, 308 is coupled to base die 212 through corresponding conductive contacts between adjacent memory dies (e.g., conductive contacts 372, 374, 376) and conductive contacts 354 in bonding layer 340. In some implementations, base die 212 includes vias 350 extending through base die 212 along the Z direction and being connected to conductive contacts 354. In some implementations, vias 350 can be through-silicon-vias (TSV). Structures and electrical connections within each memory die is described later in further detail with respect to FIGS. 4A-8.

In some implementations, base die 212 includes a base control circuitry that is configured to control memory dies 302, 304, 306, 308. The base control circuitry of base die 212 can be coupled to the control circuits in the control substructures of the memory dies 302, 304, 306, 308.

The base die 212 can be coupled to the computing die 346 through the interposer 348. The interposer 348 has a surface 358 and a surface 360. The vias 350 in the base die 212 can be connected to conductive terminals 364 on surface 358 of the interposer 348. The computing die 346 can be connected to conductive terminals 366 on surface 358 of the interposer 348. The semiconductor device 300 can include conductive terminals 362 connected to the surface 360 of the interposer 348. Conductive terminals 364, 366, and 362 can be coupled through conductive lines (e.g., conductive lines 369 as shown in FIG. 3) in the interposer 348. The conductive terminals 362 can be coupled to an external device (e.g., the external host die 112 of FIG. 1). In some implementations, the conductive terminals 364, 366, and 362 can be micro bumps. It is understood that in practice, base die 212, computing die 346, and interposer 348 can be integrated together using any suitable packaging technology including, for example, Chip-on-Wafer-on-Substrate (CoWoS).

In some implementations, as shown in FIG. 3, memory dies 302, 304, 306 can have a reduced thickness (along the Z direction) by having their substrates thinned. The topmost memory die 308 (e.g., the one among memory dies 302, 304, 306, 308 that is farthest away from base die 212) may not be thinned. As a result, a thickness of each of memory dies 302, 304, 306 can be smaller than a thickness of memory die 308. The thickness of each of memory dies 302-308 can be in any suitable range (e.g., between 3 μm and 20 μm).

Although not shown, it is to be understood that the interposer 348, the computing die 346, the base die 212, and the memory dies 302, 304, 306, 308 can be stacked sequentially along Z direction, such that the computing die 346 is between the base die 212 and the interposer 348 along Z direction. Similar to base die 212, computing die 346 can include vias extending through the computing die 346 along the Z direction and being coupled to the interposer 348 through corresponding conductive terminals. This configuration can have more compact configuration along lateral directions shown in FIG. 3.

FIG. 4A illustrates a three-dimensional view of an example memory structure or a part of an example memory structure. The semiconductor device 400 can be the memory structure 220 of FIGS. 2B-2G. FIGS. 4B-4E illustrate cross-sectional views of example memory structures identical or similar to the semiconductor device 400 of FIG. 4A. For ease of description, reference will be made to FIGS. 4A-4C when describing the structure of the semiconductor device 400. It is understood that FIGS. 4A-4E are for illustrative purposes only and may not necessarily reflect the actual device structure in practice.

In some implementations, as illustrated in FIG. 4A, the semiconductor device 400 includes a DRAM device in which memory cells are provided in the form of an array of DRAM cells 424. Each DRAM cell 424 can include a vertical transistor 426 and a capacitor 428 coupled to the vertical transistor 426. DRAM cell 424 can be a 1T1C cell consisting of one transistor and one capacitor. It is understood that DRAM cell 424 may be of any suitable configurations, such as 2T1C cell, 3T1C cell, etc. The vertical transistor 426 can be a MOSFET used to switch a respective DRAM cell 424. In some implementations, the vertical transistor 426 includes a transistor body 431 (the active region in which a channel can form) extending vertically (in the z-direction), and a gate structure 136 coupled to one side of transistor body 431. In a single-gate vertical transistor, the transistor body 431 can have a cuboid shape or a cylinder shape, and the gate structure 436 can abut a single side of transistor body 431 in a plan view, e.g., as shown in FIG. 4A. In some implementations, the vertical transistor 426 has a structure including two or more gates, e.g., a two-gates structure, a three-gates structure, or a gate all around (GAA) structure. In some implementations, the gate structure 436 includes a gate electrode 434 and a gate dielectric 432 (e.g., as illustrated in diagram (b) of FIG. 4C) laterally between the gate electrode 434 and the transistor body 431 in a bit line direction (e.g., in the X direction). In some implementations, the gate dielectric 432 abuts one side of the transistor body 431, and the gate electrode 434 abuts the gate dielectric 432. In some implementations, the gate electrode 434 is not a separate structure from a word line 434, but rather a part of the word line 434.

In some implementations, gate dielectric 432 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 434 includes a conductive material including, but not limited to W, Co, Cu, Al, TiN, TaN, polysilicon, silicide, or any combination thereof. In some implementations, the gate electrode 434 includes multiple conductive layers, such as a W layer over a TiN layer. In one example, the gate structure 436 may be a “gate oxide/gate poly” gate in which the gate dielectric 432 includes silicon oxide and gate electrode 434 includes doped polysilicon. In another example, gate structure 436 may be an HKMG in which gate dielectric 432 includes a high-k dielectric and gate electrode 434 includes a metal.

As shown in FIG. 4A, in some implementations, both ends (the upper end and lower end) of the transistor body 431 extend beyond the gate electrode 434, respectively, in the vertical direction (the z-direction). That is, the transistor body 431 can have a larger vertical dimension (e.g., the depth) than that of the gate electrode 434 (e.g., in the z-direction), and neither the upper end nor the lower end of transistor body 431 is flush with the respective end of the gate electrode 434. Thus, risks of short circuits between the bit lines 423 and the word lines/gate electrodes 434 or between the word lines/gate electrodes 434 and the capacitors 428 can be reduced.

The vertical transistor 426 can further include a source 439 and a drain 438 (e.g., as illustrated in FIG. 5) disposed at the two ends (the upper end and lower end) of the transistor body 431, respectively, in the vertical direction (the z-direction). In some implementations, one of the source and drain (e.g., at the upper end in FIGS. 4A and 5) is coupled to the capacitor 428, and the other one of source and drain (e.g., at the lower end in FIGS. 4A and 5) is coupled to the bit line 423. That is, the vertical transistor 426 can have a first terminal in the positive z-direction and a second terminal opposite the first terminal in the negative z-direction, as shown in FIGS. 4A and 5. In some implementations, the source 439 and the drain 438 are part of the transistor body 431. For example, the source 439 and the drain 438 can be formed by implanting two ends of the transistor body 431 with desired dopants.

Returning to FIG. 4A, in some implementations, the transistor body 431 includes semiconductor materials, such as single crystalline silicon, polysilicon, amorphous silicon, Ge, any other semiconductor materials, or any combinations thereof. In one example, transistor body 431 may include single crystalline silicon. Source 439 and drain 438 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between drain 438 of the vertical transistor 426 and the bit line 423 as the bit line contact or between source 439 of the vertical transistor 426 and the first electrode of the capacitor 428 as capacitor contact to reduce the contact resistance.

As described above, since the gate electrode 434 may be part of a word line (WL) or extend in the word line direction (e.g., the X direction) as a word line, the semiconductor device 400 can also include a plurality of word lines each extending in the word line direction (e.g., Y direction in FIG. 4A). Each word line 434 can be coupled to a row of DRAM cells 424. That is, the bit line 423 and the word line 434 can extend in two perpendicular lateral directions, and the transistor body 431 of the vertical transistor 426 can extend in the vertical direction perpendicular to the two lateral directions in which the bit line 423 and the word line 434 extend. As illustrated in FIG. 4A, word lines 434 can be coupled to WL conductive channels 430. In some implementations, the word lines 434 include conductive materials including, but not limited to W, Co, Cu, Al, TiN, TaN, polysilicon, silicides, or any combination thereof. In some implementations, the word line 434 includes multiple conductive layers, such as a W layer over a TiN layer.

In some implementations, as shown in FIG. 4A, the vertical transistor 426 extends vertically through and couples to the word lines 434, and the drain 438 of vertical transistor 426 at the lower end thereof couples to the bit line 423. Accordingly, the word lines 434 and the bit lines 423 can be disposed in different planes in the vertical direction due to the vertical arrangement of vertical transistor 426. In some implementations, the bit line 423 and the capacitor 428 are disposed on opposite sides of the vertical transistor 426 in the vertical direction, which simplifies the routing of the bit lines 423 and reduces the coupling capacitance between the bit lines 423 and the capacitors 428 compared with DRAM cells in which the bit lines and capacitors are disposed on the same side of the planar transistors.

In some implementations, the vertical transistors 426 can be arranged in a mirror-symmetric manner to increase the density of DRAM cells 424 in the bit line direction (the X direction). As shown in FIGS. 4A and 4C, two adjacent vertical transistors 426 in the bit line direction are mirror-symmetric to one another with respect to a trench isolation 462. That is, the semiconductor device 400 can include a plurality of trench isolations 462 each extending in the word line direction (the Y direction) in parallel with word lines 434 and disposed between vertical gates 434 of two adjacent rows of the vertical transistors 426. In some implementations, the rows of vertical transistors 426 separated by the trench isolation 462 are mirror-symmetric to one another with respect to the trench isolation 462. The trench isolation 462 can be formed with dielectric materials including, but not limited to, silicon oxide, silicon nitride, silicon oxynitride, low-k dielectrics, or any combination thereof. It is understood that the trench isolation 462 may include an air gap each disposed laterally between adjacent vertical gates 434. Air gaps may be formed due to the relatively small pitches of vertical transistors 426 in the bit line direction (e.g., the Y direction). On the other hand, the relatively small dielectric constant of air in air gaps (e.g., about ¼ of the dielectric constant of silicon oxide) can improve the insulation effect between vertical transistors 426 (and rows of DRAM cells 424) compared with some dielectrics (e.g., silicon oxide). Similarly, in some implementations, air gaps are formed laterally between word lines/gate electrodes 434 in the bit line direction as well, depending on the pitches of word lines/gate electrodes 434 in the bit line direction.

In some implementations, as illustrated in diagram (b) of FIG. 4C, instead of the trench isolation 462 having the air gap being disposed between adjacent vertical gates 434 of two adjacent rows of the vertical transistors 426, a shielding contact structure 472 (e.g., including metal such as W) is disposed between adjacent vertical transistor bodies 431. The shielding contact structure 472 can be in contact with at least one of the adjacent transistor bodies 431 and can be coupled to a low voltage (e.g., a fixed negative voltage), which can reduce charge build-up in the memory cells 424, thereby mitigating the floating body effect in the memory cells 424. Moreover, by applying a fixed low voltage on the shielding contact structure 472 between the memory cells 424, a threshold voltage of the memory cells 424 can be conveniently adjusted, which can reduce the overall manufacturing complexity and cost, and improve reliability of the memory cells 424. Further, the shielding contact structure 472 can be coupled out from a same side as word lines or a different side from the word lines. For example, the shielding contact structure 472 can be coupled out from the back side 485 of the semiconductor device 400, while the word lines can be coupled out from the front side 475 of the semiconductor device 400 through the WL conductive channel 430 (e.g., as illustrated in FIG. 4A). The shielding contact structure 472 can be also referred as shielding conductive material in this disclosure. The trench isolation having such shielding contact structure 472 may be also referred to as trench isolation (TISO) in this disclosure.

As shown in diagram (b) of FIG. 4C, in some implementations, a capacitor 428 includes a first electrode 444 above and coupled to the source 439 of vertical transistor 426, e.g., the upper end of the transistor body 431, via a capacitor contact 442. In some implementations, the capacitor contact 442 is an ohmic contact, such as a metal silicide contact, as opposed to a Schottky contact. For example, the capacitor contact 442 may include metal silicides, such as WSi, CoSi, CuSi, AlSi, or any other suitable metal silicides having higher conductivities than doped silicon. The capacitor 428 can also include a capacitor dielectric 445 in contact with the first electrode 444, and a second electrode 447 in contact with the capacitor dielectric 445. In some implementations, the capacitor 428 has a cylindrical shape as shown in FIGS. 4A and 4C. In some implementations, each first electrode 444 is coupled to source 439 of a respective vertical transistor 426 in the same DRAM cell, while all second electrodes 447 are coupled to a common plate 446 which is in turn coupled to the ground, e.g., a common ground. The capacitor 428 can have a first end 404a in the positive z-direction and a second end 404b opposite the first end in the negative z-direction. In some implementations, the second end 404b of the capacitor 428 is coupled to the source terminal 439 of the vertical transistor 426 via an ohmic contact (e.g., the capacitor contact 442 made of a metal silicide material). In some implementations, the semiconductor device 400 can further include a capacitor contact (not shown) in contact with the common plate 446 for coupling the capacitors 428 to control circuits or to the ground directly.

It is to be understood that the structure and configuration of a capacitor 428 are not limited to the example in FIGS. 4A-4E and may include any suitable structure and configuration that extends along Z direction. In some implementations, the capacitor dielectric 445 includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 428 may be a ferroelectric capacitor used in a FRAM cell, and the capacitor dielectric 445 may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As illustrated in FIG. 4A, the semiconductor device 400 can include a plurality of array structures 402. Four array structures 402 are illustrated in FIG. 4A. An array structure 402 can include a plurality of DRAM memory cells. In some implementations, an array structure 402 is surrounded by a separation structure 460. The region within the separation structure 460 can be referred to as an array region 480 in this disclosure, while a region outside of the separation structure 460 can be referred to as a connection region 490 in this disclosure. In some implementations, the separation structure 460 has a wall shape as shown in FIG. 4A. The separation structure 460 separates the capacitors 428 of the array structure 402 from a connection structure 470 in the connection region 490. In some implementations, a height of the separation structure 460 is substantially equal to a height of the capacitor 428. In some implementations, the separation structure 460 includes at least one of silicon carbon nitride (SiCN) or silicon boron nitride (SiBN).

In some implementations, the semiconductor device 400 further includes a connection structure 470 adjacent to the separation structure 460 and located in the connection region 490. The connection structure 470 includes a layered structure 450. In some implementations, as illustrated in diagram (a) of FIG. 4C, the layered structure 450 includes a first dielectric layer 452 and a second dielectric layer 454 stacked together along the Z direction. In some implementations, the layered structure 450 includes a first supporting layer 458 between the first dielectric layer 452 and the second dielectric layer 454, and a second supporting layer 456 stacked over the first dielectric layer 452. In some implementations, the first dielectric layer 452 includes tetraethyl orthosilicate (TEOS), the second dielectric layer 454 includes borophosphosilicate glass (BPSG), and the first supporting layer 458 and second supporting layer 456 include at least one of silicon carbon nitride (SiCN) or silicon boron nitride (SiBN).

In some implementations, the layered structure 450 does not extend into a dielectric body 1102 that is surrounding the transistor 126. As illustrated in FIG. 5 below, the layered structure 450 can be located within the region 550 (enclosed by dashed line), and the layered structure 450 can be disposed above the dielectric body 1102 that is in the region 560 (enclosed by dotted line). In some implementations, the layered structure 450 is positioned at a level higher than the etch-stop layer 1302 along the positive Z direction, as shown in FIG. 5, while the dielectric body 1102 is positioned at a level lower than the etch-stop layer 1302 along the negative Z direction.

In some implementations, the layered structure 450 includes the dielectric body 1102 that is surrounding the transistor 126. Therefore, the layered structures 450 can be located in both regions 550, 560.

Returning to FIGS. 4A and 4B, in some implementations, a material of the separation structure 460 is different from a material of the first dielectric layer of the layered structure 450. For example, the separation structure 460 includes SiBN, while the first dielectric layer of the layered structure 450 does not include SiBN. In some implementations, an edge 482 of the separation structure 460 is wave shaped, as illustrated in FIG. 4B.

In some implementations, the connection structure 470 includes at least one conductive channel extending through the layered structure 450 along Z direction. It is to be understood that in the present disclosure, for ease of description, conductive channels 410, 420, 430 may be referred to by different names in different implementations. For example, conductive channels can be referred to as through-silicon-contact (TSC) conductive channels 410 in reference to FIG. 4C, as BL conductive channels 420 in reference to FIG. 4D, or as WL conductive channels 430 in reference to FIG. 4E. It is further to be understood that the terms “TSC” in “TSC conductive channels,” “BL” in “BL conductive channels,” and “WL” in “WL conductive channels” are not intended to be construed in limited sense.

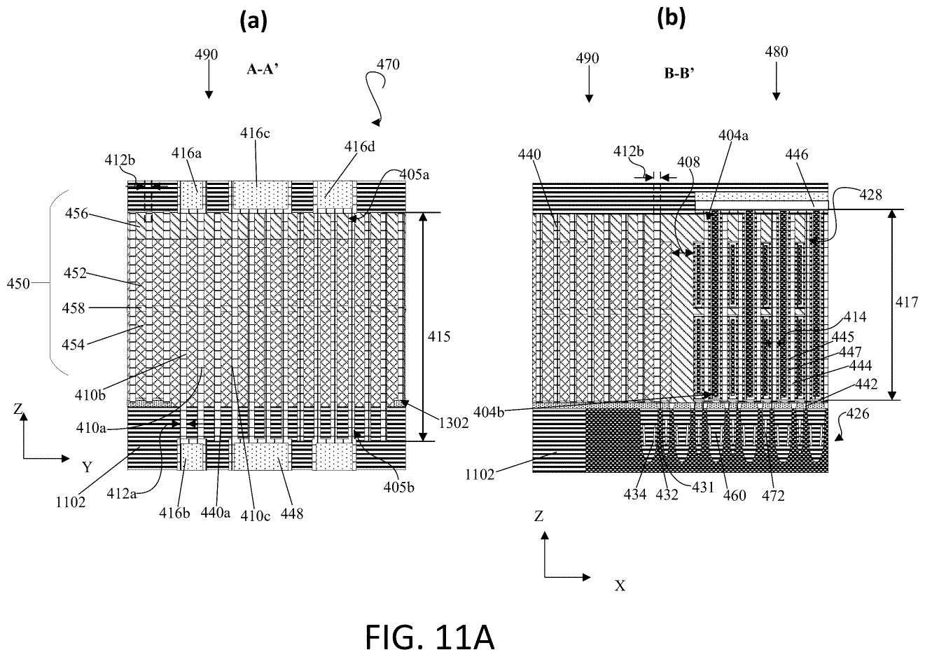

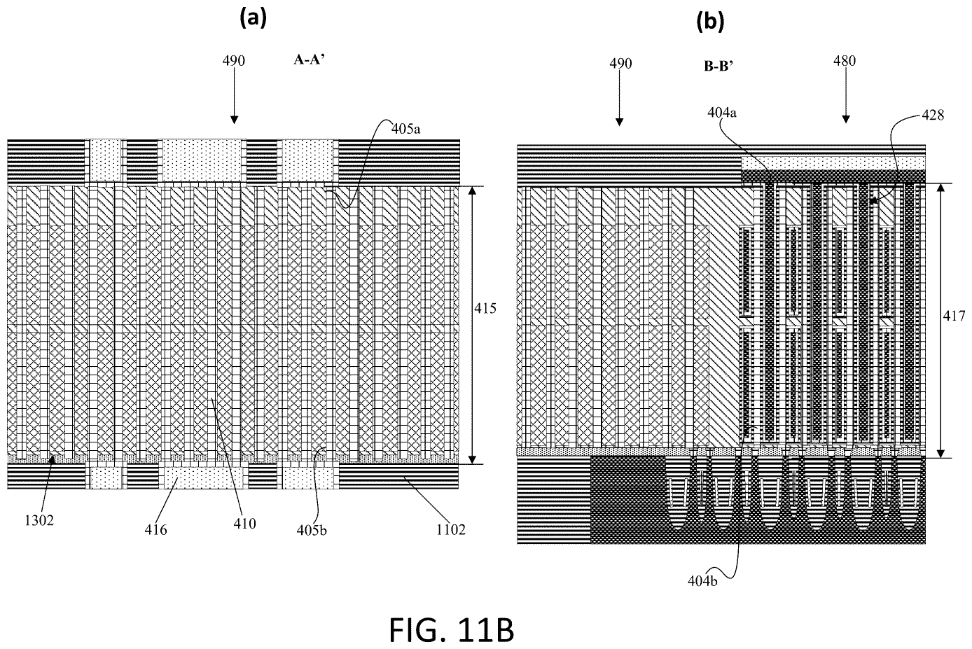

The WL conductive channels 430 are coupled to the word line 434, and the BL conductive channels 420 are coupled to the bit line 423. The TSC conductive channels 410 can be coupled to another structure (e.g., a control structure, or another memory structure). In some implementations, the conductive channel includes at least one of tungsten (W), polysilicon, or titanium intrude (TiN). Structures of TSC, BL and WL conductive channels 410, 420, 430 are described in further detail below with reference to FIGS. 4C, 4D and 4E, respectively. TSC conductive channels 410, BL conductive channels 420, and WL conductive channels 430 can be referred to generally as conductive channels and individually as a conductive channel in the present disclosure. It is to be understood that despite the term “TSC” (through-silicon-contact), the TSC conductive channel does not necessarily extend through a silicon substrate; instead, it can extend at least partially into a layered structure 450 and/or a dielectric body 1102, as shown in FIGS. 4C, 11A and 11B.

In some implementations, the WL conductive channel 430 is located between two adjacent memory array structures 402 along WL direction (e.g., Y direction of FIG. 4A), the BL conductive channel 420 is located between two adjacent memory array structures 402 along BL direction (e.g., X direction of FIG. 4A), and the TSC conductive channel 410 is located in the center of four surrounding array structures 402, as illustrated in FIG. 4A. It is to be understood that although not shown, the TSC conductive channel 410 can be located between any adjacent array structures 402. It is further to be understood that although FIG. 4A shows all three types of conductive channels are present in the semiconductor device 400, a memory structure or a semiconductor device can include only any one or two of these types. For example, a semiconductor device can include only the TSC conductive channels 410, or a semiconductor device can include the TSC conductive channels 410 and BL conductive channels 420, but not the WL conductive channels 430.

As illustrated in FIGS. 4A and 4C, in some implementations, the connection structure 470 includes at least one dummy channel 440 extending through the layered structure 450 along Z direction. Unlike conductive channels where both ends of the conductive channels are electrically coupled to conductive materials (e.g., word line 434, bit line 423, and/or contact structures 416 as described below), at least one end of the dummy channel 440 is not electrically connected to any component or structure that is conductive.

In some implementations, as illustrated in FIG. 4A, the dummy channel 440 is between the conductive channel and the separation structure 460. In some implementations, the dummy channel 440 is between adjacent TSC conductive channels 410. For example, as illustrated in diagram (a) of FIG. 4C, the dummy structure 440a can be between adjacent TSC conductive channels 410a, 410b. In some implementations, the dummy channel 440 is surrounding the separation structure 460. For example, as illustrated in diagram (b) of FIG. 4C, the dummy structure 440b can be surrounding the separation structure 460.

In some implementations, a size of the dummy channel 440 is equal to a size of the conductive channel. For example, as shown in diagram (a) of FIG. 4C, a diameter 412b of the dummy channel 440a can be equal to a diameter 412a of the conductive channel in the X-Z plane. In another example, a height 415 of the dummy channel 440a can be equal to a height 415 of the TSC conductive channel 410c along Z direction.

In some implementations, different dummy channels 440 have different heights along the first direction. For example, the dummy structure 440a (e.g., as illustrated in diagram (a) of FIG. 4C) between adjacent TSC conductive channels 410 can have a greater height than the dummy structure 440b that is adjacent to the separation structure 460 along Z direction (e.g., as illustrated in diagram (b) of FIG. 4C).

In some implementations, the dummy channel 440 includes a material different from a material of the conductive channel. For example, the conductive channel can include W and TiN, whereas the dummy channel 440 includes polysilicon. In some implementations, the dummy channel 440 includes a dielectric material, e.g., silicon carbide.

In some implementations, the TSC conductive channels 410, the WL conductive channels 430, and the BL conductive channels 420 have a uniform size. The uniform size can refer to substantially identical size. For example, the TSC conductive channels 410, the WL conductive channels 430 and the BL conductive channels 420 have the same or substantially identical diameter in the X-Y plane. In some implementations, as illustrated in FIG. 4A, the capacitors 428 and the conductive channels have same or substantially identical pitch 409a along X direction and/or uniform pitch 409b along Y direction.

As noted above, the capacitor 428 can have a first end 404a in the positive z-direction and a second end 404b opposite the first end 404a in the negative z-direction, as shown in FIG. 4A. Similarly, the conductive channel has a first end 405a in the positive z-direction and a second end 405b opposite the first end 405a in the negative z-direction. In some implementations, the first end 405a of the conductive channel is substantially coplanar with the first end 404a of the capacitor 428. Similarly, in some implementations, a first end 407a of the dummy channel 440 is substantially coplanar with the first end 404a of the capacitor 428.

In some implementations, a size of the conductive channel is smaller than a width of the separation structure 460 along BL direction or WL direction. For example, as illustrated in diagram (a) and (b) of FIG. 4C, the diameter 412a of the TSC conductive channel 410 is smaller than a width 408 of the separation structure 460 along BL direction. In some implementations, as illustrated in FIG. 4B, an edge 482 of the separation structure 460 is wave shaped, and the width 408 of the separation structure 460 can be measured at one of the portions 483 (enclosed by dashed line) with the greatest width.

In some implementations, as shown in FIGS. 4C-4D, the capacitor 428 extends along Z direction and includes a first electrode 444, a second electrode 447, and a capacitor dielectric 445 between the first electrode 444 and the second electrode 447. The first electrode 444 is coupled to the transistor 426. As shown in FIG. 4D, the first electrode 444 can include two parts, a first part 444a and a second part 444b. The first part 444a can be positioned between the second part 444b and the corresponding transistor 426 along z direction. The first part 444a can have a greater lateral dimension (e.g., diameter) along x direction but a smaller dimension (e.g., height or thickness) along z direction compared to the second part 444b. In some implementations, the second part 444b has a cylindrical shape where its longitudinal axis extends along z direction. In some implementations, an outer size 414 of the first electrode 444 is equal to a size of the conductive channel. The outer size 414 of the first electrode 444 can be, for example, an outer diameter of the second part 444b, which is measured by a diameter of the cylindrical-shaped second part 444b of the first electrode 444 along x direction.

FIGS. 4C-4E illustrates cross-sectional views of example semiconductor devices with a first implementation of TSC conductive channels, BL conductive channels and WL conductive channels, respectively. It is to be noted that more implementations of TSC conductive channels, BL conductive channels and WL conductive channels are described in greater detail below with reference to FIGS. 5-24.

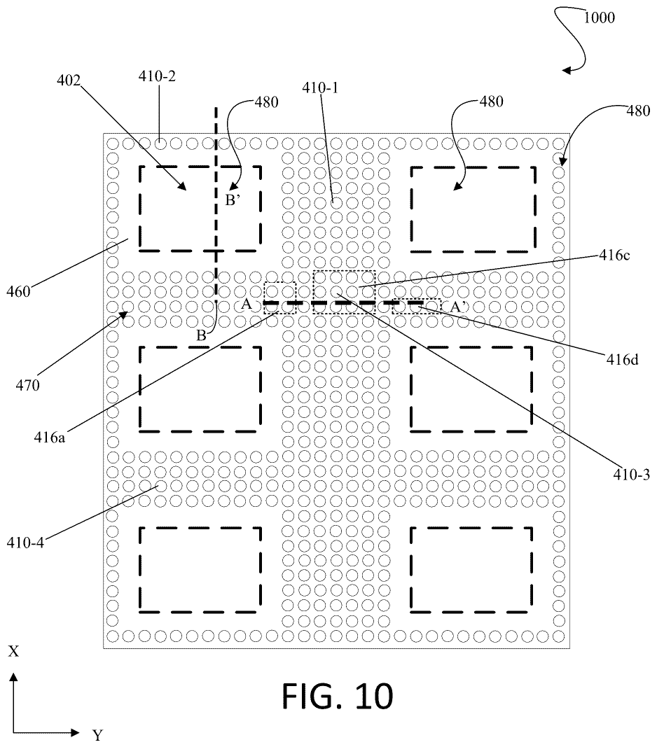

FIG. 4C illustrates a cross-sectional view of an example semiconductor device 400-1 with conductive channels 410. The conductive channels 410 can be referred to as TSC conductive channels 410 in the present disclosure when described in reference to FIG. 4C. The semiconductor device 400-1 can be implemented as the semiconductor device 400 of FIG. 4A. Diagram (a) of FIG. 4C is an X-Z cross-sectional view of connection structure 470, while diagram (b) of FIG. 4C is an X-Z cross-sectional view of the example semiconductor device near an array structure 402. X axis of FIG. 4C can be the BL direction. It is to be noted that more implementations of TSC conductive channels 410 are described in further detail below with respect to FIGS. 10-16.

As illustrated in diagram (a) of FIG. 4C, the first end 405a of the TSC conductive channel 410a is coupled to a first contact structure 416a. A second end 405b of the TSC conductive channel 410a is opposite to the first end 405a of the TSC conductive channel 410a along the first direction (e.g., Z direction) and coupled to a second contact structure 416b. In other words, both ends of the TSC conductive channel 410a can be electrically coupled to corresponding contact structures 416, and the TSC conductive channel 410a can be disposed between two contact structures 416 along the first direction (e.g., Z direction).

In some implementations, the first contact structure 416a and the second contact structure 416b are coupled to two ends of the same one or more TSC conductive channels. For example, the first contact structure 416a is coupled to first ends 405a of the first TSC conductive channel 410a and the second TSC conductive channel 410b. Correspondingly, the second contact structure 416b is coupled to second ends 405b of the exact same TSC conductive channels 410, that is, the first TSC conductive channel 410a and the second TSC conductive channel 410b.

In some implementations, as illustrated below in FIG. 5, one end of the TSC conductive channel 410 is coupled to a control structure 520 (e.g., a CMOS wafer) through corresponding contact structures 416, while the other end of the TSC conductive channel 410 is coupled to a power source structure 532.

Referring back to diagram (a) of FIG. 4C, in some implementations, the semiconductor device 400-1 further includes a third contact structure 416c. The third contact structure 416c can be coupled to at least one TSC conductive channel 410, and adjacent TSC conductive channels 410 coupled to the first contact structure 416a and the third contact structure 416c are spaced from each other by at least one dummy channel 440 between the adjacent TSC conductive channels 410. For example, as illustrated in the diagram (a) of FIG. 4C, the first contact structure 416a can be coupled to the first TSC conductive channel 410a, while the third contact structure 416c can be coupled to the third TSC conductive channel 410c. The first TSC conductive channel 410a and the third TSC conductive channel 410c can be spaced from each other by the dummy channel 440a that is not electrically connected to any contact structure at one or more ends. Without limiting to any particular theory, by separating adjacent conductive channels (e.g., TSC conductive channels 410) with at least one dummy channel 440, a parasitic capacitance can be reduced.

In some implementations, as illustrated in both diagram (a) and diagram (b) of FIG. 4C, a height 415 of the conductive channels 410 (also called TSC conductive channel 410 in the implementations of FIG. 4C) is greater than a height 417 of the capacitor 428 along the Z direction. In some implementations, although not shown, a height 415 of the TSC conductive channel 410 can be substantially equal to the height 417 of the capacitor 428 along the Z direction.

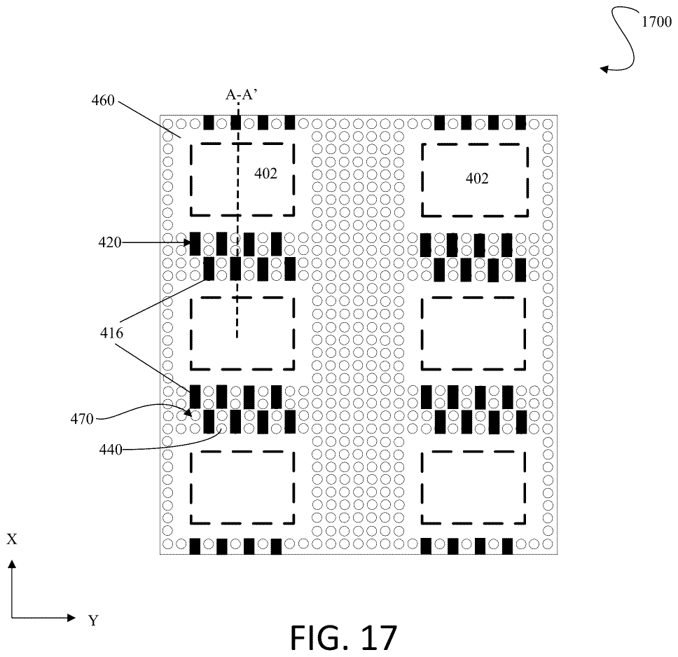

FIG. 4D illustrates an X-Z cross-sectional view of an example semiconductor device 400-2 with conductive channels 420, where X axis is the BL direction. The conductive channels 420 can be referred to as BL conductive channels 420 in the present disclosure when they are described in reference to FIG. 4D. The semiconductor device 400-2 can be implemented as the semiconductor device 400 of FIG. 4A or the semiconductor device 400-1 of FIG. 4C. It is to be noted that more implementations of memory structures with BL conductive channels 420 are described in further detail below with respect to FIGS. 17-19.

As illustrated in FIG. 4D, the semiconductor device 400-2 can include transistors 1820 in the connection region 490, identical or similar to the transistors 426 in the array region 480. In the present disclosure, the transistors 426 in the array region 480 can be referred to as first transistors 426, while the transistors in the connection region 490 can be referred to as second transistors 1820. Each second transistor 1820 can include a semiconductor body 418 extending along the first direction (e.g., Z direction). The semiconductor body 418 can be similar or identical to the transistor body 431 of the first transistors 426. The semiconductor body 418 of the second transistors 1820 can be coupled to a bit line 423.

As illustrated in FIG. 4D, the BL conductive channel 420 can be located between two adjacent array structures 402 along the BL direction (e.g., X direction) and is coupled to the bit line 423 through semiconductor bodies 418. In some implementations, a first end 419a of a semiconductor body 418 is coupled to the BL conductive channel 420, and a second end 419b of the semiconductor body 418 is coupled to the bit line 423. The first end 419a of the semiconductor body 418 is opposite to the second end 419b of the semiconductor body 418 along the first direction (e.g., Z direction), and thus the semiconductor body 418 can be disposed between the BL conductive channel 420 and the bit line 423 along the first direction (e.g., Z direction).

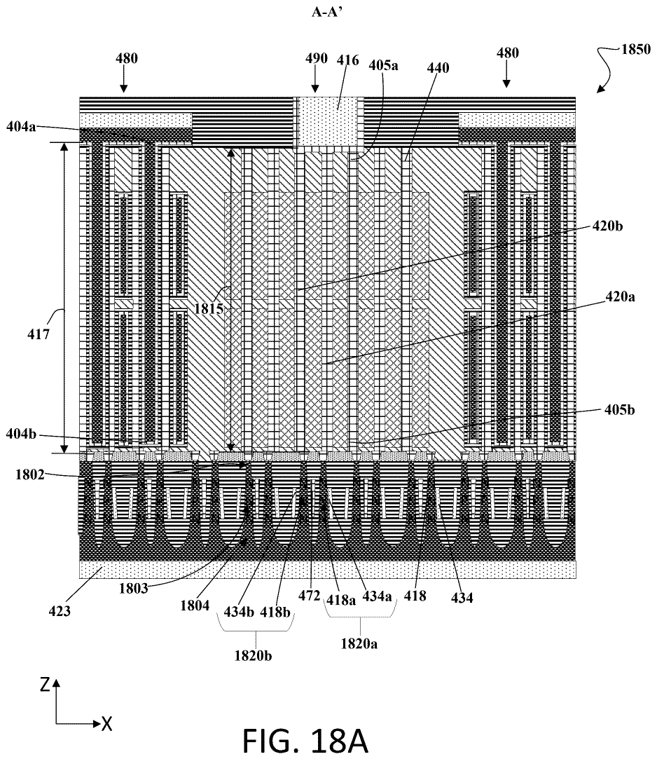

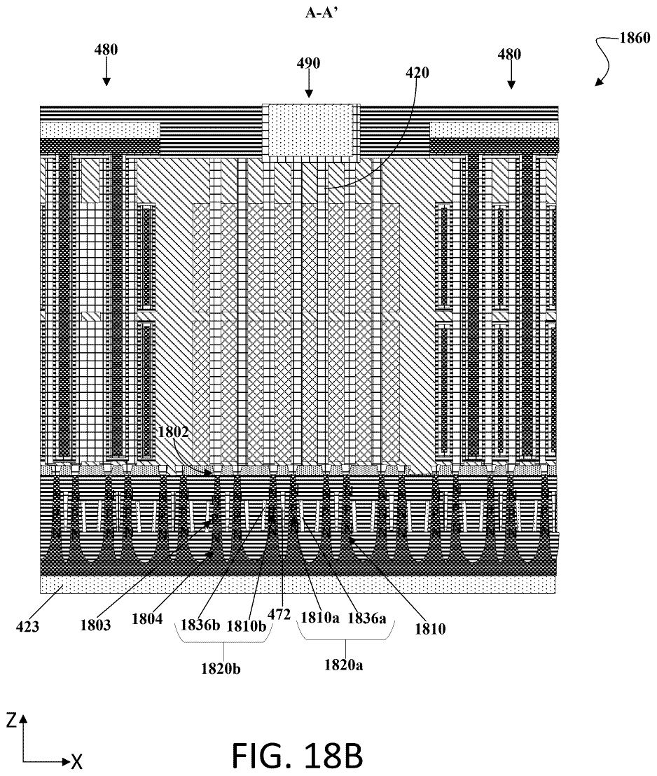

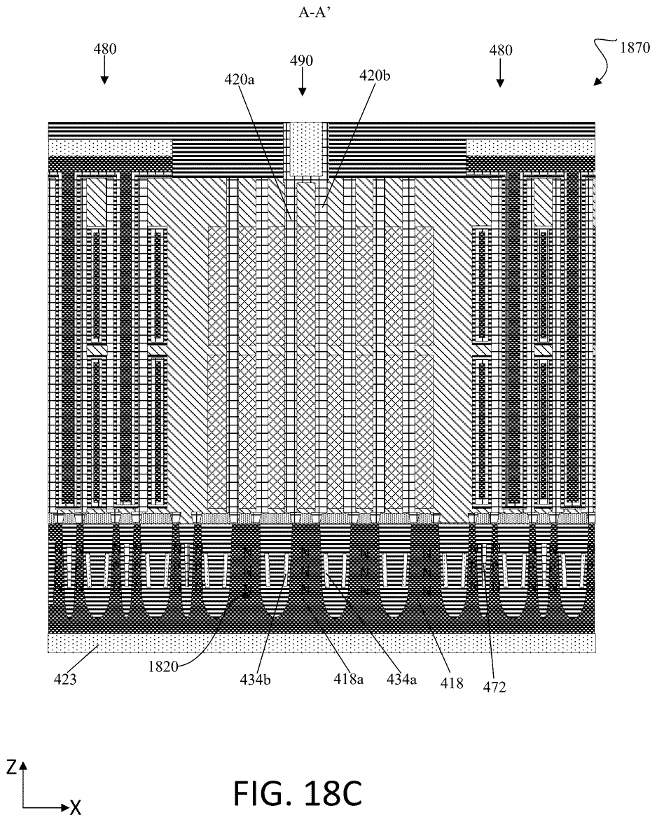

In some implementations, each of a first end 419a and a second end 419b of the semiconductor body 418 includes dopants with a first type, and a middle portion of the semiconductor body 418 between the first end and the second end of the semiconductor body includes the dopants with a second type. In some implementations, the first type is different from the second type. For example, the first type is N type dopants (e.g., Phosphorus (P) or Arsenic (As)), while the second type is P type dopants (e.g., Boron (B) or Gallium (Ga)). In some implementations, the semiconductor body 418 includes all N type dopants, as illustrated in FIG. 4D. In some implementations, semiconductor body 418 includes all P type dopants, N-P-N, or P-N-P dopants, as described in further detail with respect to FIGS. 18A-18C below.

In some implementations, a height of the BL conductive channel 420 is equal to a height of the capacitor 428 along the first direction. In some implementations, the first end 405a of the BL conductive channel 420 is coupled to a contact structure 416, and the second end 405b of the BL conductive channel 420 is coupled to a semiconductor body 418 of the second transistor 1820. BL conductive channel 420 can couple the bit line 423 to control circuits in the memory structure (e.g., the semiconductor device 400-2) and/or a control structure (e.g., the control structure 222 of FIG. 2B) for controlling the operations, e.g., reading and writing, of memory cell arrays.

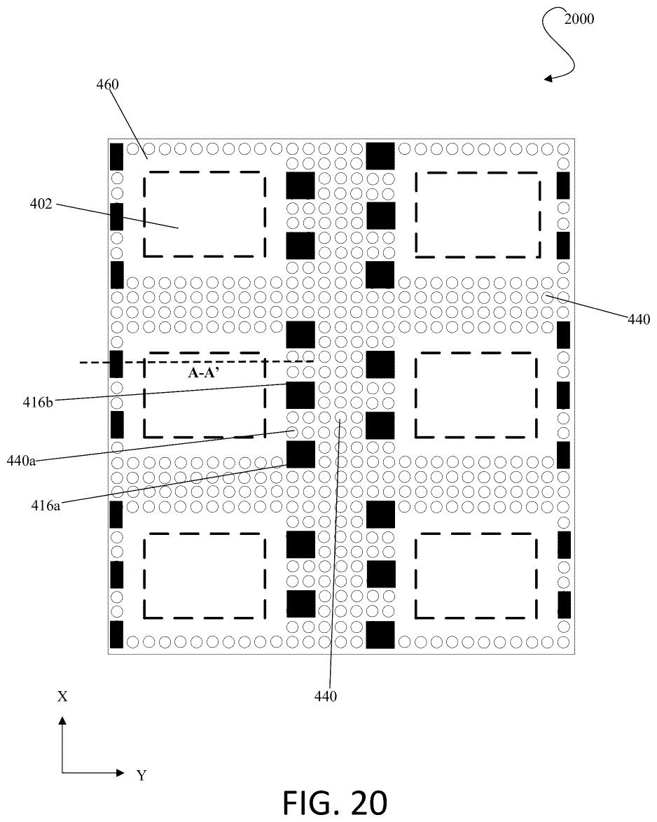

FIG. 4E illustrates a Y-Z cross-sectional view of an example semiconductor device 400-3 with conductive channels 430, where Y axis is the WL direction. The conductive channels 430 can be referred to as WL conductive channels 430 in the present disclosure when they are described in reference to FIG. 4E. The semiconductor device 400-3 can be implemented as the semiconductor device 400 of FIG. 4A, the semiconductor device 400-1 of FIG. 4C, or the semiconductor device 400-2 of FIG. 4D. It is to be noted that more implementations of memory structures with WL conductive channels 430 and methods to form such structures are described in further detail below with respect to FIGS. 20-24.

As illustrated in FIG. 4E, in some implementations, a first end 405a of the WL conductive channel 430 is coupled to a contact structure 416, and a second end 405b of the WL conductive channel 430 is coupled to the word line 434. As noted above, the WL conductive channel 430 is between adjacent array structures 402 along the WL direction, e.g., Y axis in FIGS. 4A and 4E. WL conductive channels 430 can couple the word line 434 to control circuits in the memory structure (e.g., the semiconductor device 400-3) and/or control structure (e.g., the control structure 222 of FIG. 2B) for controlling the operations, e.g., reading and writing, of memory cell arrays.

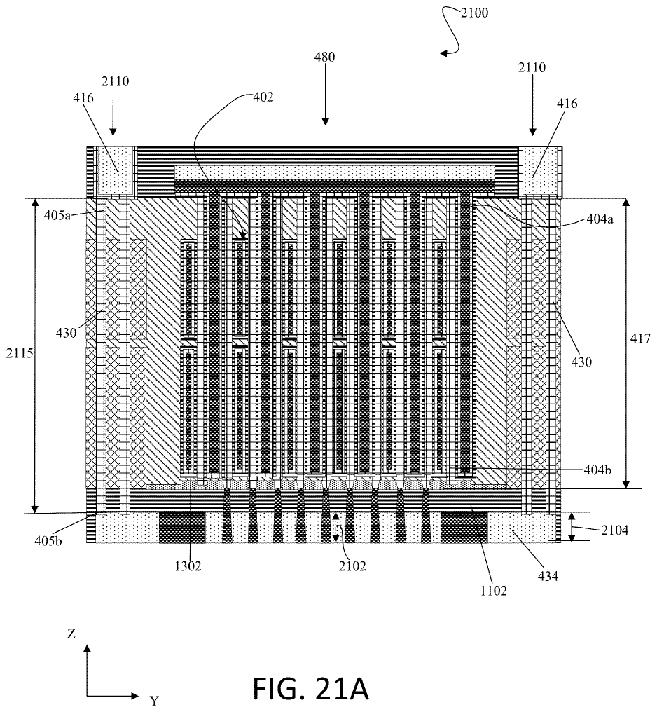

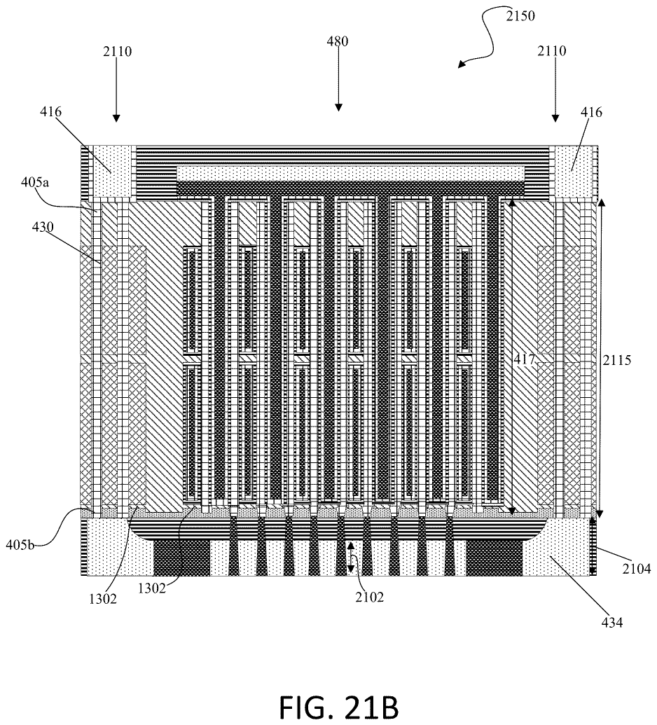

In some implementations, as illustrated in FIG. 4E, a height 413 of the WL conductive channel 430 is greater than a height 417 of the capacitor 428 along the Z direction. In some implementations, as illustrated below in FIG. 21B, a height 2115 of the conductive channel is substantially equal to a height 417 of the capacitor 428 along the Z direction.

FIG. 5 illustrates an example of a semiconductor device 500 with a memory structure and a control structure. A semiconductor device with one memory structure and one control structure can be referred to as AC configuration in the present disclosure. It is to be understood that that the devices or structures depicted in FIG. 5 can represent a composite view from multiple cross-sectional planes. Thus, FIG. 5 is for illustrative purpose only and does not depict a single cross-sectional view within an actual device. For example, the WL conductive channel 430 and the BL conductive channel 420 in an actual device may not be seen together in a single cross-sectional plane cut along BL direction, although both conductive channels are depicted in FIG. 5 for illustrative purpose.

The semiconductor device 500 can be a memory die 302, 304, 306, 308 of FIG. 3. As described above with respect to FIG. 2B, a semiconductor device can have one memory structure 510 and one control structure 520 stacked together. The memory structure 510 can be the semiconductor device 400, 400-1, 400-2, 400-3 of FIGS. 4A-4E. The memory structure 510 can include one or more array structures 402, the separation structure 460, and the connection structure 470. As illustrated in FIG. 5, the connection structure 470 can include all three types of conductive channels: TSC conductive channel 410, BL conductive channel 420 and WL conductive channel 430. In some implementations, the control structure 520 includes a semiconductor substrate 508 and control circuits 502 on the semiconductor substrate 508.

As illustrated in FIG. 5, the memory structure 510 and the control structure 520 can be integrated through hybrid bonding. A hybrid bonding can include a combination of metal-to-metal bonding and a direct oxide bonding. A first bonding layer 504 can be in or on a first side 514 of the memory structure 510, and a second bonding layer 506 is in or on a first side 516 of the control structure 520. The bonding layers 504, 506 can be part of the structures 510, 520, or separate layers formed on the structures 510, 520.

In some implementations, the first bonding layer 504 is in contact with the second bonding layer 506. The first bonding layer 504 includes one or more first conductive contacts 524 isolated by a first dielectric material, and the second bonding layer 506 includes one or more second conductive contacts 526 isolated by a second dielectric material. The first conductive contact 524 can be in contact with a corresponding second conductive contact 526. In some implementations, the capacitors 428 are closer to the first side 514 of the memory structure 510 compared to the second side 518, and the bit line 423 is closer to the second side 518 of the memory structure 510 compared to the first side 514. In some implementations, the capacitors 428 are located between the control structure 520 and the transistors 426 along the Z direction, as shown in FIG. 5.

As illustrated in FIG. 5, the conductive channels of the memory structure are coupled to at least one first conductive contact 524. For example, the BL conductive channel 420 is coupled to the first conductive contact 524 through a contact structure 416. As the first conductive contact 524 is in contact with the corresponding second conductive contact 526, which in turns couples to the control circuits 502 in the control structure 520, the bit line 423 of the memory structure 510 is thus coupled to the control circuits 502 of the control structure 520 through BL conductive channels 420 and corresponding conductive contacts. Similarly, the word line 434 of the memory structure 510 can be coupled to the control circuits 502 of the control structure 520 through WL conductive channels 430 and corresponding conductive contacts. The second conductive contacts 526 of the control structure 520 can be referred to as connecting structures in the present disclosure.

In some implementations, the semiconductor device 500 further includes a power source structure 532 on a second side 518 of the memory structure 510, which connects to an external power source to power the semiconductor device 500. The power source structure 532 cam include a plurality of interconnects and via contacts. In some implementations, one end of the TSC conductive channel 410 is coupled to the power source structure 532, and the other end of the TSC conductive channel 410 is coupled to the control structure 520 through a first conductive contact 524. Therefore, the power source structure 532 can be configured to power the control structure 520 through the TSC conductive channel 410.

The conductive contacts 524,526 can include conductive materials including, but not limited to, W, Co, Cu, Al, doped silicon, silicides, or any combination thereof. The first dielectric material of the first bonding layer 504 and/or the second dielectric material of the second bonding layer 506 can be formed with dielectric materials including, but not limited to, silicon oxide, silicon nitride, silicon oxynitride, low-k dielectrics, or any combination thereof.

FIG. 6 illustrates an example of a semiconductor device 600. It is to be understood that that the devices or structures depicted in FIG. 6 can represent a composite view from multiple cross-sectional planes. Thus, FIG. 6 does not depict a single cross-sectional view within an actual device. For example, the WL conductive channel 430 and the BL conductive channel 420 in an actual device may not be seen together in a single cross-sectional plane cut along the BL direction, although both conductive channels are depicted in FIG. 6 for illustrative purpose.

The semiconductor device 600 can be a memory die 302, 304, 306, 308 of FIG. 3. As described above with respect to FIG. 2E, a memory die can have two memory structure 610, 630 and two control structure 620, 640 stacked together in a CAAC configuration. Alternatively, the semiconductor device 600 can be an integration of two memory dies, with each memory die having an AC configuration.

The memory structure 610, 630 can include the semiconductor device 400, 400-1, 400-2, 400-3 of FIGS. 4A-4E. The memory structures 610, 630 can include one or more array structures 402, the separation structure 460, and the connection structure 470. As illustrated in FIG. 6, the connection structure 470 can include all three types of conductive channels: TSC conductive channel 410, BL conductive channel 420 and WL conductive channel 430. In some implementations, each of the control structures 620, 640 includes a semiconductor substrate 658 and control circuits 652a, 652b on the semiconductor substrate 658. The control circuits 652a, 652b can have identical or different layout.

As illustrated in FIG. 6, all four structures can be integrated through hybrid bonding in a similar way as described above with respect to FIG. 5, which can include a combination of metal-to-metal bonding and a direct oxide bonding. Each structure can have two bonding layers in or on two sides and conductive contacts extending through the bonding layers. The two adjacent structures can be integrated together by bonding their corresponding bonding layers and conductive contacts. The conductive contacts of the control structures 620, 640 can be also referred to as connecting structures in the present disclosure.

In some implementations, as illustrated in FIG. 6, a first bonding layer 601 is in or on a first side of the first memory structure 610, a second bonding layer 602 is in or on a first side of the control structure 620, a third bonding layer 603 is in or on a second side of the first memory structure 610, a fourth bonding layer 604 is in or on a first side of the second memory structure 630, a fifth bonding layer 605 is in or on a second side of the second memory structure 630, and a sixth bonding layer is in or on a first side of the second control structure 640.

Further, in some implementations, the first bonding layer 601 includes one or more first conductive contacts 611 isolated by a first dielectric material, the second bonding layer 602 includes one or more second conductive contacts 612 isolated by a second dielectric material, the third bonding layer 603 includes the one or more third conductive contacts 613 isolated by a third dielectric material, the fourth bonding layer 604 includes the one or more fourth conductive contacts 614 isolated by a fourth dielectric material, the fifth bonding layer 605 includes the one or more fifth conductive contacts 615 isolated by a fifth dielectric material, and the sixth bonding layer 606 includes the one or more sixth conductive contacts 616 isolated by a sixth dielectric material.

To bond the first memory structure 610 and the first control structure 620 through hybrid bonding, at least one of the one or more first conductive contacts 611 of the first memory structure 610 can be in contact with a corresponding one of the one or more second conductive contacts 612 of the first control structure 620. To bond the first memory structure 610 and the second memory structure 630 through hybrid bonding, at least one of the one or more third conductive contacts 613 of the first memory structure 610 can be in contact with a corresponding one of the one or more fourth conductive contacts 614 of the second memory structure 630. Similarly, to bond the second memory structure 630 and the second control structure 640, at least one of the one or more fifth conductive contacts 615 can be in contact with a corresponding one of the one or more sixth conductive contacts 616.

In some implementations, the TSC conductive channels 410 of two memory structures 610, 630 are coupled to each other through corresponding conductive contacts 613, 614 at the bonding interface. More specifically, as illustrated in FIG. 6, for the first memory structure 610, a first end (e.g., a lower end) of the TSC conductive channel 410 is coupled to at least one first conductive contact 611, and a second end (e.g., an upper end) of the TSC conductive channel 410 is coupled to at least one third conductive contact 613. Similarly, for the second memory structure 630, a first end (e.g., a lower end) of the TSC conductive channel 410 is coupled to at least one fourth conductive contact 614, and a second end (e.g., an upper end) of the TSC conductive channel 410 is coupled to at least one fifth conductive contact 615. Therefore, the TSC conductive channel 410 of the first memory structure 610 can be coupled to the TSC conductive channel 410 of the second memory structure 630 through at least one of the third conductive contacts 613 or the fourth conductive contacts 614.

In some implementations, the control structure 620, 640 includes at least one conductive via 650. The conductive via 650 can be a through-silicon-vias (TSV) that extends through the substrate 658. In some implementations, one end of the conductive via 650 of the first control structure 620 is coupled to the TSC conductive channel 410 of the first memory structure 610 through at least one of the first conductive contacts 611 or the second conductive contacts 612. Similarly, in some implementations, one end of the conductive via 650 of the second control structure 640 is coupled to the TSC conductive channel 410 of the second memory structure 630 through at least one of the sixth conductive contacts 616 or the fifth conductive contacts 615.

In some implementations, the substrate (e.g., silicon) of the two memory structures 610, 630 are removed, whereas the substrate 658 of the two control structures 620, 640 are retained, as illustrated in FIG. 6.

In some implementations, as illustrated in FIG. 6, the two control structures 620, 640 have bonding layers 607, 608 and connecting structures 617, 618 in or on their second sides. Therefore, two or more semiconductor device 600 can be integrated together vertically through hybrid bonding, as illustrated above in FIGS. 2G and 3.

In some implementations, as illustrated in FIG. 6, the control structure 620, 640 is integrated on the side of the memory structure 610, 630 that is nearest to the capacitors 428 of the memory structure 610, 630. For example, the first control structure 620 can be closer to the capacitors 428 of the first memory structure 610 than to the transistors 426 of the first memory structure 610. In other words, the capacitors 428 of the first memory structure 610 can be between the transistors 426 of the first memory structure 610 and the first control structure 620. Similarly, the capacitors 428 of the second memory structure 630 can be between the transistors 426 of the second memory structure 630 and the second control structure 640. This configuration can ease the electrical interconnections between BL conductive channels 420 and corresponding control structure 620, 640, and/or between WL conductive channels 430 and corresponding control structure 620, 640.

As described above with respect to FIG. 2C, instead of a CAAC configuration, a memory die can have an AAC configuration with two memory structures and one control structure, where the one control structure can be used to control the two memory structures. A semiconductor device with an AAC configuration can have a structure similar to the semiconductor device 600 of FIG. 6 but excluding the second control structure 640 or the first control structure 620.

As described above with respect to FIG. 2D, a semiconductor device can have a CACA configuration. A semiconductor device with the CACA configuration can have a structure similar to the semiconductor device 600 of FIG. 6, except that the positions of the second control structure 640 and the second memory structure 630 are swapped. Therefore, the second control structure 640 is between the first memory structure 610 and the second memory structure 630 (e.g., as illustrated in FIG. 2D) in a CACA configuration.

As noted above, a control structure can be disposed closer to capacitors 428 of its corresponding memory structure than to transistors 426 in order to ease its connections to BL conductive channels 420 and/or WL conductive channels 430. Therefore, with the CACA configuration, the second control structure 640 can be disposed closer to the capacitors 428 of the second memory structure 630 but closer to the transistors 426 of the first memory structure 610. In other words, at least one of the one or more third conductive contacts 613 of the first memory structure 610 can be in contact with a corresponding one of the one or more eighth conductive contacts 618 of the second control structure 640, and at least one of the one or more fifth conductive contacts 615 of the second memory structure 630 can be in contact with a corresponding one of the one or more sixth conductive contacts 616 of the second control structure 640.

In some implementations, in the CACA configuration as illustrated in FIG. 2D, the second control structure 640 has a conductive via 650 (e.g., TSV). A first end of the conductive via 650 is coupled to the TSC conductive channel 410 of the first memory structure 610 through corresponding conductive contacts 613, 618, and a second end of the conductive via 650 is coupled to the TSC conductive channel 410 of the second memory structure 630 through corresponding conductive contacts 615, 616.

It is to be noted that although not shown, a separation structure 460 can be included in the semiconductor device 600 of FIG. 6, similar or identical to the separation structure 460 of FIGS. 4A-5. The separation structure 460 can separate the capacitors 428 from the connection structure 470, as described above with reference to FIGS. 4A-4E.

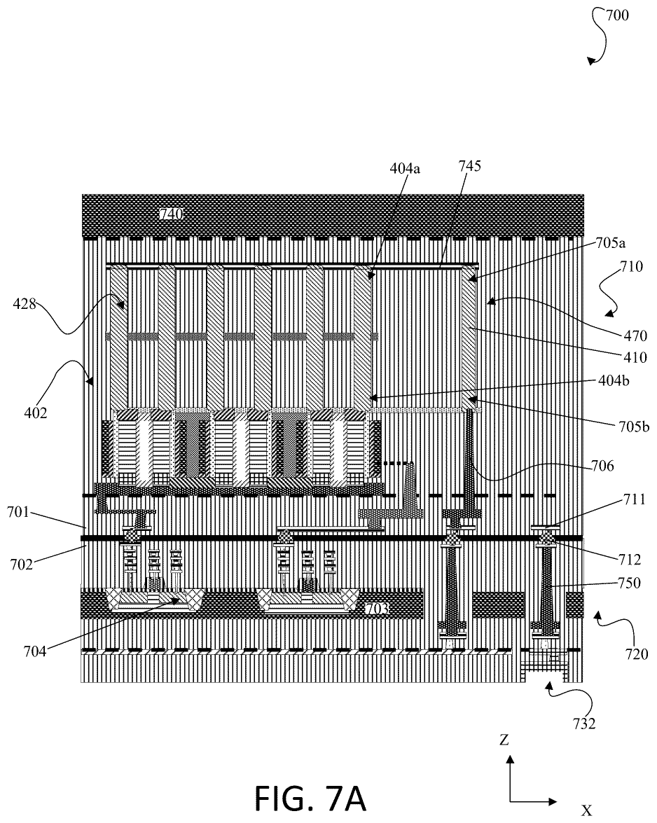

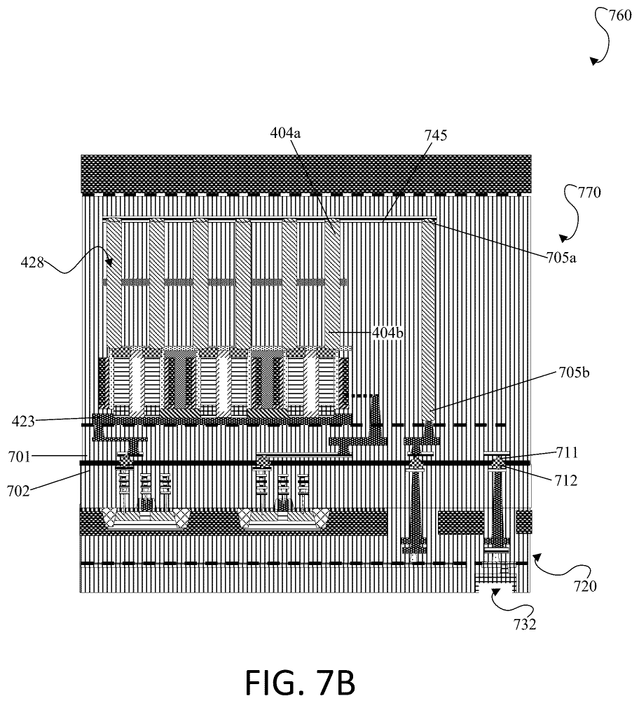

FIG. 7A illustrates an example of a semiconductor device 700 in an AC configuration with a first implementation of TSC conductive channels. The semiconductor device 700 can be a memory die 302, 304, 306, 308 of FIG. 3. The semiconductor device 700 differs from the semiconductor device 500 of FIG. 5 at least in that its conductive channels include only TSC conductive channels 410 and do not include BL or WL conductive channels 420, 430.

As illustrated in FIG. 7A, the memory structure 710 and the control structure 720 can be integrated together through hybrid bonding. The memory structure 710 can include one or more array structures 402, the separation structure 460 (not shown), and the connection structure 470 with TSC conductive channels 410. Unlike the semiconductor device 500 of FIG. 5, the memory structure 710 has a substrate 740 (e.g., silicon substrate).

In some implementations, each end of the TSC conductive channel 410 is substantially coplanar with a respective end of the capacitor 428, as shown in FIG. 7A. For example, the first end 705a of the TSC conductive channel 410 can be substantially coplanar with the first end 404a of the capacitor 428, and the second end 705b of the TSC conductive channel 410 can be substantially coplanar with the second end 404b of the capacitor 428. Therefore, a height of the TSC conductive channels 410 can be substantially equal to a height of the capacitor 428 along Z direction.

In some implementations, the semiconductor device 700 includes an interconnection via 706. A first end (e.g., an upper end) of the TSC conductive channel 410 is coupled to a conductive layer 745, and a second end (e.g., a lower end) of the TSC conductive channel 410 is coupled to the interconnection via 706. The interconnection via 706 can be coupled to the first conductive contacts 711 of the memory structure 710. Therefore, the TSC conductive channel 410 can be coupled to the control structure 720 through the interconnection via 706 and the corresponding first conductive contacts 711. The conductive layer 745 and the interconnection via 706 can be implemented as the contact structure 416 of FIG. 4C.

In some implementations, the control structure 720 includes a conductive via 750. One end of the conductive via 750 can be coupled to the TSC conductive channel 410 of the memory structure 710 through at least one of the first conductive contacts 711 or the second conductive contacts 712. In some implementations, the conductive via 750 is a through-silicon-vias (TSV), which extends through the substrate 703 of the control structure 720.

In some implementations, the semiconductor device 700 further includes a power source structure 732 on the control structure 720, which connects to an external power source to power the semiconductor device 700. The power source structure 732 can include a plurality of interconnects and via contacts. In some implementations, one end of the conductive via 750 is coupled to the power source structure 732, and the other end of the conductive via 750 is coupled to the second conductive contact 712. Therefore, the power source structure 732 can be configured to power the memory structure 710 through the conductive via 750, the second conductive contact 712 and the corresponding first conductive contacts 711, as show in FIG. 7A.

It is to be noted that although not shown, a separation structure 460 can be included in the semiconductor device 700 of FIG. 7A, similar or identical to the separation structure 460 of FIGS. 4A-5. The separation structure 460 can separate the capacitors 428 from the connection structure 470, as described above with reference to FIGS. 4A-4E.

FIG. 7B illustrates an example of a semiconductor device 760 with another implementation of TSC conductive channels. The semiconductor device 760 can be a memory die 302, 304, 306, 308 of FIG. 3. The semiconductor device 760 differs from the semiconductor device 700 of FIG. 7A primarily in that its TSC conductive channels 410 is longer than the capacitors 428 along the Z direction.

Similar to the semiconductor device 700 of FIG. 7A, the first end 705a of the TSC conductive channel 410 of the semiconductor device 760 can be substantially coplanar with the first end of the capacitor 428. However, unlike the semiconductor device 700 of FIG. 7A, the second end 705b of the TSC conductive channel 410 of the semiconductor device 760 can extend beyond the second end 404b of the capacitor 428. Therefore, a height of the TSC conductive channels 410 can be greater than a height of the capacitor 428 along Z direction, as illustrated in FIG. 7B.

In some implementations, one end of the TSC conductive channel 410 is coupled to a conductive layer 745, and the other end of the TSC conductive channel 410 is coupled to the first conductive contacts 711 of the memory structure 770. Therefore, the TSC conductive channel 410 can be coupled to the control structure 720 through first conductive contacts 711 and second conductive contacts 712.

When the memory structure of a semiconductor device includes only TSC conductive channels 410 (without BL or WL conductive channels 420, 430), the control structure of the semiconductor device can be integrated on either side of the memory structure. Therefore, the control structure can be closer to the capacitors of the memory structure or closer to the transistors of the memory structure in such situations. This can be because both ends of TSC conductive channels 410 can be coupled to contact structures 416, which can be then coupled to the control structure through conductive contacts. It is to be understood that, although not shown in FIGS. 7A and 7B, the control structure 720 can be integrated on the capacitor 428 side of memory structure 710, 770 in a manner similar to the semiconductor device 600 of FIG. 6.

It is to be noted that although not shown, a separation structure 460 can be included in the semiconductor device 760 of FIG. 7B, similar or identical to the separation structure 460 of FIGS. 4A-5. The separation structure 460 can separate the capacitors 428 from the connection structure 470, as described above with reference to FIGS. 4A-4E.

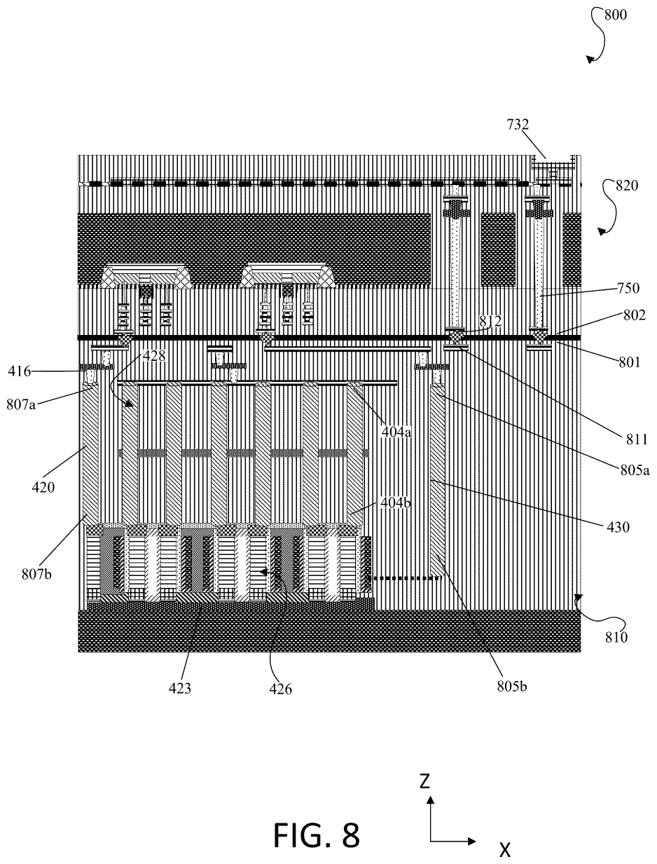

FIG. 8 illustrates an example of a semiconductor device 800. It is to be understood that that the semiconductor device 800 depicted in FIG. 8 can represent a composite view from multiple cross-sectional planes. Thus, FIG. 8 is for illustrative purpose only and does not depict a single cross-sectional view within an actual device. For example, the WL conductive channel 430 and the BL conductive channel 420 in an actual device may not be seen together in a single cross-sectional plane cut along BL direction, although both conductive channels are depicted in FIG. 8 for illustrative purpose.

The semiconductor device 800 can be a memory die 302, 304, 306, 308 of FIG. 3. The semiconductor device 800 differs from the semiconductor device 500 of FIG. 5 at least in that its conductive channels include BL conductive channels 420 and/or WL conductive channels 430 but do not include TSC conductive channels 410.

As illustrated in FIG. 8, in some implementations, a first end 807a of the BL conductive channel 420 is substantially coplanar with a first end 404a of a capacitor 428, and a second end 807b of the BL conductive channel 420 is coupled to a bit line 423. The first end 807a of the BL conductive channel 420 is opposite to the second end 807b of the BL conductive channel 420 along Z direction. Similarly, a first end 805a of the WL conductive channel 430 can be substantially coplanar with a first end 404a of capacitor 428, and a second end 805b of the WL conductive channel 430 is coupled to a word line 434. The first end 805a of the WL conductive channel 430 is opposite to the second end 805b of the WL conductive channel 430 along Z direction.

In some implementations, as illustrated in FIG. 8, the control structure 820 is integrated at the capacitor 428 side of the memory structure 810 as opposed to its transistors side. In some implementations, the first end 807a of the BL conductive channel 420 or the first end 805a of the WL conductive channel 430 is coupled to the control structure 820 by hybrid bonding, e.g., through at least one of the first conductive contacts 811 or the second conductive contacts 812.

Similar to the semiconductor device 700 of FIG. 7A and the semiconductor device 760 of FIG. 7B, the semiconductor device 800 can include a power source structure 732 on the control structure 820, which connects to an external power source to power the semiconductor device 800. The power source structure 732 can include a plurality of interconnects and via contacts. In some implementations, one end of the conductive via 750 is coupled to the power source structure 732, and the other end of the conductive via 750 is coupled to the second conductive contact 812. Therefore, the power source structure 732 can be configured to power the memory structure 810 through the conductive via 750, the second conductive contact 812 and the corresponding first conductive contacts 811, as show in FIG. 8.

It is to be noted that although not shown, a separation structure 460 can be included in the semiconductor device 800 of FIG. 8, similar or identical to the separation structure 460 of FIGS. 4A-5. The separation structure 460 can separate the capacitors 428 from the connection structure 470, as described above with reference to FIGS. 4A-4E.

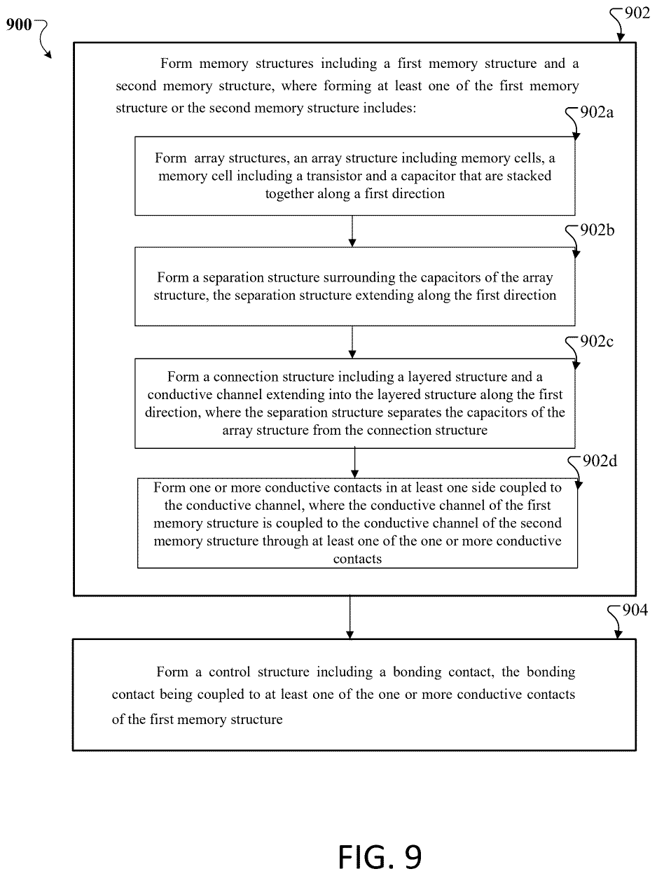

FIG. 9 is a flow chart of an example process 900 for forming a semiconductor device with at least one memory structure and at least one control structure. The semiconductor device can include or be implemented as the semiconductor device 400, 400-1, 400-2, 400-3 of FIGS. 4A-4E, the semiconductor device 500 of FIG. 5, the semiconductor device 600 of FIG. 6, the semiconductor device 700 of FIG. 7A, the semiconductor device 760 of FIG. 7B, or the semiconductor device 800 of FIG. 8.

At step 902, a plurality of memory structures is formed including a first memory structure and a second memory structure. The first memory structure can be, e.g., the first memory structure 220a of FIGS. 2C-2G, or the first memory structure 610 of FIG. 6. The second memory structure can be, e.g., the second memory structure 220b of FIGS. 2C-2G, or the second memory structure 630 of FIG. 6.

Forming at least one of the first memory structure or the second memory structure includes the following step: at step 902a, a plurality of array structures is formed. An array structure of the plurality of array structures includes a plurality of memory cells. A memory cell of the plurality of memory cells includes a transistor and a capacitor that are stacked together along a first direction. At step 902b, a separation structure surrounding the capacitors of the array structure is formed, where the separation structure extends along the first direction. At step 902c, a connection structure is formed that includes a layered structure and a conductive channel extending into the layered structure along the first direction. At step 902d, one or more conductive contacts are formed in at least one side coupled to the conductive channel. The conductive channel of the first memory structure is coupled to the conductive channel of the second memory structure through at least one of the one or more conductive contacts. The array structure can be, e.g., the array structure 402 of FIGS. 4A-8. The memory cells can be, e.g., the memory cell 424 of FIGS. 4A-8. The transistor can be, e.g., the transistor 426 of FIGS. 4A and 4C-8. The capacitor can be, e.g., the capacitor 428 of FIGS. 4A-8. The first direction can be, e.g., the Z direction of FIGS. 4A and 4C-8. The separation structure can be, e.g., the separation structure 460 of FIGS. 4A-5. The connection structure can be, e.g., the connection structure 470 of FIGS. 4A-8. The layered structure can be, e.g., the layered structure 450 of FIGS. 4C-8. The conductive channel can be, e.g., the TSC conductive channels 410 of FIGS. 4A, 4C and 5-7B, the BL conductive channels 420 of FIGS. 4A, 4D, 5, 6 and 8, or the WL conductive channels 430 of FIGS. 4A, 4E, 5, 6 and 8. The conductive contacts can be, e.g., the first conductive contacts 524 of FIG. 5, the first conductive contacts 611 of FIG. 6, the first conductive contacts 711 of FIGS. 7A and 7B, the first conductive contacts 811 of FIG. 8, the third conductive contacts 613 of FIG. 6, the fourth conductive contacts 614 of FIG. 6, or the fifth conductive contacts 615 of FIG. 6.

At step 904, a control structure is formed including a connecting structure. The connecting structure is coupled to at least one of the one or more conductive contacts of the first memory structure. The control structure can be, e.g., the control structure 222 of FIGS. 2C-2G and 5-8. The connecting structure can be, e.g., the second conductive contacts 526 of FIG. 5, the second conductive contacts 612 of FIG. 6, the second conductive contacts 712 of FIGS. 7A and 7B, the second conductive contacts 812 of FIG. 8, the sixth conductive contacts 616 of FIG. 6, the seventh conductive contacts 617 of FIG. 6, or the eighth conductive contacts 618 of FIG. 6.

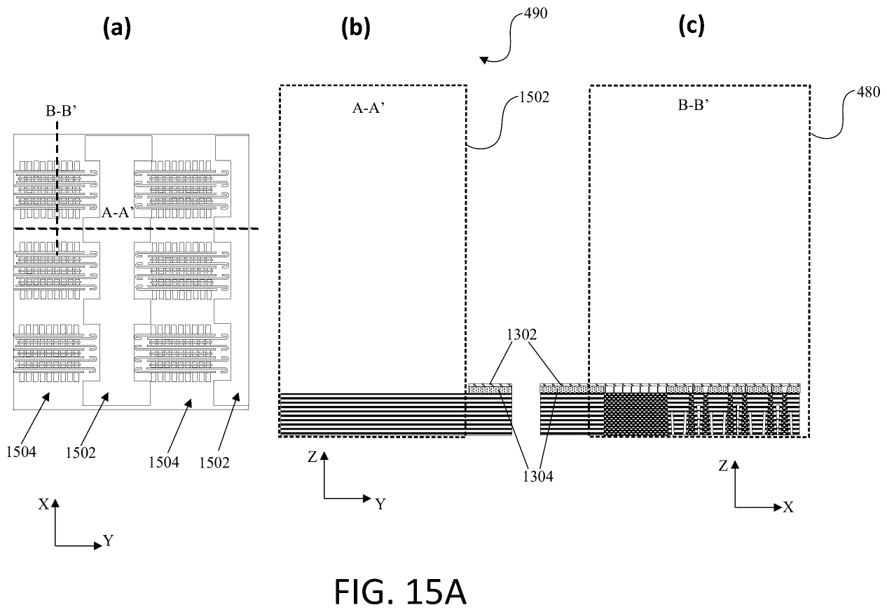

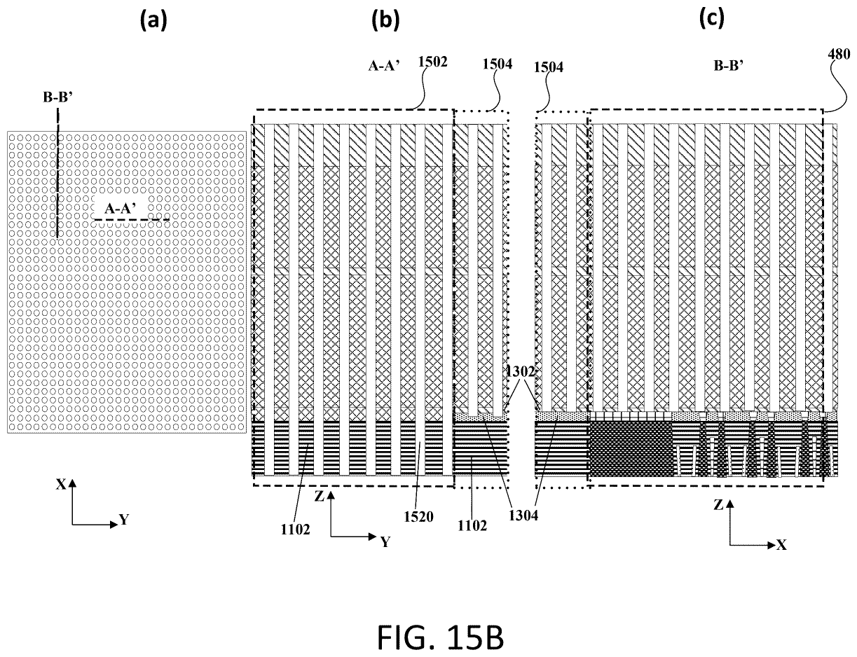

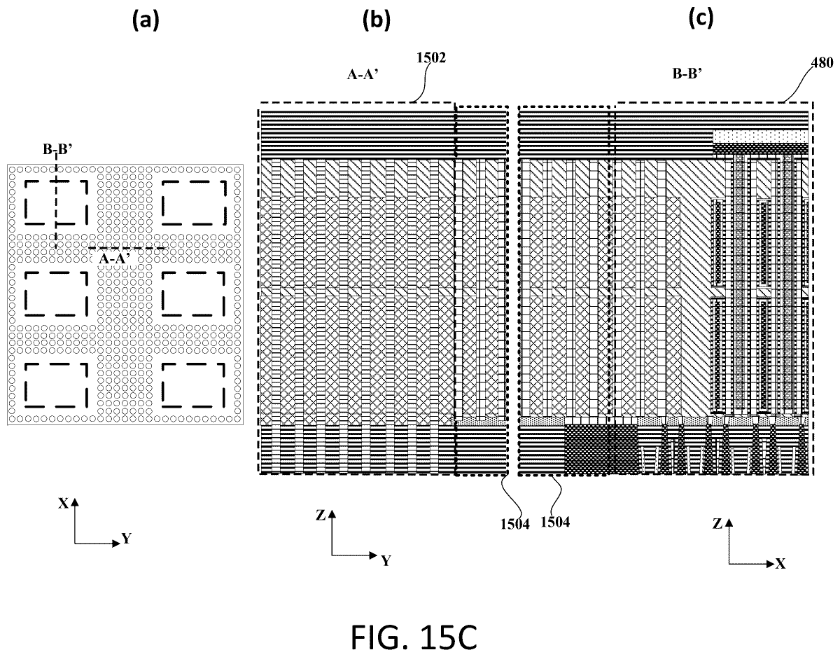

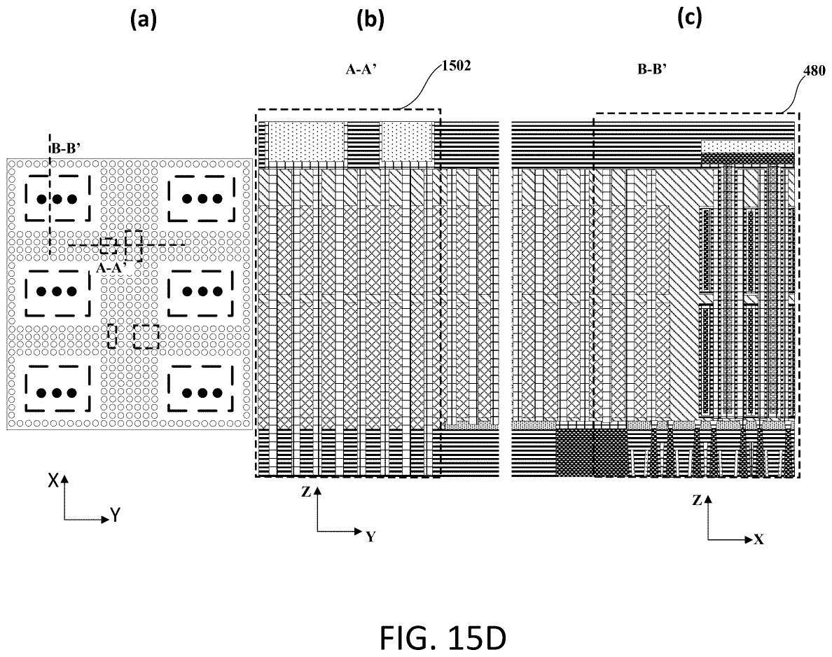

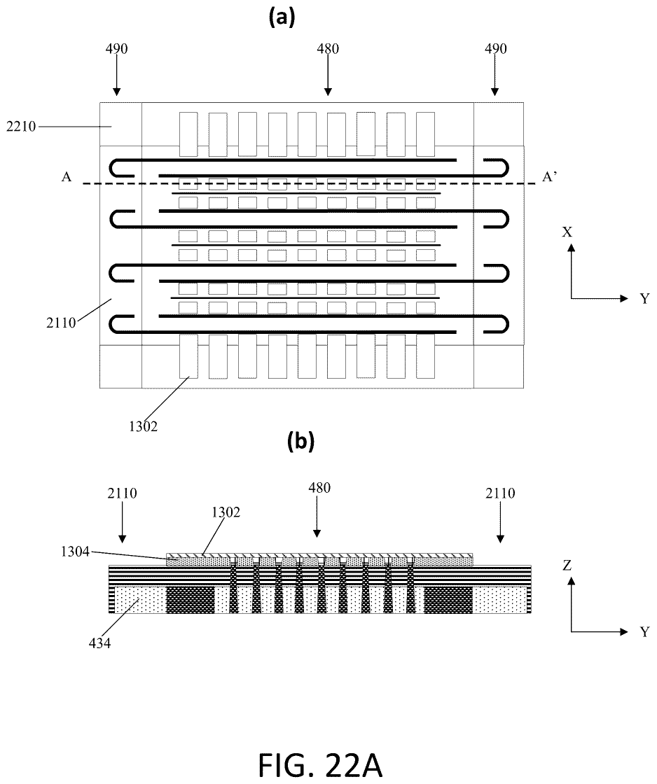

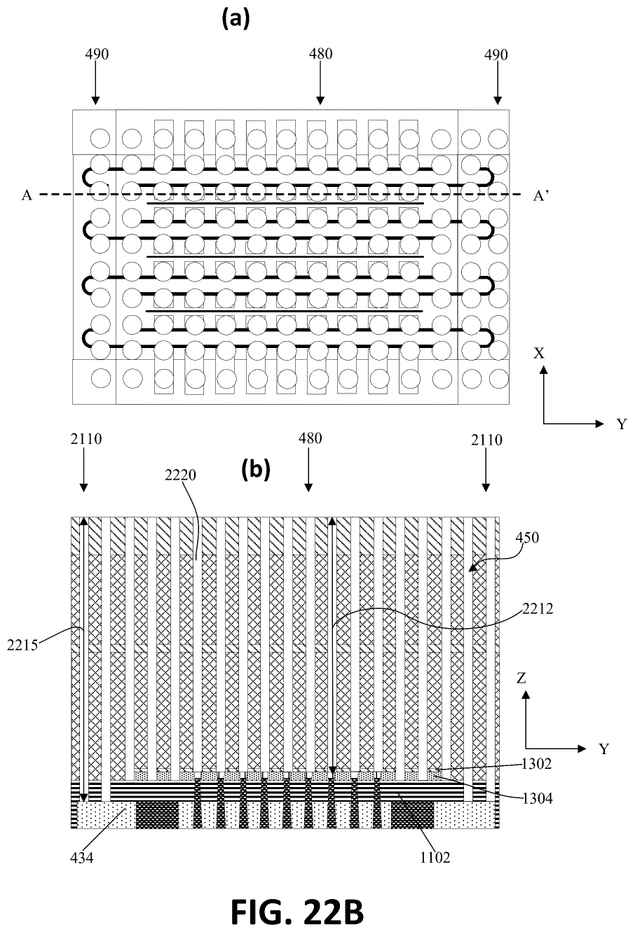

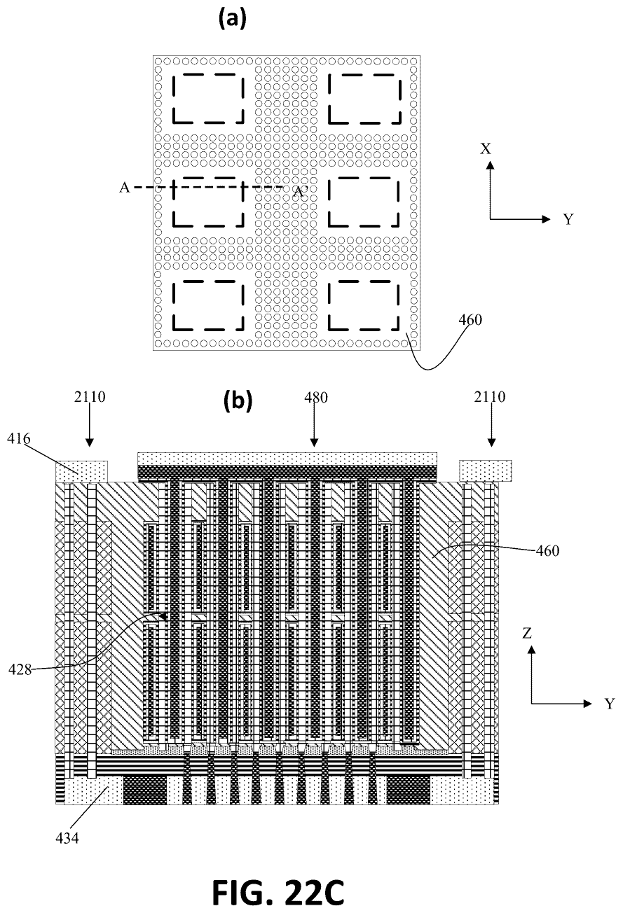

In some implementations, the layered structure is formed; openings extending into the layered structure along the first direction are formed; the separation structure extending into the layered structure is formed, defining an array region surrounded by the separation structure; the capacitors in the array region are formed; and the conductive channel is formed outside of the separation structure and extending into the layered structure. The openings can be, e.g., the openings 1520 of FIG. 15B, or the openings 2220 of FIG. 22B, as described below. The array region can be, e.g., the array region 480 of FIGS. 4A-8. The region outside of the separation structure can be referred to as connection region 490, as illustrated in FIGS. 4A-8.

In some implementations, forming conductive channels outside of the separation structure includes depositing a conductive material into at least one of the openings outside of the separation structure. The conductive material can include at least one of tungsten (W), polysilicon, or titanium intrude (TiN).

In some implementations, a sacrificial material is deposited into one or more openings outside of the separation structure; then, the sacrificial material of at least one of the one or more openings outside of the separation structure is removed to form holes; and the conductive material is deposited into the holes. The process of depositing and removing sacrificial material is described below in further detail with respect to FIGS. 15A-15D.

In some implementations, an etch stop layer is formed between the layered structure and the transistors; and the etch stop layer is at least partially removed outside of the separation structure. The etch stop layer can be, e.g., the etch-stop layer 1302 of FIG. 15A, as described below.

In some implementations, a first contact structure is formed that is coupled to a first end of one or more conductive channels. The first contact structure can be, e.g., the first contact structure 416a of FIG. 4C, the second contact structure 416b of FIG. 4C, the third contact structure 416c of FIG. 4C, the contact structure 416 of FIGS. 4D-6 and 8, the conductive layer 745 of FIGS. 7A and 7B, or interconnection via 706 of FIG. 7A.

In some implementations, a second contact structure is formed that is coupled to a second end of the one or more conductive channels. The second contact structure can be, e.g., the first contact structure 416a of FIG. 4C, the second contact structure 416b of FIG. 4C, the third contact structure 416c of FIG. 4C, the contact structure 416 of FIGS. 4D-6 and 8, the conductive layer 745 of FIGS. 7A and 7B, or interconnection via 706 of FIG. 7A.

In some implementations, forming capacitors in the array region surrounded by the separation structure includes depositing a first electrode into the openings in the array region. The first electrode can include, e.g., the first electrode 444 of FIGS. 4C-4D.

In some implementations, a first bonding layer in a first side of the first memory structure and a third bonding layer in a second side of the first memory structure are formed; a fourth bonding layer in a first side of the second memory structure is formed; one or more first conductive contacts are formed that are extending through the first bonding layer and isolated by a first dielectric material; one or more third conductive contacts are formed that are extending through the third bonding layer and isolated by a third dielectric material; and one or more fourth conductive contacts are formed that are extending through the fourth bonding layer and isolated by a fourth dielectric material. The first bonding layer can be, e.g., the first bonding layer 232 of FIG. 2B, the first bonding layer 504 of FIG. 5, the first bonding layer 601 of FIG. 6, the first bonding layer 701 of FIGS. 7A and 7B, or the first bonding layer 801 of FIG. 8. The third bonding layer can be, e.g., the third bonding layer 603 of FIG. 6. The fourth bonding layer can be, e.g., the fourth bonding layer 604 of FIG. 6. The first side of the first memory structure can be, e.g., the first side 641 of the first memory structure 610 of FIG. 6. The second side of the first memory structure can be, e.g., the second side 642 of the first memory structure 610 of FIG. 6. The first side of the second memory structure can be, e.g., the first side 661 of the second memory structure 630 of FIG. 6. The first, second, third, or fourth dielectric material can include, but not limited to, silicon oxide, silicon nitride, silicon oxynitride, or any combination thereof.

In some implementations, the first memory structure and the second memory structure are stacked, where the third bonding layer is in contact with the fourth bonding layer, and at least one of the one or more third conductive contacts of the first memory structure is in contact with a corresponding one of the one or more fourth conductive contacts of the second memory structure, as illustrated in FIG. 6.

In some implementations, forming the control structure includes forming a second bonding layer in a first side of the control structure and forming the one or more connecting structures extending through the second bonding layer and isolated by a second dielectric material. The second bonding layer can be, e.g., the second bonding layer 234 of FIG. 2B, the second bonding layer 506 of FIG. 5, the second bonding layer 602 of FIG. 6, the second bonding layer 702 of FIGS. 7A and 7B, or the second bonding layer 802 of FIG. 8.

In some implementations, the first memory structure and the control structure are stacked together, where the first bonding layer is in contact with the second bonding layer, and at least one of the one or more first conductive contacts of the first memory structure is in contact with a corresponding one of the one or more connecting structures of the control structure.

FIGS. 10-15D illustrates various implementations of semiconductor devices with conductive channels 410. The conductive channels 410 can be referred to as TSC conductive channels 410 in the present disclosure when they are described in reference to FIGS. 10-15D. FIG. 10 illustrates a plan view of a memory structure 1000. The memory structure 1000 can also be referred to as the semiconductor device 1000 in the present disclosure. As illustrated in FIG. 10, the memory structure 1000 includes a plurality of array structures 402. Six array structures 402 are shown in FIG. 10. An array structure 402 includes a plurality of DRAM memory cells, as described above with respect to FIGS. 4A-4E. An array structure 402 can be surrounded by a separation structure 460. The memory structure 1000 can further include a connection structure 470 adjacent to the separation structure 460. The separation structure 460 separates the capacitors 428 of the array structure 402 from the connection structure 470 (e.g., as illustrated in FIG. 4A). The area surrounded by the separation structure 460 is referred to as an array region 480 (e.g., the area enclosed by dashed line in FIG. 10) in this disclosure. Six array regions 480 are illustrated in FIG. 10. The area outside the separation structure 460 is referred to as a connection region 490 in this disclosure. The connection region 490 can include the area between adjacent array structures 402 and/or the area surrounding each array region 480.

In some implementations, the connection structure 470 includes at least one conductive channel extending through the layered structure 450 along Z direction. As illustrated in FIG. 10, the conductive channels can include TSC conductive channels 410. In some implementations, the TSC conductive channels 410 are located between any two adjacent array structures 402 (e.g., the TSC conductive channels 410-1, 410-4), adjacent to the separation structure 460 (e.g., the TSC conductive channel 410-2), and/or near the center of four surrounding array structures 402 (e.g., the TSC conductive channel 410-3), as illustrated in FIG. 10.

In some implementations, the semiconductor device 1000 further includes a plurality of contact structures 416 coupled to at least one TSC conductive channels 410. Three contact structures 416a, 416c, 416d are shown in FIG. 10. Contact structures 416 can differ in size and be coupled to different number of conductive channels. For example, the three contact structures 416 shown in FIG. 10 are coupled to 4 conductive channels (e.g., 2×2 channels), 12 conductive channels (e.g., 3×4 channels) and 3 conductive channels (e.g., 3×1 channels), respectively.

FIGS. 11A and 11B illustrate cross-sectional views of the semiconductor device 1000 of FIG. 10 with two different implementations of TSC conductive channels 410. Diagram (a) of both FIGS. 11A and 11B is a cross-sectional view through A-A′ axis of FIG. 10 along the WL direction (e.g., Y direction of FIG. 10), while diagram (b) of both FIGS. 11A and 11B is a cross-sectional view through B-B′ axis of FIG. 10 along the BL direction (e.g., X direction of FIG. 10). The first implementation of TSC conductive channels 410 illustrated in FIG. 11A is identical to that of FIG. 4C. For ease of description, reference will be made to both FIGS. 11A and 11B when describing the semiconductor device 1000.

In some implementations, as illustrated in FIG. 11A, the connection structure 470 includes a layered structure 450. As noted above, the layered structure 450 includes a first dielectric layer 452 and a second dielectric layer 454 stacked together along the Z direction. In some implementations, the layered structure 450 includes a first supporting layer 458 between the first dielectric layer 452 and the second dielectric layer 454, and a second supporting layer 456 stacked over the first dielectric layer 452. In some implementations, the first dielectric layer 452 includes tetraethyl orthosilicate (TEOS), the second dielectric layer 454 includes borophosphosilicate glass (BPSG), and the first supporting layer 458 and second supporting layer 456 include at least one of silicon carbon nitride (SiCN) or silicon boron nitride (SiBN). In some implementations, at least one material of the separation structure 460 is different from a material of the layered structure 450. For example, the separation structure 460 can include silicon carbon nitride (SiCN) or silicon boron nitride (SiBN) but not TEOS, whereas the layered structure 450 can include TEOS. In some implementations, an edge of the separation structure 460 is wave shaped, as illustrated above in FIG. 4B.

In some implementations, the capacitor 428 includes a first end 404a and a second end 404b opposite to the first end 404a along the first direction. The second end 404b of the capacitor 428 is coupled to the transistor 426. In some implementations, a first end 405a of the TSC conductive channel 410 is substantially coplanar with the first end 404a of the capacitor 428 (e.g., also illustrated in FIG. 4A).

In some implementations, as illustrated in FIG. 11A, the second end 405b of the TSC conductive channel 410 extends beyond the second end 404b of the capacitor 428 and further into a dielectric body 1102 surrounding the transistors 426. Therefore, a height 415 of the TSC conductive channel 410 is greater than a height 417 of the capacitor 428 along Z direction. In some implementations, an etch-stop layer 1302 is removed at least partially in the connection region 490 and thus the TSC conductive channel 410 can extend into the dielectric body 1102, as described in further detail below with reference to FIGS. 15A-15D.

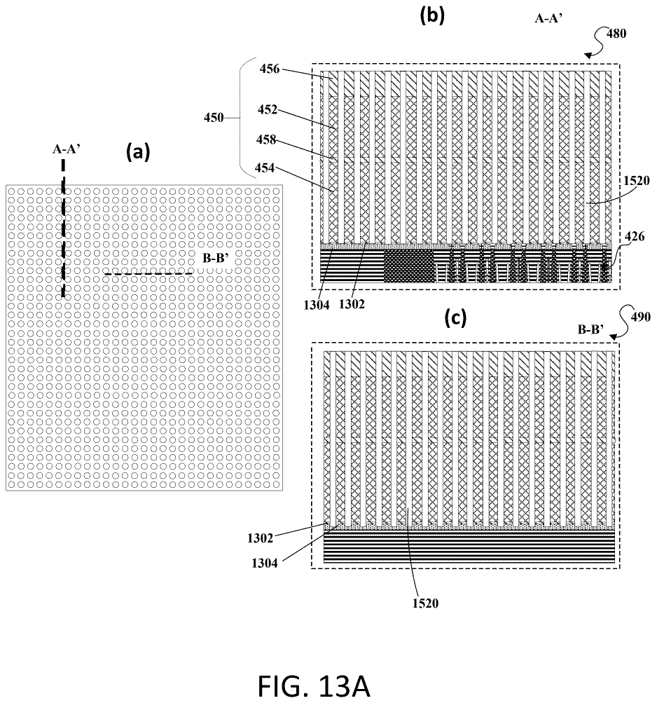

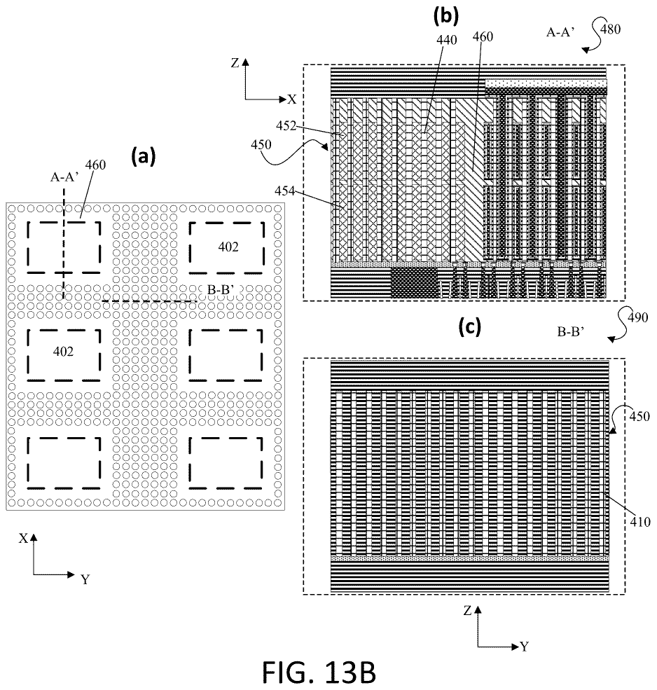

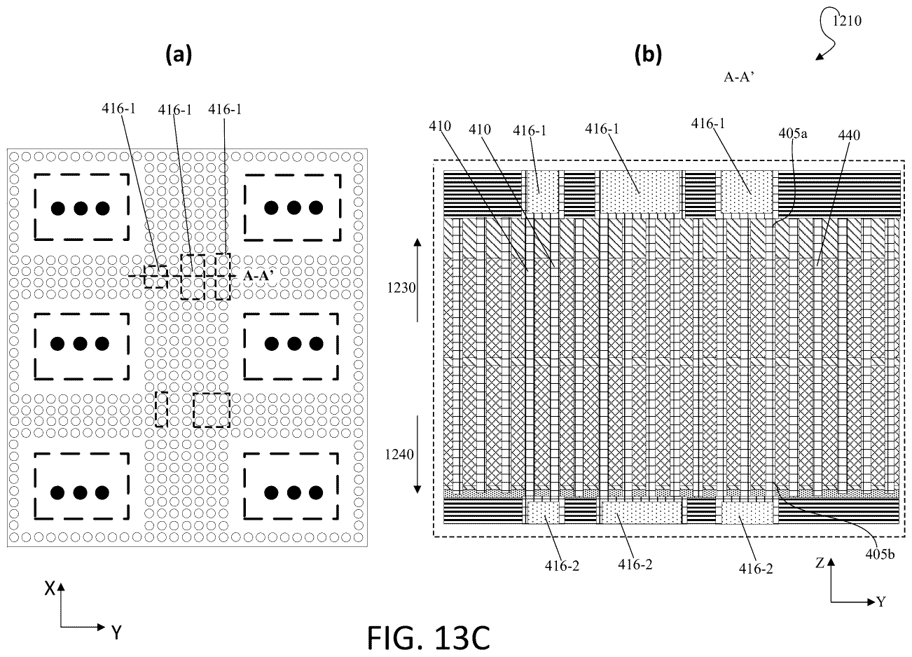

In some implementations, as illustrated in FIG. 11B, the second end 405b of the TSC conductive channel 410 is substantially coplanar with the second end 404b of the capacitor 428. Therefore, a height 415 of the TSC conductive channels 410 can be substantially equal to a height 417 of the capacitor 428 along Z direction. In some implementations, an etch-stop layer 1302 is present in both the connection region 490 and the array region 480 and thus the TSC conductive channels 410 can stop at the etch-stop layer 1302 without extending further into the dielectric body 1102, as described in further detail below with reference to FIGS. 13A-13C.

Referring back to FIG. 11A, the first end 405a of the TSC conductive channel 410 can be coupled to a first contact structure 416a. A second end 405b of the TSC conductive channel 410 that is opposite to the first end 405a of the TSC conductive channel 410 along the first direction can be coupled to a second contact structure 416b. Therefore, the TSC conductive channel 410 can be between the first contact structure 416a and the second contact structure 416b along the first direction (e.g., Z direction, or a vertical direction perpendicular to a substrate surface), and both ends of the TSC conductive channel 410 can be electrically coupled to corresponding contact structures 416. In some implementations, the first contact structure 416a and the second contact structure 416b are coupled to two ends of the same one or more conductive channels. For example, the first contact structure 416a is coupled to first ends 405a of the first TSC conductive channel 410a and the second TSC conductive channel 410b. Correspondingly, the second contact structure 416b is coupled to second ends 405b of the exact same two TSC conductive channels 410, that is, the first TSC conductive channel 410a and the second TSC conductive channel 410b. Consequently, the first TSC conductive channel 410a and the second TSC conductive channel 410b can be electrically coupled to each other in parallel.

In some implementations, the semiconductor device 1000 further includes a third contact structure 416c. The third contact structure 416c is coupled to at least one TSC conductive channel 410, and adjacent TSC conductive channels 410 that are coupled to the first contact structure 416a and the third contact structure 416c are spaced from each other by at least one dummy channel 440 between the adjacent conductive channels. For example, as illustrated in the diagram (a) of FIG. 11A, the first contact structure 416a can be coupled to the first TSC conductive channel 410a, while the third contact structure 416c can be coupled to the third TSC conductive channel 410c. The first TSC conductive channel 410 and the third TSC conductive channel 410 can be spaced from each other by the first dummy channel 440a which is not electrically connected to any contact structure 416 at either end. Without limiting to any particular theory, by separating adjacent TSC conductive channels 410 with at least one dummy channel 440, a parasitic capacitance between the adjacent TSC conductive channels 410 can be reduced.

In some implementations, as discussed above with reference to FIGS. 7A and 7B, the first end of the TSC conductive channels 410 can be coupled to a conductive layer 7452, while the second end of the TSC conductive channels 410 can be coupled to a control structure (e.g., control structure 720 of FIGS. 7A and 7B). In some implementations, as discussed above with reference to FIG. 6, each end of the TSC conductive channels 410 is coupled to another structure (e.g., memory structures 610, 630 and/or control structures 620, 640).

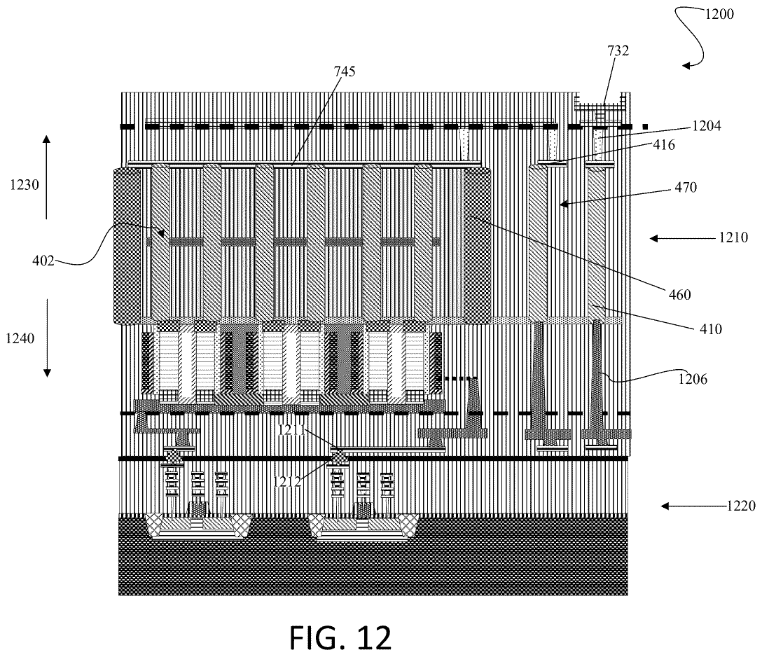

FIG. 12 illustrated a cross-sectional view of a semiconductor device 1200 with TSC conductive channels. The semiconductor device 1200 includes a memory structure 1210 and a control structure 1220 stacked together. The memory structure 1210 can be the semiconductor device 1000 of FIGS. 10 and 11B. The semiconductor device 1200 of FIG. 12 is similar to the semiconductor device 700 of FIG. 7A but differs at least in the contact structures 416 that are coupled to the TSC conductive channels 410 and positions of a power source structure 732.

Similar to the semiconductor device 700 of FIG. 7A, the memory structure 1210 and the control structure 1220 can be integrated together through hybrid bonding. The memory structure 1210 can include one or more array structures 402, the separation structure 460, and the connection structure 470 with TSC conductive channels 410. The TSC conductive channels 410 of FIG. 12 can implemented as the TSC conductive channels 410 of FIG. 11B, where a height of the TSC conductive channels 410 can be substantially equal to a height of the capacitor 428 along Z direction.

Unlike the semiconductor device 700 of FIG. 7A where one end of the TSC conductive channel 410 is coupled to the conductive layer 745, one end of the TSC conductive channel 410 can be coupled to a contact structure 416 separate from the conductive layer 745 as illustrated in FIG. 12. Additionally, the other end of the TSC conductive channel 410 can be coupled to an interconnection via 1206. The interconnection via 1206 can be coupled to the first conductive contacts 1211 of the memory structure 1210, and the first conductive contacts 1211 can be coupled to the connecting structures 1212. Therefore, the TSC conductive channel 410 can be coupled to the control structure 1220 through the interconnection via 1206, the corresponding first conductive contacts 1211 and the connecting structures 1212. The interconnection via 1206 can be implemented as the contact structure 416 of FIG. 11B.

Further, in contrast to the semiconductor device 700 of FIG. 7A where the power source structure 732 is on the control structure 1220, the power source structure 732 can be in or on the memory structure 1210, as illustrated in FIG. 12. The power source structure 732 can connect to an external power source to power the semiconductor device 1200. The power source structure 732 can include a plurality of interconnects and via contacts. In some implementations, one end (e.g., the upper end) of the TSC conductive channel 410 is coupled to the power source structure 732 through the contact structure 416 and vias 1204.

FIGS. 13A-13C illustrate cross-sectional views of the memory structure 1210 of FIG. 12 at various stages of a fabrication process. Diagram (a) of FIGS. 13A-13C is a plan view of the memory structure 1210. Diagram (b) and diagram (c) of FIGS. 13A-13B are cross-sectional views along axis A-A′ and B-B′ of diagram (a), respectively. Diagrams (b) of FIGS. 13A-13B show cross-sectional views of the memory structure 1210 near the array region 480, while diagrams (c) show cross-sectional views of the connection region 490 of the memory structure 1210. Diagram (b) of FIG. 13C is a cross-sectional view of the connection region 490 along axis A-A′ of diagram (a) of FIG. 13C. For ease of description, reference will be made to all diagrams when describing the structure of the memory structure 1210.

As illustrated in FIG. 13A, an etch-stop layer 1302 can be formed on top of the transistors 426 of the array structure 402, and a layered structure 450 can be formed on the etch-stop layer 1302. Both layered structure 450 and the etch-stop layer 1302 can extend in both array region 480 and connection region 490. As noted above, in some implementations, the layered structure 450 includes four layers: a second dielectric layer 454, a first supporting layer 458, a first dielectric layer 452 and a second supporting layer 456 stacked sequentially along Z direction. In some implementations, the first dielectric layer 452 includes tetraethyl orthosilicate (TEOS), the second dielectric layer 454 includes borophosphosilicate glass (BPSG), and the first supporting layer 458 and second supporting layer 456 include at least one of silicon carbon nitride (SiCN) or silicon boron nitride (SiBN). In some implementations, the etch-stop layer 1302 includes silicon nitride or silicon dioxide. The etch-stop layer 1302 and the layered structure 450 can be deposited using one or more thin film deposition techniques, including, but not limited to, chemical vapor deposition (CVD), physical vapor deposition (PVD), atomic layer deposition (ALD), sputtering, or any combination thereof.

Openings 1520 can be formed extending through the layered structure 450 along Z direction in both array region 480 and connection region 490. In some implementations, the openings 1520 stop at the etch-stop layer 1302. In some implementations, the openings 1520 extend into the etch-stop layer 1302 along Z direction, as illustrated in diagram (b) of FIG. 13A. In some implementations, the openings 1520 penetrate the etch-stop layer 1302 and further extend into a dielectric layer 1304 underneath the etch-stop layer 1302, as illustrated in diagram (c) of FIG. 13A. It is understood that although diagram (b) and diagram (c) of FIG. 13A shows different levels of penetration of openings 1520 into the dielectric layer 1304, they can have the same or similar level of penetration.

In some implementations, the openings 1520 in both array region 480 and the connection region 490 have uniform diameter, height and/or pitch. In some implementations, the etch time to form openings 1520 in the array region 480 is substantially equal to the etch time to form openings 1520 in the connection region 490. In some implementations, forming the openings 1520 involves using a full print lithography mask to define openings 1520 pattern in both array region 480 and connection region 490 at the same process step. In some implementations, one or more dry etching and/or wet etching techniques are used after patterning to form openings, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 13B, a separation structure 460 can be formed extending through the layered structure 450. The separation structure 460 defines the array region 480 (e.g., the area surrounded by the separation structure 460). The separation structure 460 can be formed by first enlarging openings in selected rows and/or columns with additional etching and then depositing a dielectric material into these enlarged openings 1520. In some implementations, as illustrated in FIG. 4A, the selected rows and/or columns of openings 1520 form a square shape and thus the separation structure have a wall configuration. In some implementations, as illustrated in FIG. 4B, the separation structure 460 has a wave shape in X-Y plane because of the enlargement of the openings 1520. In some implementations, the separation structure 460 includes at least one of silicon carbon nitride (SiCN) or silicon boron nitride (SiBN).

Referring back to diagram (b) of FIG. 13B, the capacitors 428 can be formed in the array region 480. In some implementations, forming capacitors 428 can include depositing a first electrode 444 into the openings 1520 in the array region 480. The first electrode 444 can extend along Z direction and have a cylindrical shape. In some implementations, forming capacitors 428 further includes removing the first dielectric layer 452 and the second dielectric layer 454 in the array region 480 to form second openings (not shown) between adjacent first electrodes 444, followed by depositing a capacitor dielectric layer 445 and a second electrode 447 sequentially into the second openings. The first electrode 444 and the second electrode 447 can include, but not limited to, TiN, TaN, Al, W, Cu, doped-polysilicon, silicides, or any combination thereof.

TSC conductive channels 410 can be formed outside of the array region 480 (e.g., in the connection region 490) that extend through the layered structure 450, as illustrated in diagram (c) of FIG. 13B. In some implementations, forming the TSC conductive channels 410 in the connection region 490 includes depositing a conductive material into at least one opening 1520 in the connection region 490. In some implementations, the TSC conductive channel 410 has the same material as the first electrode 444 of the capacitors 428. In some implementations, the conductive channel includes at least one of tungsten (W), polysilicon, or titanium intrude (TiN).

In some implementations, the deposition of the TSC conductive channel 410 into the openings 1520 in the connection region 490 and depositing the first electrode 444 in the array region 480 are performed at the same process step, which can involve depositing a conductive material into the openings 1520 in both regions. The conductive material deposited in the array region 480 can become part of the capacitors 428, while the conductive material deposited in the connection region 490 can become TSC conductive channels 410.

In some implementations, the dummy channels 440 are formed together with the TSC conductive channels 410 through the deposition of the conductive material into the openings 1520 in the connection region 490. Therefore, the dummy channels 440 can have the same material and structure as the TSC conductive channel 410. However, the difference can be that both ends of the TSC conductive channels 410 are coupled to contact structures 416, whereas the dummy channels 440 are not electrically connected to any other conductive structures at one or more ends. Therefore, the TSC conductive channels 410 can be padded out through forming contact structures 416 at selected locations of the connection structure 470, and the channels at the unselected locations of the connection structure 470 can be the dummy channels 440.

As illustrated in diagram (b) of FIG. 13C, contact structures 416 can be formed on upper ends of the TSC conductive channels 410 from the front side 1230 of the memory structure 1210. The contact structures 416 that are coupled to the upper ends of the TSC conductive channels 410 can be referred to upper contact structures 416-1 in the present disclosure. Three upper contact structures 416-1 are shown in FIG. 13C. Each upper contact structure 416-1 can couple to one or more TSC conductive channels 410, and different upper contact structure 416-1 can couple to different number of TSC conductive channels 410, as illustrated in diagram (a) and (b) of FIG. 13C. For example, the three upper contact structures 416 are coupled to 4 channels, 8 channels, and 4 channels, respectively, as illustrated in diagram (a) of FIG. 13C.

In some implementations, the memory structure 1210 is flipped over to form contact structures 416-2 from the backside 1240 of the memory structure 1210. The contact structures 461-2 can be coupled to the lower ends of the TSC conductive channels 410. Those contact structures 461-2 coupled to the lower ends of the TSC conductive channels 410 can be referred to as lower contact structures 416-2 in the present disclosure. Three lower contact structures 416-2 are illustrated in diagram (b) of FIG. 12. As noted above, in some implementations, a pair of an upper contact structure 416-1 and a lower contact structure 416-2 is coupled to the exact same TSC conductive channels 410 such that each coupled TSC conductive channel 410 is connected on both ends. In some implementations, forming lower contact structures 416-2 from the backside 1240 of the memory structure 1210 involves bonding a carrier wafer, substrate thinning, photolithography, dry/wet etch, thin film deposition, or any other suitable process. The contact structure 416 can include a conductive material including, but not limited to W, Co, Cu, Al, TiN, TaN, polysilicon, or any combination thereof.

In some implementations, the lower contact structures 416-2 that are coupled to the lower ends of the TSC conductive channels 410 have same or similar structures as the upper contact structures 416-1 that are coupled to the upper ends of the TSC conductive channels 410. For example, as illustrated in diagram (b) of FIG. 13C, each pair of contact structures 416-1, 416-2 can have similar structures and layout.

In some implementations, the lower contact structures 416-2 that are coupled to the lower ends of the TSC conductive channels 410 have different structures or shape as the upper contact structures 416-1 that are coupled to the upper ends of the TSC conductive channels 410. For example, as illustrated in FIG. 12, the contact structure 416 that are coupled to the upper ends of the TSC conductive channels 410 can be a thin film, whereas the contact structure 416 that are coupled to the lower ends of the TSC conductive channels 410 can be an elongated interconnection via 1206 that extends vertically along Z direction.

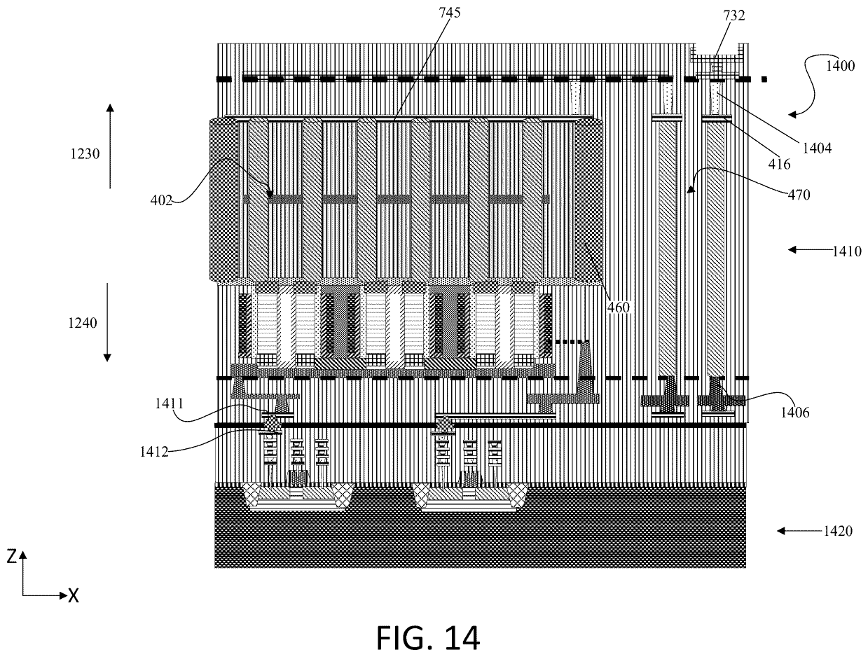

FIG. 14 illustrated a cross-sectional view of a semiconductor device 1400 with TSC conductive channels. The semiconductor device 1400 can include a memory structure 1410 and a control structure 1420 stacked together. The memory structure 1410 can be the semiconductor device 1000 of FIGS. 10 and 11A. The semiconductor device 1400 of FIG. 14 is similar to the semiconductor device 760 of FIG. 7B but differs primarily in the contact structures 416 coupled to the TSC conductive channels 410 and their connections to a power source structure 732.

Similar to the semiconductor device 760 of FIG. 7B, the memory structure 1410 and the control structure 1420 can be integrated together through hybrid bonding. The memory structure 1410 can include one or more array structures 402, the separation structure 460, and the connection structure 470 with TSC conductive channels 410. The TSC conductive channels 410 can be implemented as the TSC conductive channels 410 of FIG. 11A, where a height of the TSC conductive channels 410 is greater than a height of the capacitor 428 along Z direction.

Unlike the semiconductor device 760 of FIG. 7B where one end of the TSC conductive channel 410 is coupled to the conductive layer 745 (e.g., the ground plate), one end of the TSC conductive channel 410 can be coupled to a contact structure 416 separate from the conductive layer 745. In addition, the other end of the TSC conductive channel 410 can be coupled to an interconnection structure 1406. The interconnection structure 1406 can be coupled to the first conductive contacts 1411 of the memory structure 1410, and the first conductive contacts 1411 of the memory structure 1410 can be coupled to the connecting structures 1412 of the control structure 1420. Therefore, the TSC conductive channel 410 can be coupled to the control structure 1420 through the interconnection structure 1406, the corresponding first conductive contacts 1411 and corresponding connecting structures 1412. The interconnection structure 1406 can be implemented as the contact structure 416 of FIG. 11A.

Further, in contrast to the semiconductor device 760 of FIG. 7B where the power source structure 732 is on the control structure, the power source structure 732 can be in or on the memory structure 1410, as illustrated in FIG. 14. The power source structure 732 can connect to an external power source to power the semiconductor device 1400. The power source structure 732 can include a plurality of interconnects and via contacts. In some implementations, one end of the TSC conductive channel 410 is coupled to the power source structure 732 through the contact structure 416 and vias 1404.

FIGS. 15A-15D illustrate cross-sectional views of the memory structure 1410 of FIG. 14 at various stages of a fabrication process. Diagram (a) of FIGS. 15A-15D is a plan view of the memory structure 1410. Diagram (b) and diagram (c) of FIGS. 15A-15D are cross-sectional views along axis A-A′ and B-B′ of diagram (a), respectively. Diagram (b) shows the cross-sectional view of the connection region 490, while diagram (c) shows the cross-sectional view of the memory structure 1410 near the array region 480. For ease of description, reference will be made to all diagrams when describing the structure of the memory structure 1410.

As illustrated in FIG. 15A, an etch-stop layer 1302 can be deposited in both array region 480 and connection region 490. In some implementations, the etch-stop layer 1302 is at least partially removed in the connection region 490, as shown in diagram (b) of FIG. 15A. The portion of the connection region 490 without the etch-stop layer 1302 can be referred to as an exposed region 1502 or TSC pick-up region 1502 in this disclosure. The rest portion of the connection region 490 that includes the etch-stop layer 1302 can be referred to as an unexposed region 1504 in this disclosure. Diagram (a) of FIG. 15A illustrates a plan view of the memory structure 1410 with partially removed etch-stop layer 1302. It is understood that the example in the diagram (a) of FIG. 15A is for illustration purpose and is not intended to be construed in a limiting sense, and thus other layouts of the TSC pick-up region 1502 can also be employed. In some implementations, the dielectric layer 1304 underneath the etch-stop layer 1302 is partially removed together with the etch-stop layer 1302.

As illustrated in FIG. 15B, the layered structure 450 can be formed using the process similar to those described above with respect to FIG. 13A. Openings 1520 can then be formed extending through the layered structure 450 along Z direction in both array region 480 and connection region 490. In some implementations, in the region with the etch-stop layer 1302 (e.g., the array region 480 illustrated in diagram (c) of FIG. 15B), the openings 1520 stops at the etch-stop layer 1302, or extend into the etch-stop layer 1302 along Z direction, as illustrated in diagram (c) of FIG. 15B. In some implementations, the openings 1520 penetrate the etch-stop layer 1302 and further extend into the dielectric layer 1304 underneath the etch-stop layer 1302, as illustrated in diagram (b) of FIG. 15B. It is understood that although diagram (b) and diagram (c) of FIG. 13A shows different levels of penetration of openings 1520 into the dielectric layer 1304 underneath the etch-stop layer 1302, they can have the same or similar level of penetration.

In some implementations, in the exposed region 1502 without the etch-stop layer 1302, the openings 1520 extend deeper into the dielectric body 1102 of the memory structure 1410. Therefore, a height of the openings 1520 in the exposed region 1502 can be greater than a height of the openings 1520 in the unexposed region 1504, as illustrated in diagram (b) of FIG. 15B. In some implementations, an etch time for forming the openings 1520 outside of the array region 480 (e.g., in the exposed region 1502) is longer than an etch time for forming the openings 1520 inside the array region 480. In other words, an over-etch can be performed to form deeper openings 1520 in the exposed region 1502 compared to the openings 1520 in the array region 480. As noted above, despite different heights, the openings 1520 in both array region 480 and the connection region 490 can have uniform diameter and/or pitch.

As illustrated in FIG. 15C, capacitors 428 can be formed in the array region 480 using the techniques described above with respect to FIG. 13B. A sacrificial material can be deposited into one or more openings 1520 outside of the array region 480 (e.g., the deeper openings 1520 in the exposed region 1502). In some implementations, the sacrificial material includes polysilicon and carbon. Without limiting to any particular theory, filling with nonconductive material can reduce damage from etching at subsequent process steps when the memory structure 1410 is flipped over to form bit lines 423 on its backside 1240 (e.g., as illustrated in FIG. 14). In some implementations, the openings 1520 in the unexposed region 1504 of the connection region 490 are deposited with a conductive material identical or similar to the first electrode 444 of the capacitors 428 in the array region 480, as illustrated in diagram (b) of FIG. 15C. In some implementations, the openings 1520 in the unexposed region 1504 of the connection region 490 are deposited with a sacrificial material identical to that in the exposed region 1502 (not shown in FIG. 15C). The sacrificial material can be deposited using one or more thin film deposition techniques, including, but not limited to, chemical vapor deposition (CVD), physical vapor deposition (PVD), atomic layer deposition (ALD), sputtering, or any combination thereof.

As illustrated in FIG. 15D, the sacrificial material of at least one opening 1520 outside of the array region 480 can be removed to form holes (not shown). The holes can be the openings 1520 with removed sacrificial materials. A conductive material can be then deposited into the holes to form the TSC conductive channels 410. In some implementations, the conductive material is the same as the material of the first electrode 444. In some implementations, the TSC conductive channel 410 includes at least one of tungsten (W), polysilicon, or titanium intrude (TiN). In some implementations, the removal of the sacrificial material and the deposition of the conductive material to form TSC conductive channels 410 are performed from the backside 1240 of the memory structure 1410. In some implementations, these steps are performed after the bit lines 423 are formed from the backside 1240 of the memory structure 1410.

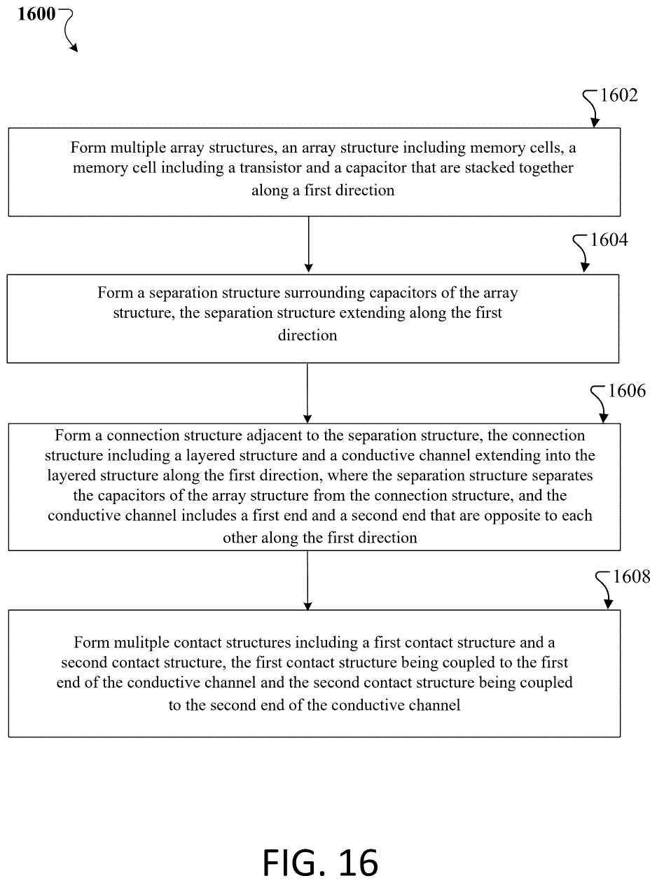

FIG. 16 is a flow chart of an example process 1600 for forming a semiconductor device. The semiconductor device can be the semiconductor device 1000 of FIGS. 10-11B, the semiconductor device 1200 of FIGS. 12-13C, or the semiconductor device 1400 of FIGS. 14-15D.

At step 1602, a plurality of array structures is formed. An array structure of the plurality of array structures includes a plurality of memory cells. A memory cell of the plurality of memory cells includes a transistor and a capacitor that are stacked together along a first direction. The array structure can be, e.g., the array structure 402 of FIGS. 4A-4E, 10-12, 13B-13C, 14 and 15C-15D. The memory cells can be, e.g., the memory cell 424 of FIGS. 4A-4E, 10-12, 13B-13C, 14 and 15C-15D. The transistor can be, e.g., the transistor 426 of FIGS. 4A, 4C-4D, and 11A-15D. The capacitor can be, e.g., the capacitor 428 of FIGS. 4A-8. The first direction can be, e.g., the Z direction of FIGS. 4A-4E, 10-12, 13B-13C, 14 and 15C-15D.

At step 1604, a separation structure surrounding capacitors of the array structure is formed, and the separation structure extends along the first direction. The separation structure can be, e.g., the separation structure 460 of FIGS. 4A-4E, 10-12, 13B-13C, 14 and 15C-15D.

At step 1606, a connection structure is formed that is adjacent to the separation structure. The connection structure includes a layered structure and a conductive channel extending into the layered structure along the first direction, where the separation structure separates the capacitors of the array structure from the connection structure, and the conductive channel includes a first end and a second end that are opposite to each other along the first direction. The connection structure can be, e.g., the connection structure 470 of FIGS. 4A-4C, 5-7B, 10-14 and 15B-15D. The layered structure can be, e.g., the layered structure 450 of FIGS. 4C-14 and 15B-15D. The conductive channel can be, e.g., the TSC conductive channels 410 of FIGS. 4A, 4C, 5-7B, 10-12, 13B-13C and 15D. The first end can be, e.g., the first end 405a or the upper end 405a of FIGS. 4A, 4C, 5-7B, 11A-12, 13B-13C and 15D. The second end can be, e.g., the second end 405b or the lower end 405b of FIGS. 4A, 4C, 5-7B, 11A-12, 13B-13C and 15D.

At step 1608, a plurality of contact structures is formed, which includes a first contact structure and a second contact structure. The first contact structure is coupled to the first end of the conductive channel and the second contact structure is coupled to the second end of the conductive channel. The contact structures can be, e.g., the contact structure 416 of FIGS. 10-12, 13C, 14 and 15D.

In some implementations, an etch stop layer is formed. The layered structure is formed on the etch stop layer. Openings are formed, extending into the layered structure along the first direction. The separation structure is formed, extending into the layered structure and defining an array region surrounded by the separation structure. The capacitors are formed in the array region. The conductive channel is formed outside of the array region and extending into the layered structure. The etch stop layer can be, e.g., the etch-stop layer 1302 of FIGS. 4C-8 and 10-15D. The openings can be, e.g., the openings 1520 of FIGS. 13A and 15B, or the openings 2220 of FIG. 22B, as described below. The array region can be, e.g., the array region 480 of FIGS. 4A-8 and 10-15D. The region outside of the separation structure can be referred to as connection region 490, as illustrated in FIGS. 4A-8 and 10-15D.

In some implementations, the etch stop layer is at least partially removed outside of the array region, as described with respect to FIG. 15A.

In some implementations, a sacrificial material is deposited into one or more openings outside of the array region. The sacrificial material of at least one of the one or more openings outside of the array region to form holes is removed, and a conductive material is deposited into the holes, as described above with respect to FIGS. 15C and 15D.

FIGS. 17-18C illustrates various implementations of semiconductor devices with conductive channels 420. The conductive channels 420 can be referred to as BL conductive channels 420 below when they are described in reference to FIGS. 17-18C. FIG. 17 illustrates a plan view of a memory structure 1700 with BL conductive channels. The memory structure 1700 can be referred to as the memory device 1700 in the present disclosure. As illustrated in FIG. 17, the memory structure 1700 can include a plurality of array structures 402. Similar to the memory structure 1000 of FIG. 10, six array structures 402 are shown in FIG. 17. An array structure 402 can include a plurality of DRAM memory cells, as described above with respect to FIGS. 4A-4E. An array structure 402 is surrounded by a separation structure 460. In some implementations, the memory structure 1700 further includes a connection structure 470 adjacent to the separation structure 460. The separation structure 460 separates the capacitors 428 of the array structure 402 from the connection structure 470 (e.g., as illustrated in FIG. 4A). The connection structure 470 can include BL conductive channels 420. The semiconductor device 1700 of FIG. 17 differs from the semiconductor device 1000 of FIG. 10 primarily in that the conductive channels in FIG. 17 are BL conductive channels 420 that are located between adjacent array structure 402 along the BL direction (e.g., X direction). In some implementations, the BL conductive channel 420 includes at least one of tungsten (W), polysilicon, or titanium intrude (TiN).

In some implementations, as illustrated in FIG. 17, the semiconductor device 1700 includes a plurality of contact structures 416 positioned between adjacent array structures 402 along the BL direction (e.g., X direction). A contact structure 416 can be coupled to at least one BL conductive channels 420. For example, the contact structure 416 of FIG. 17 can couple to two BL conductive channels 420. Although not shown, it is to be understood that different contact structures 416 can differ in size and be coupled to different number of conductive channels. In some implementations, the contact structures 416 have a staggered pattern, as illustrated in FIG. 17. Adjacent contact structures 416 can be separate by at least one dummy channel 440 along the WL direction (e.g., Y direction). It is to be understood that the example layout and configuration of contact structures 416 in FIG. 17 is for illustration purpose and is not intended to be construed in a limiting sense; other configurations of contact structures 416 can also be deployed.

FIGS. 18A-18C are cross-sectional views of different implementations of the semiconductor device 1700 in a view similar to the A-A′ axis of the semiconductor device 1700 of FIG. 17. FIG. 18A illustrates a first implementation of a semiconductor device 1850 with BL conductive channels 420.

As illustrated in FIG. 18A, the BL conductive channels 420 can be between two adjacent array structures 402 along the BL direction (e.g., X direction of FIG. 18A). The array structures 402 can include capacitors 428 and transistors 426. A capacitor 428 includes a first end 404a and a second end 404b opposite to the first end 404a along Z direction. The second end 404b of the capacitor 428 can be coupled to the transistor 426. Similarly, the BL conductive channels 420 include a first end 405a and a second end 405b opposite to the first end 405a along Z direction. In some implementations, a first end 405a of the BL conductive channel 420 is substantially coplanar with the first end 404a of the capacitor 428, and a second end 405b of the BL conductive channel 420 is substantially coplanar with the second end 404b of the capacitor 428. In some implementations, a height 1815 of the BL conductive channels 420 is equal to a height 417 of the capacitor 428 along Z direction, as illustrated in FIG. 18A.

As noted above, a transistor 426 in the array region 480 can include a transistor body 431, a drain terminal 438, a source terminal 439, and a gate structure 436. In some implementations, the source terminal 439 and the drain terminal 438 are part of the transistor body 431 in the array region 480. For example, the source terminal 439 and the drain terminal 438 can be formed by implanting two ends of the transistor body 431 with desired dopants (N type dopants, or P type dopants). In some implementations, as noted above, the gate structure 436 is part of a word line 434.

In some implementations, the connection region 490 includes a transistor 1820. The transistor 1820 in the connection region 490 can include a semiconductor body 418, as illustrated in FIG. 18A. It is to be noted that in the present disclosure the transistors 426 in the array region 480 can be referred to as the first transistors 426, while the transistors 1820 in the connection region 490 can be referred to as second transistors 1820. Additionally, a vertical body structure that extends vertically along Z direction can be referred to as transistor body 431 in the array region 480 and as semiconductor body 418 in the connection region 490. As illustrated in FIG. 18A, the transistor body 431 in the array region 480 can have a height identical or substantially similar to that of the semiconductor body 418 in the connection region 490. The transistor body 431 of the first transistor 426 can be coupled to the capacitors 428 in the array region 480, while the semiconductor body 418 of the second transistor 1820 can be coupled to at least one BL conductive channel 420 in the connection region 490. In some implementations, the first transistor 426 of the memory cell 424 in the array region 480 is used as a switch for the capacitor 428 of the memory cell 424 where user data can be stored, while the second transistor 1820 in the connection region 490 is used as a switch or a resistor to connect the BL conductive channels 420 to the bit line 423.

Similar to the transistor body 431 of first transistors 426 in the array region 480, the semiconductor body 418 of second transistors 1820 in the connection region 490 can extend along Z direction. The semiconductor body 418 can include a first end 1802 and a second end 1804 opposite to the first end 1802 along the first direction (e.g., Z direction). In some implementations, each of a first end 1802 and a second end 1804 of the semiconductor body 418 includes dopants with a first type, and a middle portion 1803 of the semiconductor body 418 between the first end 1802 and the second end 1804 of the semiconductor body 418 includes the dopants with a second type. The first type of dopants can be N type dopants, and the second type of dopants can be P type dopants. The N type dopant can include Phosphorus (P) or Arsenic (As), and the P type dopant can include Boron (B) or Gallium (Ga).

In some implementations, the first type is different from the second type. For example, the semiconductor body 418 can include N-P-N dopants, where the first end 1802 and the second end 1804 of the semiconductor body 418 include N type dopants, and the middle portion 1803 of the semiconductor body 418 include P type dopants (e.g., as illustrated in FIG. 18B). In another example, the semiconductor body 418 can include P-N-P dopants.

In some implementations, the first type is identical to the second type. For example, the semiconductor body 418 can include N-N-N dopants, where the entire semiconductor body 418 is doped with only N type dopants. In another example, the semiconductor body 418 can include P-P-P dopants. It is to be understood that, in some implementations, despite the term “transistors,” second transistors 1820 in the connection region 490 do not have transistor properties; instead, it can function as a resistor when it is doped with only one type of dopants (either N type or P type), For example, FIG. 18A illustrates that the semiconductor body 418 can be doped with N type dopant, which can function as a resistor.

In some implementations, as illustrated in FIG. 18A, the semiconductor body 418 of the second transistor 1820 is coupled to a word line 434 extending along a WL direction (e.g., Y direction). The second transistor 1820 can be configured to be supplied with a voltage applied on the word line 434 while the BL conductive channel 420 is coupled to the bit line 423 through the semiconductor body 418 of the second transistor 1820. Without limiting any particular theory, applying a voltage on the word line 434 can reduce the resistance of the semiconductor body 418 and thus reduce energy loss.

In some implementations, the semiconductor device 1850 includes an isolating structure 472 between adjacent second transistors 1820. The isolating structure can be the shielding contact structure 472 of FIG. 4C. The isolating structure can also be referred to as TISO 472 in this disclosure.

In some implementations, the first end 1802 of the semiconductor body 418 of the second transistor 1820 is coupled to a BL conductive channel 420, while the second end 1804 is coupled to a bit line 423, as illustrated in FIG. 18A. Therefore, the BL conductive channel 420 can be coupled to the BL 423 through the semiconductor body 418 of the second transistor 1820.

In some implementations, the first end 405a of the BL conductive channel 420 is coupled to a contact structure 416. As noted above, the contact structure 416 can couple to one or more BL conductive channels 420, and different contact structures 416 can couple to different number of BL conductive channels 420.

In some implementations, the semiconductor device 1850 includes a dummy channel 440 extending into the layered structure 450 along Z direction in the connection region 490. As illustrated in FIG. 18A, the dummy channel 440 may not be in contact with a contact structure 416 at least at one end. The dummy structures 440 can be the same size as the BL conductive channels 420, and/or be made from materials that are identical or substantially similar to those used for the BL conductive channels 420.

FIG. 18B illustrates a second implementation of a semiconductor device 1860 with BL conductive channels 420. In contrast to the first implementation of the semiconductor device 1850 of FIG. 18A, the semiconductor device 1860 of FIG. 18B can have dopants with two different types in its semiconductor bodies 418 in the connection region 490. As illustrated in FIG. 18B, each of the first end 1802 and the second end 1804 of the semiconductor body 418 can include dopants with the first type (e.g., N type), and a middle portion 1803 of the semiconductor body 418 between the first end and the second end of the semiconductor body 418 includes dopants with the second type (e.g., P type). Therefore, the semiconductor body 418 of second transistors 1820 can include N-P-N dopants, similar to that of the transistor body 431 of the first transistors 426 in the array region 480. The semiconductor body 418 and the word line 434 can together function as a transistor in the connection region 490. In some implementations, the semiconductor body 418 of the second transistor 1820 in the connection region 490 includes different dopants as the first transistor 426 in the array region 480. For example, the semiconductor body 418 of the second transistor 1820 can include N-P-N dopants, whereas the transistor body 431 of the transistor 426 in the array region 480 can include P-N-P dopants.

In some implementations, the second transistor 1820 of the semiconductor device 1860 is configured to be turned on by a voltage applied on the corresponding word line 434. Therefore, the BL conductive channels 420 can be coupled to the bit line 423 through the second transistor 1820.

FIG. 18C illustrates a third implementation of a semiconductor device 1870 with BL conductive channels 420. In contrast to the semiconductor devices 1850, 1860 of FIGS. 18A and 18B, the semiconductor device 1870 of FIG. 18C can include a bigger semiconductor body 418. In some implementations, the semiconductor body 418 includes two vertical bodies that are integrated together (e.g., comparing FIG. 18A to FIG. 18C). In other words, there can be no TISO structure 472 between two vertical bodies in the semiconductor device 1870 (e.g., comparing FIG. 18A to FIG. 18C). In some implementations, a lateral size of the semiconductor body 418 of second transistors 1820 is greater than or equal to twice the lateral size of the transistor body 431 of first transistors 426. Without limiting to any particular theory, thicker semiconductor body 418 can reduce its resistance and thus reduce the energy loss across the semiconductor body 418 while coupling out the bit line 423 through the BL conductive channels 420.

In some implementations, as illustrated in FIG. 18C, a single semiconductor body 418 is coupled to two more BL conductive channels 420. For example, the semiconductor body 418a can be coupled to both the first BL conductive channels 420a and the second BL conductive channels 420b.

In some implementations, a single semiconductor body 418 is coupled to two word lines 434. For example, as illustrated in FIG. 18C, the semiconductor body 418a can be coupled to a first word line 434a and a second word line 434b on two lateral sides.

In some implementations, the second transistor 1820 is configured to be supplied with a voltage applied on the word line 434 while the BL conductive channel 420 is coupled to the bit line 423 through the semiconductor body 418 of the second transistor 1820. In some implementations, both word lines coupled to the semiconductor body 418 are supplied with the voltage. For example, for the semiconductor body 418a, both word lines (the first word line 434a and the second word line 434b) that is coupled to the semiconductor body 418a can be supplied with the voltage. Without limiting any particular theory, applying a voltage on the word line 434 can reduce the resistance of the semiconductor body 418 and thus reduce energy loss while coupling the BL line 423 out through the BL conductive channels 420.

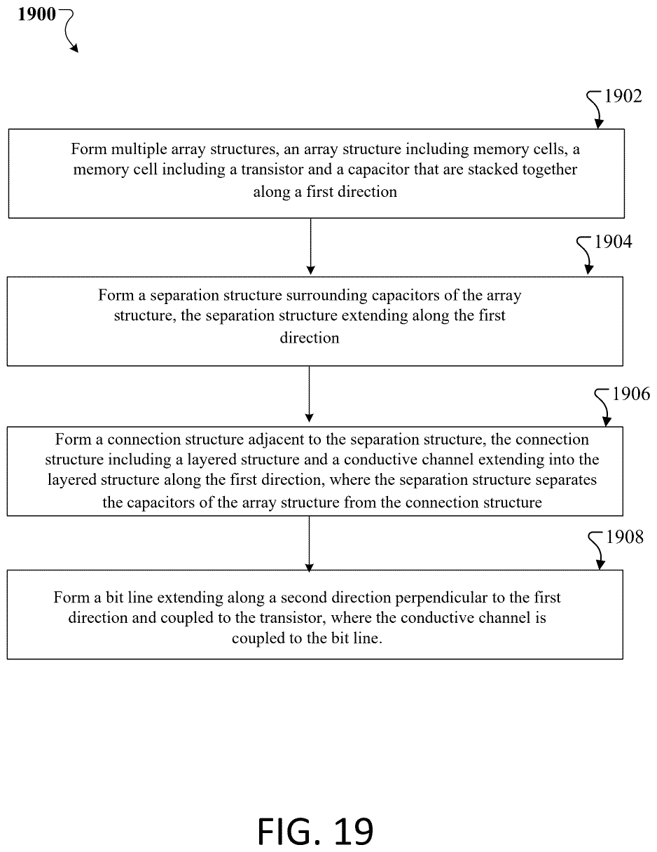

FIG. 19 is a flow chart of an example process 1900 for forming a semiconductor device with BL conductive channels. The semiconductor device can be the semiconductor device 1700 of FIG. 17, the semiconductor device 1850 of FIG. 18A, the semiconductor device 1860 of FIG. 18B, or the semiconductor device 1870 of FIG. 18C.

At step 1902, a plurality of array structures is formed. An array structure of the plurality of array structures includes a plurality of memory cells. A memory cell of the plurality of memory cells includes a transistor and a capacitor that are stacked together along a first direction. The array structure can be, e.g., the array structure 402 of FIGS. 4A-4E, 10-12, 13B-13C, 14 and 15C-15D. The memory cells can be, e.g., the memory cell 424 of FIGS. 4A-4E, 10-12, 13B-13C, 14, 15C-15D and 17-18C. The transistor can be, e.g., the transistor 426 of FIGS. 4A, 4C-4D, 11A-15D and 17-18C. The capacitor can be, e.g., the capacitor 428 of FIGS. 4A-8 and 18A-18C. The first direction can be, e.g., the Z direction of FIGS. 4A-4E, 10-12, 13B-13C, 14, 15C-15D and 18A-18C.

At step 1904, a separation structure surrounding capacitors of the array structure is formed, and the separation structure extends along the first direction. The separation structure can be, e.g., the separation structure 460 of FIGS. 4A-4E, 10-12, 13B-13C, 14, 15C-15D and 18A-18C.

At step 1906, a connection structure is formed that is adjacent to the separation structure. The connection structure includes a layered structure and a conductive channel extending into the layered structure along the first direction, where the separation structure separates the capacitors of the array structure from the connection structure, and the conductive channel includes a first end and a second end that are opposite to each other along the first direction. The connection structure can be, e.g., the connection structure 470 of FIGS. 4A-4C, 5-7B, 10-14, 15B-15D and 17-18C. The layered structure can be, e.g., the layered structure 450 of FIGS. 4C-14, 15B-15D and 18A-18C. The conductive channel can be, e.g., the BL conductive channels 420 of FIGS. 4A, 4D, 5-6, 8, and 17-18C. The first end can be, e.g., the first end 405a or the upper end 405a of the BL conductive channels 420 of FIGS. 4A, 4D, 5-6, 8, and 17-18C. The second end can be, e.g., the second end 405b or the lower end 405b of the BL conductive channels 420 of FIGS. 4A, 4D, 5-6, 8, and 17-18C.

At step 1908, a bit line extending along a second direction perpendicular to the first direction and coupled to the transistor, where the conductive channel is coupled to the bit line. The bit line can be, e.g., the bit line 423 of FIGS. 4A, 4D, 5-8 and 18A-18C. The second direction can be, e.g., the bit direction or X direction of FIGS. 4A, 4D, 5-8 and 18A-18C.

In some implementations, an etch stop layer is formed. The layered structure is formed on the etch stop layer. Openings are formed, extending into the layered structure along the first direction. The separation structure is formed, extending into the layered structure and defining an array region surrounded by the separation structure. The capacitors are formed in the array region. The conductive channel is formed outside of the array region and extending into the layered structure. The etch stop layer can be, e.g., the etch-stop layer 1302 of FIGS. 4C-8 and 18A-18C. The openings can be, e.g., the openings 1520 of FIGS. 13A and 15B, or the openings 2220 of FIG. 22B, as described above. The array region can be, e.g., the array region 480 of FIGS. 4A-8 and 17-18C. The region outside of the separation structure can be referred to as connection region 490, as illustrated in FIGS. 4A-8 and 17-18C.

In some implementations, a second transistor is formed outside of the array region, where the conductive channel is coupled to the bit line through a semiconductor body of the second transistor. The second transistor can be, e.g., the second transistor 1820 of FIGS. 4D and 8A-8C. The semiconductor body can be, e.g., the semiconductor body 418 of FIGS. 4D and 8A-8C.

FIGS. 20-23C illustrate various implementations of semiconductor devices with conductive channels 430 and cross-sectional views of the semiconductor devices at various stages of a fabrication process. The conductive channels 430 can be referred to as WL conductive channels 430 below when they are described in reference to FIGS. 20-23C. FIG. 20 illustrates a plan view of a semiconductor device 2000 with WL conductive channels. As illustrated in FIG. 20, the semiconductor device 2000 includes a plurality of array structures 402. Similar to the semiconductor device 1000 of FIG. 10 and the semiconductor device 1700 of FIG. 17, six array structures 402 are shown in FIG. 20. An array structure 402 includes a plurality of DRAM memory cells, as described above with respect to FIGS. 4A-4E. An array structure 402 can be surrounded by a separation structure 460. The semiconductor device 2000 further includes a connection structure 470 adjacent to the separation structure 460. The separation structure 460 can separate the capacitors 428 of the array structure 402 from the connection structure 470 (e.g., also illustrated in FIG. 4A). The connection structure 470 includes conductive channels. FIG. 20 differs from the FIGS. 10 and 17 primarily in that the conductive channels in FIG. 20 are WL conductive channels 430 that are located between adjacent array structure 402 along the WL direction (e.g., Y direction of FIG. 20). In some implementations, the WL conductive channel 430 includes at least one of tungsten (W), polysilicon, or titanium intrude (TiN).

In some implementations, as illustrated in FIG. 20, the semiconductor device 2000 includes a plurality of contact structures 416 coupled to at least one WL conductive channels 430. For example, the contact structure 416 can couple to 2×2 WL conductive channels 430, as illustrated in FIG. 20. Although not shown in FIG. 20, different contact structures 416 can differ in size and be coupled to different number of WL conductive channels 430. The contact structures 416 for WL conductive channels can be positioned between adjacent array structures 402 along the WL direction (e.g., Y direction of FIG. 20).

In some implementations, a staggered pattern of contact structures 416 is employed, as illustrated in FIG. 20, where the locations of contact structures 416 can be alternative and/or zigzag to each other. In some implementations, WL conductive channels 430 coupled to adjacent contact structures 416 are separated by at least one dummy channel 440. For example, the WL conductive channels 430 coupled to adjacent contact structures 416a, 416b can be separated by at least one dummy channel 440a. In some implementations, the contact structures 416 are positioned near the separation structure 460. In some implementations, the contact structures 416 are positioned above the word lines 434 along a vertical direction (e.g., Z direction), as shown below in FIGS. 21A-21B.

It is to be understand that the example in FIG. 20 is for illustration purpose and is not intended to be construed in a limiting sense; other configurations and layout of contact structures 416 can also be deployed.

FIGS. 21A and 21B are cross-sectional views of different implementations of a semiconductor device similar to the A-A′ axis of the semiconductor device 2000 of FIG. 20. FIG. 21A is identical to the implementation illustrated in FIG. 4E.

As illustrated in FIGS. 20 and 21A, the WL conductive channels 430 can be between two adjacent array structures 402 along the WL direction (e.g., Y direction of FIG. 20). The array structures 402 can include capacitors 428 and transistors 426. A capacitor 428 includes a first end 404a and a second end 404b opposite to the first end 404a along Z direction. The second end 404b of the capacitor 428 can be coupled to the transistor 426. Similarly, the WL conductive channels 430 include a first end 405a and a second end 405b opposite to the first end 405a along Z direction. In some implementations, the first end 405a of the WL conductive channel 430 is substantially coplanar with the first end 404a of the capacitor 428, whereas the second end 2105b of the WL conductive channels 430 extends beyond the second end 404b of the capacitor 428, as illustrated in FIG. 21A. In some implementations, a height 2115 of the conductive channel is greater than a height 417 of the capacitor 428 along Z direction, as illustrated in FIG. 21A.

As illustrated in FIG. 21A, the array structure 402 can be in an array region 480, and the WL conductive channels 430 can be in a word line (WL) pick-up region 2110. The WL pick-up region 2110 can be at least part of the connection region 490. In some implementations, the semiconductor device 2100 includes an etch-stop layer 1302 between the capacitor 428 and the transistor 426. The etch-stop layer 1302 can extend within the array region 480 but without extending into the WL pick-up region 2110, as illustrated in FIG. 21A. Therefore, absent the etch-stop layer 1302, a deeper channel can be formed in the WL pick-up region 2110 during etching, as described in further detail below with respect to FIGS. 22A-22C. As the WL conductive channels 430 extends further into the dielectric body 1102, the bottom end 405b of the WL conductive channels 430 can be in contact with or coupled to the WL 434.

In some implementations, as illustrated in FIG. 21A, a height 2102 of the word line 434 in the array region 480 is equal to a height 2104 of the word line 434 in the WL pick-up region 2110 along Z direction. In other words, the WL 434 can have uniform height along Z direction in both array region 480 and WL pick-up regions 2110.

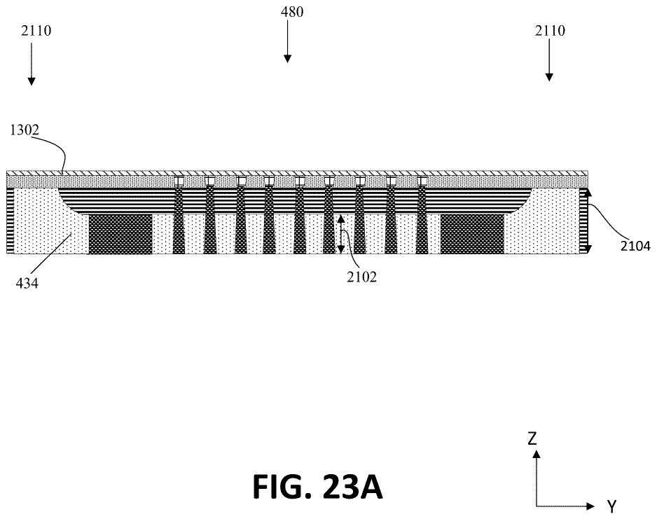

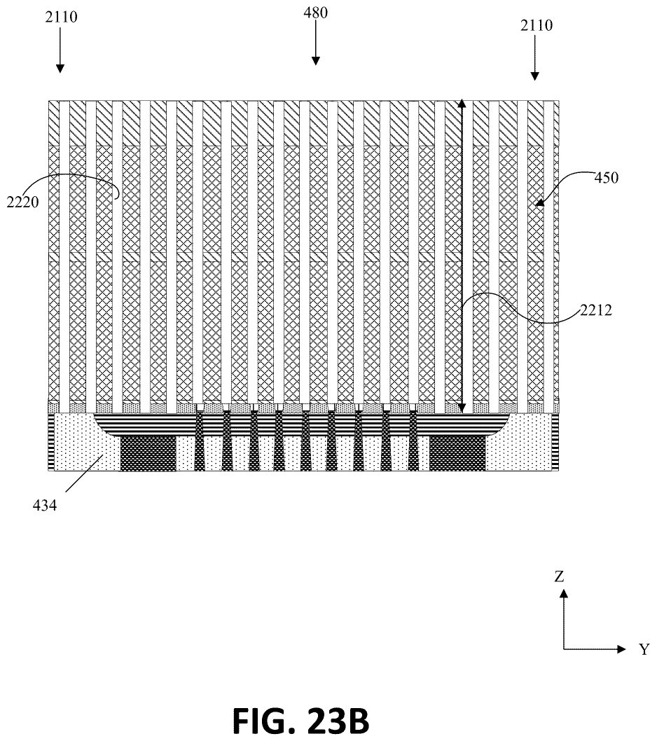

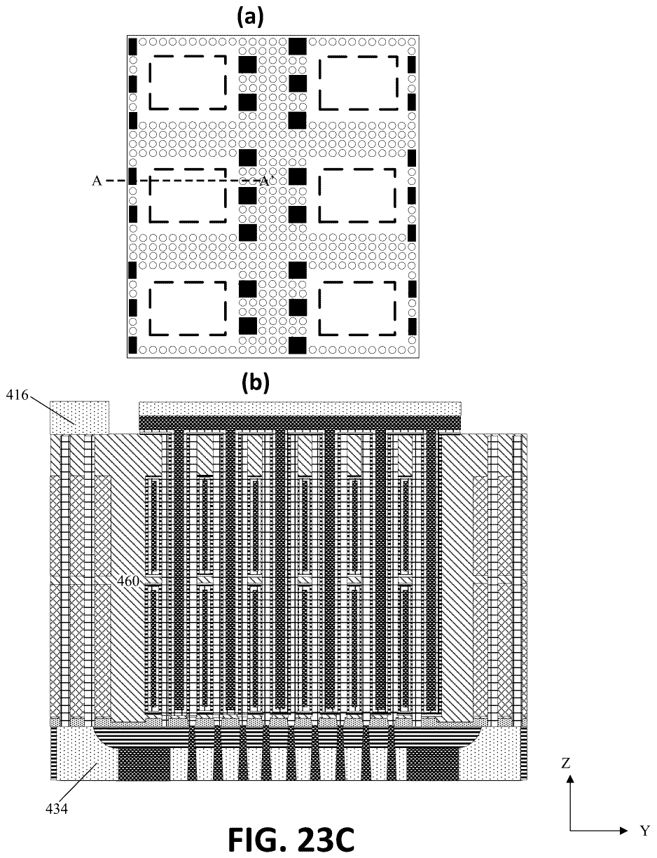

FIG. 21B illustrates another implementation of a semiconductor device 2150 with WL conductive channels 430. In contrast to the semiconductor device 2100 of FIG. 21A, the semiconductor device 2150 of FIG. 21B can have a height 2115 of the WL conductive channels 430 that is substantially equal to a height 417 of the capacitor 428 along Z direction. As illustrated in FIG. 21B, the etch-stop layer 1302 between the capacitor 428 and the transistor 426 can extend in both the array region 480 and the WL pick-up region 2110 along the WL direction (e.g., the Y axis). As described below with respect to FIGS. 23A-23C, the etch-stop layer 1302 in the WL pick-up region 2110 can block the etching of holes from extending further deeper into the dielectric body 1102 in both the array region 480 and the WL pick-up region 2110. Therefore, the WL conductive channels 430 and the capacitors 428 can have substantially same height. In other words, both ends of the WL conductive channels 430 can be substantially coplanar with respective ends of the capacitors 428.

In some implementations, a height 2102 of the word line 434 in the array region 480 is smaller than a height 2104 of the word line 434 in the WL pick-up region 2110 along Z direction, as illustrated in FIG. 21B. As the word line 434 is higher in the WL pick-up region 2110, the word line 434 can be in contact with the bottom end 405b of the WL conductive channel 430. Thus, the word line 434 can be coupled out through the WL conductive channel 430.

In some implementations, as illustrated in FIGS. 21A-21B, the semiconductor device 2100, 2150 include a plurality of contact structures 416, and each contact structures 416 is coupled to one or more WL conductive channels 430 in the WL pick-up region 2110. Therefore, the upper end 405a of the WL conductive channels 430 can be coupled to the corresponding contact structure 416, while the lower end 405b of the WL conductive channels 430 can be coupled to the word line 434.

FIGS. 22A-22C illustrated cross-sectional views of the semiconductor device 2100 of FIG. 21A with WL conductive channels 430 at various stages of a fabrication process. Diagram (a) of FIGS. 22A-22C are a plan view of the semiconductor device 2100, while diagram (b) of FIGS. 22A-22C is a cross-sectional view along A-A′ axis of diagram (a). The A-A′ axis is along the WL direction (e.g., Y axis). For ease of description, reference will be made to all diagrams when describing the structure of the semiconductor device 2100.

It is to be noted that the fabrication process illustrated by FIGS. 22A-22C for manufacturing WL conductive channels 430 are substantially similar to those illustrated in FIGS. 15A-15D for manufacturing TSC conductive channels 410. One primary difference lies in the position of conductive channels. As noted above, the WL conductive channels 430 can be located between two array structures 402 along the WL direction, and the WL conductive channels 430 can be in contact with the WL 434. In contrast, the TSC conductive channels 410 can have a greater flexibility in their placement: they can be situated in any region between adjacent array structures 402, whether along the BL direction, WL direction, or diagonally (e.g., as illustrated in FIG. 10), as long as they do not interfere with the WL 434 of FIGS. 21A-21B or semiconductor body 418 of second transistors 1820 of FIGS. 18A-18C. The placement of conductive channels can impact which portion of the connection region 490 needs have the etch-stop layer 1302 removed, as described below.

As illustrated in FIG. 22A, an etch-stop layer 1302 can be initially deposited in both array region 480 and connection region 490. However, the etch-stop layer 1302 can be subsequently at least partially removed in the connection region 490, as shown in diagram (b) of FIG. 22A. In some implementations, the dielectric layer 1304 underneath the etch-stop layer 1302 is also partially removed together with the etch-stop layer 1302. The connection region 490 with removed etch-stop layer 1302 can be referred to as a WL pick-up region 2110 in this disclosure. As noted above, the WL pick-up region 2110 is part of the connection region 490. Therefore, the connection region 490 can include both the WL pick-up region 2110 without etch-stop layer 1302 and an unexposed region 2210 covered by the etch-stop layer 1302. Diagram (a) of FIG. 22A illustrates a top view of the semiconductor device 2100 with partially removed etch-stop layer 1302. It is understood that the example in FIG. 22A is for illustration purpose and is not intended to be construed in a limiting sense.

As illustrated in FIG. 22B, the layered structure 450 can be formed using the process similar to those described above with respect to FIG. 13A. Openings 2220 can then be formed extending through the layered structure 450 along Z direction in both array region 480 and connection region 490. In some implementations, in the region with the etch-stop layer 1302 (e.g., the array region 480), the openings 2220 can stop at the etch-stop layer 1302, or extend into the etch-stop layer 1302 along Z direction, as illustrated in diagram (b) of FIG. 22B. In some implementations, the openings 2220 penetrate the etch-stop layer 1302 and further extend into the dielectric layer 1304 underneath the etch-stop layer 1302, as illustrated in diagram (b) of FIG. 22B, but with the etch-stop layer 1302, the openings 2220 may not extend further into the dielectric body 1102.

In some implementations, in the WL pick-up region 2110 without the etch-stop layer 1302, the openings 2220 can extend deeper into the dielectric body 1102 of the memory structure 1410. Therefore, a height 2215 of the openings 2220 in the WL pick-up region 2110 is greater than a height 2212 of the openings 2220 in the array region 480, as illustrated in diagram (b) of FIG. 22B. In some implementations, an etch time for forming the openings 2220 outside of the array region 480 (e.g., in the WL pick-up region 2110) is longer than an etch time for forming the openings 2220 inside the array region 480. In other words, an over-etch can be performed to form deeper openings 2220 in the WL pick-up region 2110 compared to the openings 2220 in the array region 480.

In some implementations, forming the openings 2220 involves using a full print lithography mask to define openings 2220 pattern in both array region 480 and connection region 490. As noted above, the openings 2220 in both array region 480 and the connection region 490 can have uniform diameter and/or pitch. In some implementations, one or more dry etching and/or wet etching techniques are used after patterning, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 22C, a separation structure 460 can be formed extending through the layered structure 450. The separation structure 460 defines the array region 480 (e.g., the area surrounded by the separation structure 460). The separation structure 460 can be formed by techniques described above with respect to FIG. 13B.

The capacitors 428 can be formed in the array region 480, as illustrated in diagram (b) of FIG. 22C. In some implementations, forming capacitors 428 can use the techniques described above with respect to FIG. 13B.

The WL conductive channel 430 can be formed outside of the array region 480 (e.g., the connection region 490) that extend into the layered structure 450, as illustrated in diagram (b) of FIG. 22C. In some implementations, forming the WL conductive channels 430 in the WL pick-up region 2110 includes depositing a conductive material into at least one opening 2220 in the WL pick-up region 2110. In some implementations, the WL conductive channel 430 has the same material as the first electrode 444 of the capacitors 428. In some implementations, the WL conductive channel 430 includes at least one of tungsten (W), polysilicon, or titanium intrude (TiN). In some implementations, the deposition of the conductive material into the openings 2220 in the connection region 490 is performed at the same process steps as those used for depositing the first electrode 444 of capacitors 428 in the array region 480.

As illustrated in FIG. 22C, contact structures 416 can be formed on top ends of the WL conductive channels 430. Each contact structure 416 can couple to one or more WL conductive channels 430. The contact structure 416 can include a conductive material including, but not limited to W, Co, Cu, Al, TiN, TaN, polysilicon, or any combination thereof. The contact structure 416 can be deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

FIGS. 23A-23C illustrated cross-sectional views of the semiconductor device 2150 of FIG. 21B with WL conductive channels 430 at various stages of a fabrication process. FIGS. 23A and 23B shows cross-sectional views along the WL direction (e.g., Y axis). Diagram (a) of FIG. 23C is a plan view of the semiconductor device 2150, while diagram (b) of FIG. 23C is a cross-sectional view along A-A′ axis of diagram (a). The A-A′ axis is along the WL direction. For ease of description, reference will be made to all diagrams when describing the structure of the semiconductor device 2150.

It is to be noted that some of the fabrication process illustrated by FIGS. 23A-23C for manufacturing WL conductive channels 430 can be similar to those illustrated in FIGS. 13A-13B for manufacturing TSC conductive channels 410. Two primary difference lies in the recess of word lines 434 and the position of conductive channels.

As illustrated in FIG. 23A, a portion of the word line 434 can be recessed in the array region 480 but not in the WL pick-up region 2110. Because of the recess, a height 2102 of the word line 434 in the array region 480 can be smaller than a height 2104 of the word line 434 in the WL pick-up region 2110 along Z direction. This is in contrast to FIG. 22A where the word line 434 is recessed in both the array region 480 and the WL pick-up region 2110. The recessed word line 434 in the array region 480 may reduce the likelihood of shorting between WL 434 and terminals of transistors 426 or between WL 434 and capacitors 428.

An etch-stop layer 1302 can be deposited in both array region 480 and connection region 490. Unlike the process step illustrated in FIG. 22A, the etch-stop layer 1302 can be kept intact in the connection region 490 for forming the semiconductor device 2150, as shown in FIG. 13C.

As illustrated in FIG. 23B, the layered structure 450 can be formed using the process similar to those described above with respect to FIG. 13A. Openings 2220 can then be formed extending into the layered structure 450 along Z direction in both array region 480 and connection region 490 using the process techniques similar to those describe above with respect to FIG. 13A. Because the etch-stop layer 1302 is present in both the array region 480 and the connection region 490, the openings 2220 can have substantially similar height 2212 in both regions. In some implementations, as illustrated in FIG. 23B, a portion of the WL 434 is exposed by the openings 2220 in the WL pick-up region 2110.

As illustrated in FIG. 23C, a separation structure 460 and capacitors 428 can be formed using the process techniques described above with respect to FIG. 13B. The WL conductive channel 430 can be formed outside of the array region 480 (e.g., in the connection region 490) that extend through the layered structure 450. Filling the openings 2220 with a conductive material can form the WL conductive channels 430. As the WL can be exposed in the prior process step illustrated by FIG. 23B, the WL conductive channels 430 can be in contact with the exposed portion of the WL 434. Therefore, the WL conductive channels 430 can electrically couple out the WL 434, e.g., to a word line driver.

In some implementations, forming the WL conductive channels 430 in the WL pick-up region 2110 includes depositing a conductive material into at least one opening 2220 in the WL pick-up region 2110, as described above in reference to FIG. 22C.

As illustrated in FIG. 23C, contact structures 416 can be formed on top ends of the WL conductive channels 430. Each contact structure 416 can couple to one or more WL conductive channels 430. The contact structure 416 can include a conductive material including, but not limited to W, Co, Cu, Al, TiN, TaN, polysilicon, or any combination thereof.

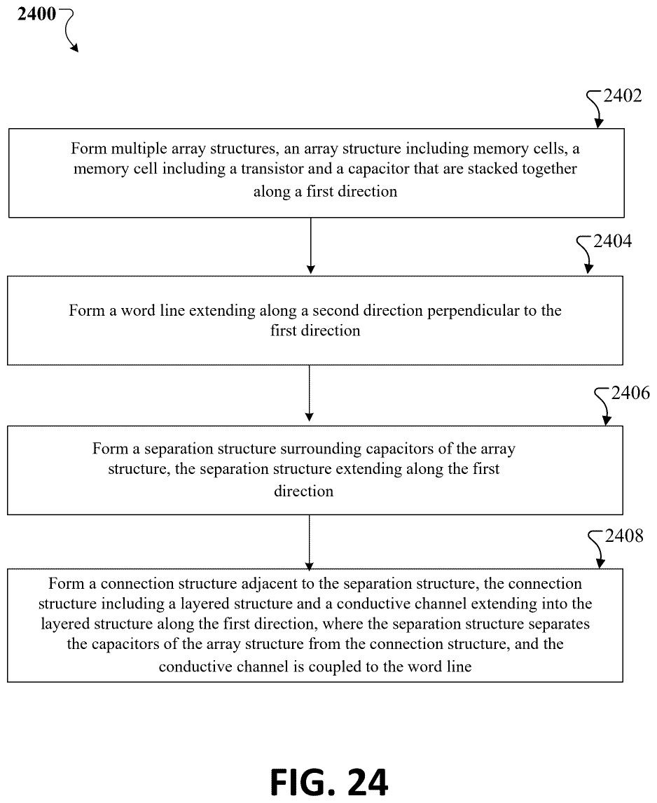

FIG. 24 is a flow chart of an example process 2400 for forming a semiconductor device with WL conductive channels. The semiconductor device can be the semiconductor device 2000 of FIG. 20, the semiconductor device 2100 of FIG. 21A, or the semiconductor device 2150 of FIG. 21B.

At step 2402, a plurality of array structures is formed. An array structure of the plurality of array structures includes a plurality of memory cells. A memory cell of the plurality of memory cells includes a transistor and a capacitor that are stacked together along a first direction. The array structure can be, e.g., the array structure 402 of FIGS. 4A-4E, 10-12, 13B-13C, 14, 15C-15D, 20-21B, 22C and 23C. The memory cells can be, e.g., the memory cell 424 of FIGS. 4A-4E, 10-12, 13B-13C, 14, 15C-15D, 17-18C, 20-21B, 22C and 23C. The transistor can be, e.g., the transistor 426 of FIGS. 4A, 4C-4D, 11A-15D and 17-18C. The capacitor can be, e.g., the capacitor 428 of FIGS. 4A-8, 18A-18C, 20-21B, 22C and 23C. The first direction can be, e.g., the Z direction of FIGS. 4A-4E, 10-12, 13B-13C, 14, 15C-15D, 18A-18C, and 21A-23C.

At step 2404, a word line extending along a second direction perpendicular to the first direction is formed. The word line can be, e.g., the word line 434 of FIGS. 4A, 4C-8 and 10-23C. The second direction can be, e.g., the word line direction or Y direction of FIGS. 4A, 4E, 21A and 23C.

At step 2406, a separation structure surrounding capacitors of the array structure is formed, and the separation structure extends along the first direction. The separation structure can be, e.g., the separation structure 460 of FIGS. 4A-4E, 10-12, 13B-13C, 14, 15C-15D, 18A-18C, and 21A-23C.

At step 2408, a connection structure is formed that is adjacent to the separation structure. The connection structure includes a layered structure and a conductive channel extending into the layered structure along the first direction, where the separation structure separates the capacitors of the array structure from the connection structure, and the conductive channel includes a first end and a second end that are opposite to each other along the first direction. The connection structure can be, e.g., the connection structure 470 of FIGS. 4A-4C, 5-7B, 10-14, 15B-15D, 17-18C and 20-23C. The layered structure can be, e.g., the layered structure 450 of FIGS. 4C-14, 15B-15D, 18A-18C, 20-21B, 22B-22C and 23B-23C. The conductive channel can be, e.g., the WL conductive channels 430 of FIGS. 4A, 4E, 5-6, 8, and 20-21B, 22C and 23C. The first end can be, e.g., the first end 405a or the upper end 405a of the WL conductive channels 430 of FIGS. 4A, 4D, 5-6, 8, 17-18C, 20-21B, 22C and 23C. The second end can be, e.g., the second end 405b or the lower end 405b of the WL conductive channels 430 of FIGS. 4A, 4D, 5-6, 8, 17-18C, 20-21B, 22C and 23C.

In some implementations, an etch stop layer is formed. The layered structure is formed on the etch stop layer. Openings are formed, extending into the layered structure along the first direction. The separation structure is formed, extending into the layered structure and defining an array region surrounded by the separation structure. The capacitors are formed in the array region. The conductive channel is formed outside of the array region and extending into the layered structure. The etch stop layer can be, e.g., the etch-stop layer 1302 of FIGS. 4C-8, 18A-18C and 21A-23C. The openings can be, e.g., the openings 1520 of FIGS. 13A and 15B, or the openings 2220 of FIGS. 22B and 23B. The array region can be, e.g., the array region 480 of FIGS. 4A-8, 17-18C and 20-23C. The region outside of the separation structure can be referred to as connection region 490, as illustrated in FIGS. 4A-8, 17-18C and 20-23C.

In some implementations, the etch-stop layer outside of the array region is at least partially removed, as described above with reference to FIGS. 22A-22C.

In some implementations, a portion of the word line in the array region is recessed, as described above with reference to FIGS. 23A-23C.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3 memory” refers to a three-dimensional (3) semiconductor device with vertically oriented strings of memory cell transistors 426 (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a plurality of array structures, an array structure of the plurality of array structures comprising a plurality of memory cells, a memory cell of the plurality of memory cells comprising a transistor and a capacitor that are stacked together along a first direction;
a separation structure surrounding capacitors of the array structure, the separation structure extending along the first direction;
a connection structure adjacent to the separation structure, the connection structure comprising a layered structure and a conductive channel extending into the layered structure along the first direction, wherein the separation structure separates the capacitors of the array structure from the connection structure, and the conductive channel comprises a first end and a second end that are opposite to each other along the first direction; and
a first contact structure and a second contact structure, the first contact structure being coupled to the first end of the conductive channel and the second contact structure being coupled to the second end of the conductive channel.

2. The semiconductor device of claim 1, wherein the layered structure comprises a first dielectric layer and a second dielectric layer stacked together along the first direction.

3. The semiconductor device of claim 2, wherein the layered structure further comprises:
a first supporting layer between the first dielectric layer and the second dielectric layer, and
a second supporting layer stacked over the first dielectric layer.

4. The semiconductor device of claim 3, wherein the first dielectric layer comprises tetraethyl orthosilicate (TEOS), the second dielectric layer comprises borophosphosilicate glass (BPSG), and the first supporting layer and second supporting layer comprise at least one of silicon carbon nitride (SiCN) or silicon boron nitride (SiBN).

5. The semiconductor device of claim 2, wherein a material of the separation structure is different from a material of the first dielectric layer of the layered structure.

6. The semiconductor device of claim 1, wherein an edge of the separation structure is wave shaped.

7. The semiconductor device of claim 1, wherein the capacitor comprises a first end and a second end opposite to the first end along the first direction, the second end of the capacitor being coupled to the transistor, and wherein a first end of the conductive channel is coplanar with the first end of the capacitor.

8. The semiconductor device of claim 7, wherein a height of the conductive channel is greater than a height of the capacitor along the first direction.

9. The semiconductor device of claim 7, wherein a height of the conductive channel is equal to a height of the capacitor along the first direction.

10. The semiconductor device of claim 1, wherein the connection structure comprises a plurality of conductive channels including the conductive channel, and
wherein the first contact structure and the second contact structure are coupled to first and second ends of one or more same conductive channels including the conductive channel.

11. The semiconductor device of claim 10, comprising: a third contact structure coupled to at least one of the plurality of conductive channels, and
wherein adjacent conductive channels coupled to the first contact structure and the third contact structure are spaced from each other by at least one dummy channel between the adjacent conductive channels.

12. The semiconductor device of claim 1, wherein a size of the conductive channel is smaller than a width of the separation structure along a second direction perpendicular to the first direction, the separation structure surrounding capacitors of the array structure along the second direction and a third direction perpendicular to the first direction and the second direction.

13. The semiconductor device of claim 1, wherein the capacitor extends along the first direction and comprises a first electrode, a second electrode, and a capacitor dielectric between the first electrode and the second electrode, the first electrode is coupled to the transistor, and an outer size of the first electrode is equal to a size of the conductive channel.

14. A semiconductor device, comprising:
a plurality of array structures, an array structure of the plurality of array structures comprising a plurality of memory cells, a memory cell of the plurality of memory cells comprising a transistor and a capacitor that are stacked together along a first direction;
a connection structure adjacent to the array structures, the connection structure comprising a layered structure and a conductive channel extending into the layered structure along the first direction, wherein the layered structure comprises a first dielectric layer and a second dielectric layer stacked together along the first direction, and the conductive channel comprises a first end and a second end that are opposite to each other along the first direction; and
a first contact structure and a second contact structure, the first contact structure being coupled to the first end of the conductive channel and the second contact structure being coupled to the second end of the conductive channel.

15. The semiconductor device of claim 14, wherein the layered structure comprises a first supporting layer between the first dielectric layer and the second dielectric layer, and a second supporting layer stacked over the first dielectric layer.

16. The semiconductor device of claim 14, comprising:
a separation structure surrounding capacitors of the array structure, the separation structure extending along the first direction, wherein the separation structure separates capacitors of the array structure from the connection structure.

17. A method of forming a semiconductor device, comprising:
forming a plurality of array structures, an array structure of the plurality of array structures comprising a plurality of memory cells, a memory cell of the plurality of memory cells comprising a transistor and a capacitor that are stacked together along a first direction;
forming a separation structure surrounding capacitors of the array structure, the separation structure extending along the first direction;
forming a connection structure adjacent to the separation structure, the connection structure comprising a layered structure and a conductive channel extending into the layered structure along the first direction, wherein the separation structure separates the capacitors of the array structure from the connection structure, and the conductive channel comprises a first end and a second end that are opposite to each other along the first direction; and
forming a plurality of contact structures comprising a first contact structure and a second contact structure, the first contact structure being coupled to the first end of the conductive channel and the second contact structure being coupled to the second end of the conductive channel.

18. The method of claim 17, comprising:
forming an etch stop layer;
forming the layered structure on the etch stop layer;
forming openings extending into the layered structure along the first direction;
forming the separation structure extending into the layered structure and defining an array region surrounded by the separation structure;
forming the capacitors in the array region; and
forming the conductive channel outside of the array region and extending into the layered structure.

19. The method of claim 18, further comprising:
at least partially removing the etch stop layer outside of the array region.

20. The method of claim 19, wherein forming the conductive channels outside of the array region comprises:
depositing a sacrificial material into one or more openings outside of the array region;
removing the sacrificial material of at least one of the one or more openings outside of the array region to form holes; and
depositing a conductive material into the holes.
